(19) United States
(12) Patent Application Publication
(10) Pub. No.: US 2024/0237527 A1
(43) Pub. Date: Jul. 11, 2024

(54) LIGHT-EMITTING DEVICE, DISPLAY APPARATUS, DISPLAY MODULE, AND ELECTRONIC DEVICE

(71) Applicant: SEMICONDUCTOR ENERGY LABORATORY CO., LTD., Atsugi-shi (JP)

(72) Inventors: Takeyoshi WATABE, Atsugi (JP); Hideko YOSHIZUMI, Atsugi (JP); Nobuharu OHSAWA, Zama (JP); Hiromi SEO, Sagamihara (JP); Toshiki SASAKI, Kawasaki (JP)

(21) Appl. No.: 18/541,411

(22) Filed: Dec. 15, 2023

(30) Foreign Application Priority Data
Dec. 23, 2022 (JP) 2022-206180

(51) Int. Cl. H10K 85/60; H10K 50/13; H10K 50/17; H10K 59/131; H10K 59/35; H10K 85/30

(52) U.S. Cl. CPC H10K 85/6572; H10K 50/131; H10K 50/171; H10K 59/131; H10K 59/352; H10K 85/342; H10K 85/6576

(57) ABSTRACT

A novel light-emitting device that is highly convenient, useful, or reliable is provided. The light-emitting device includes a first electrode, a second electrode, a first unit, and a first layer. The first unit is positioned between the first electrode and the second electrode and contains a first light-emitting material. The first layer is positioned between the second electrode and the first unit and contains a first organic compound and a second organic compound. The first organic compound has an acid dissociation constant pKₐ larger than or equal to 8, and the second organic compound has no pyridine ring, no phenanthroline ring, or one phenanthroline ring.

### BACKGROUND OF THE INVENTION

### 1. Field of the Invention

One embodiment of the present invention relates to a light-emitting device, a display apparatus, a display module, an electronic device, or a semiconductor device.

One embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display apparatus, a light-emitting apparatus, a power storage device, a memory device, a method for driving any of them, and a method for manufacturing any of them.

### 2. Description of the Related Art

In recent years, higher resolution has been required for display panels. Examples of devices that require high-resolution display panels include a smartphone, a tablet terminal, and a laptop computer. Furthermore, higher resolution has been required for a stationary display apparatus such as a television device or a monitor device along with an increase in definition. The highest resolution is required of a device for virtual reality (VR) or augmented reality (AR), for example.

Typical examples of display apparatuses that can be used for display panels include a liquid crystal display apparatus, a light-emitting apparatus including a light-emitting element such as an organic electroluminescent (EL) element or a light-emitting diode (LED), and electronic paper performing display by an electrophoretic method or the like.

An organic EL element generally has a structure in which, for example, a layer containing a light-emitting organic compound is provided between a pair of electrodes. By voltage application to this element, the light-emitting organic compound can emit light. A display apparatus including such an organic EL element needs no backlight that is necessary in a liquid crystal display apparatus and the like; thus, thin, lightweight, high-contrast, and low-power display apparatuses can be obtained. Patent Document 1, for example, discloses an example of a display apparatus including an organic EL element.

Patent Document 2 discloses a display apparatus including an organic EL device for VR.

As an organic thin film with an excellent electron-injection property and electron-transport property when used as an electron-injection layer of an organic EL element, for example, a single film containing a hexahydropyrimidopyrimidine compound and a material transporting an electron, and a stacked film of a film containing a hexahydropyrimidopyrimidine compound and a film containing a material transporting an electron are known (Patent Document 3).

### REFERENCES

### Patent Documents

[Patent Document 1] Japanese Published Patent Application No. 2002-324673
[Patent Document 2] PCT International Publication No. WO2018/087625
[Patent Document 3] PCT International Publication No. WO2021/045178

### SUMMARY OF THE INVENTION

An object of one embodiment of the present invention is to provide a novel light-emitting device that is highly convenient, useful, or reliable. Another object is to provide a novel display apparatus that is highly convenient, useful, or reliable. Another object is to provide a novel display module that is highly convenient, useful, or reliable. Another object is to provide a novel electronic device that is highly convenient, useful, or reliable. Another object is to provide a novel light-emitting device, a novel display apparatus, a novel display module, a novel electronic device, or a novel semiconductor device.

Note that the description of these objects does not preclude the existence of other objects. In one embodiment of the present invention, there is no need to achieve all these objects. Other objects will be apparent from and can be derived from the description of the specification, the drawings, the claims, and the like.
(1) One embodiment of the present invention is a light-emitting device including a first electrode, a second electrode, a first unit, and a first layer.

The first unit is positioned between the first electrode and the second electrode and contains a first light-emitting material.

The first layer is positioned between the second electrode and the first unit and contains a first organic compound and a second organic compound. The first organic compound has an acid dissociation constant pKₐ larger than or equal to 8, and the second organic compound has no pyridine ring, no phenanthroline ring, or one phenanthroline ring.
(2) Another embodiment of the present invention is a light-emitting device including a first electrode, a second electrode, a first unit, and a first layer.

The first unit is positioned between the first electrode and the second electrode and contains a first light-emitting material.

The first layer is positioned between the second electrode and the first unit and contains a first organic compound and a second organic compound. The first organic compound has an acid dissociation constant pKₐ larger than or equal to 8, and the second organic compound has an acid dissociation constant pKₐ smaller than 4.
(3) Another embodiment of the present invention is a light-emitting device including a first electrode, a second electrode, a first unit, and a first layer.

The first unit is positioned between the first electrode and the second electrode and contains a first light-emitting material.

The first layer is positioned between the second electrode and the first unit and contains a first organic compound and a second organic compound. The first organic compound has an acid dissociation constant pKₐ larger than or equal to 8, and the second organic compound has a polarization term δₚ of a solubility parameter δ of less than or equal to 4.0 MPa^{0.5}.
(4) Another embodiment of the present invention is the light-emitting device in which the first organic compound has a guanidine skeleton.
(5) Another embodiment of the present invention is the light-emitting device in which the first organic compound has a 1,3,4,6,7,8-hexahydro-2H-pyrimido[1,2-a]pyrimidine group.
(6) Another embodiment of the present invention is the light-emitting device in which the first organic compound does not have an electron-donating property with respect to the second organic compound.
(7) Another embodiment of the present invention is the light-emitting device in which the first layer contains a material having a spin density lower than or equal to 1×10¹⁷ spins/cm³ in a film state observed by electron spin resonance spectroscopy.
(8) Another embodiment of the present invention is the light-emitting device in which the first layer is in contact with the second electrode.

Another embodiment of the present invention is the light-emitting device further including an intermediate layer and a second unit in addition to the above components, for example. The second unit is positioned between the first unit and the first electrode and contains a second light-emitting material. The intermediate layer is positioned between the first unit and the second unit and contains an organic compound OCX and an organic compound ETMX. The organic compound OCX has an acid dissociation constant pKₐ larger than or equal to 8, and the organic compound ETMX has no pyridine ring, no phenanthroline ring, or one phenanthroline ring.

Another embodiment of the present invention is the light-emitting device in which the intermediate layer contains the organic compound OCX and the organic compound ETMX, the organic compound OCX has an acid dissociation constant pKₐ larger than or equal to 8, and the organic compound ETMX has an acid dissociation constant pKₐ smaller than 4.

Another embodiment of the present invention is the light-emitting device in which the intermediate layer contains the organic compound OCX and the organic compound ETMX, the organic compound OCX has an acid dissociation constant pKₐ larger than or equal to 8, and the organic compound ETMX has a polarization term δₚ of a solubility parameter δ of less than or equal to 4.0 MPa^{0.5}.

Another embodiment of the present invention is the light-emitting device in which the organic compound OCX has a guanidine skeleton.

Another embodiment of the present invention is the light-emitting device in which the organic compound OCX has a 1,3,4,6,7,8-hexahydro-2H-pyrimido[1,2-a]pyrimidine group.

Another embodiment of the present invention is the light-emitting device in which the organic compound OCX does not have an electron-donating property with respect to the organic compound ETMX.

Accordingly, the first layer can supply electrons to the first unit. Furthermore, for example, the first layer can be formed without a substance with high activity, such as an alkali metal or an alkaline earth metal. In addition, the resistance to the air or an impurity such as water can be increased. Moreover, a reduction in emission efficiency due to the air or an impurity such as water can be inhibited. As a result, a novel light-emitting device that is highly convenient, useful, or reliable can be provided.
(9) Another embodiment of the present invention is a display apparatus including a first light-emitting device and a second light-emitting device.

The first light-emitting device includes a first electrode, a second electrode, a first unit, and a first layer.

The first unit is positioned between the first electrode and the second electrode and contains a first light-emitting material.

The first layer is positioned between the second electrode and the first unit and contains a first organic compound and a second organic compound.

The second light-emitting device includes a third electrode, a fourth electrode, a second unit, and a second layer.

The third electrode is adjacent to the first electrode, and a first gap is positioned between the third electrode and the first electrode.

The second unit is positioned between the third electrode and the fourth electrode and contains a second light-emitting material.

The second layer is positioned between the fourth electrode and the second unit and contains a third organic compound and a fourth organic compound.

The first organic compound has an acid dissociation constant pKₐ larger than or equal to 8, and the third organic compound has an acid dissociation constant pKₐ larger than or equal to 8. The second organic compound has no pyridine ring, no phenanthroline ring, or one phenanthroline ring, and the fourth organic compound has no pyridine ring, no phenanthroline ring, or one phenanthroline ring.
(10) Another embodiment of the present invention is a display apparatus including a first light-emitting device and a second light-emitting device.

The first light-emitting device includes a first electrode, a second electrode, a first unit, and a first layer.

The first unit is positioned between the first electrode and the second electrode and contains a first light-emitting material.

The first layer is positioned between the second electrode and the first unit and contains a first organic compound and a second organic compound.

The second light-emitting device includes a third electrode, a fourth electrode, a second unit, and a second layer.

The third electrode is adjacent to the first electrode, and a first gap is positioned between the third electrode and the first electrode.

The second unit is positioned between the third electrode and the fourth electrode and contains a second light-emitting material.

The second layer is positioned between the fourth electrode and the second unit and contains a third organic compound and a fourth organic compound.

The first organic compound has an acid dissociation constant pKₐ larger than or equal to 8, and the third organic compound has an acid dissociation constant pKₐ larger than or equal to 8. The second organic compound has an acid dissociation constant pKₐ smaller than 4, and the fourth organic compound has an acid dissociation constant pKₐ smaller than 4.
(11) Another embodiment of the present invention is a display apparatus including a first light-emitting device and a second light-emitting device.

The first light-emitting device includes a first electrode, a second electrode, a first unit, and a first layer.

The first unit is positioned between the first electrode and the second electrode and contains a first light-emitting material.

The first layer is positioned between the second electrode and the first unit and contains a first organic compound and a second organic compound.

The second light-emitting device includes a third electrode, a fourth electrode, a second unit, and a second layer.

The third electrode is adjacent to the first electrode, and a first gap is positioned between the third electrode and the first electrode.

The second unit is positioned between the third electrode and the fourth electrode and contains a second light-emitting material.

The second layer is positioned between the fourth electrode and the second unit and contains a third organic compound and a fourth organic compound.

The first organic compound has an acid dissociation constant pKₐ larger than or equal to 8, and the third organic compound has an acid dissociation constant pKₐ larger than or equal to 8. The second organic compound has a polarization term δₚ of a solubility parameter δ of less than or equal to 4.0 MPa^{0.5}, and the fourth organic compound has a polarization term δₚ of a solubility parameter δ of less than or equal to 4.0 MPa^{0.5}.
(12) Another embodiment of the present invention is the display apparatus in which at least one of the first organic compound and the third organic compound has a guanidine skeleton.
(13) Another embodiment of the present invention is the display apparatus in which at least one of the first organic compound and the third organic compound has a 1,3,4,6,7,8-hexahydro-2H-pyrimido[1,2-a]pyrimidine group.
(14) Another embodiment of the present invention is the display apparatus in which the first organic compound does not have an electron-donating property with respect to the second organic compound, and the third organic compound does not have an electron-donating property with respect to the fourth organic compound.
(15) Another embodiment of the present invention is the display apparatus in which the first layer contains a material having a spin density lower than or equal to 1×10¹⁷ spins/cm³ in a film state observed by electron spin resonance spectroscopy, and the second layer contains a material having a spin density lower than or equal to 1×10¹⁷ spins/cm³ in a film state observed by electron spin resonance spectroscopy.
(16) Another embodiment of the present invention is the display apparatus in which the first layer is in contact with the second electrode, and the second layer is in contact with the fourth electrode.

Another embodiment of the present invention is the display apparatus in which the first light-emitting device further includes a first intermediate layer and a third unit, and the second light-emitting device further includes a second intermediate layer and a fourth unit, for example. The third unit is positioned between the first unit and the first electrode and contains a third light-emitting material. The first intermediate layer is positioned between the first unit and the third unit and contains an organic compound OCX and an organic compound ETMX. The fourth unit is positioned between the second unit and the third electrode and contains a fourth light-emitting material. The second intermediate layer is positioned between the second unit and the fourth unit and contains the organic compound OCX and the organic compound ETMX. The organic compound OCX has an acid dissociation constant pKₐ larger than or equal to 8, and the organic compound ETMX has no pyridine ring, no phenanthroline ring, or one phenanthroline ring.

Another embodiment of the present invention is the display apparatus in which the first intermediate layer and the second intermediate layer each contain the organic compound OCX and the organic compound ETMX, the organic compound OCX has an acid dissociation constant pKₐ larger than or equal to 8, and the organic compound ETMX has an acid dissociation constant pKₐ smaller than 4.

Another embodiment of the present invention is the display apparatus in which the first intermediate layer and the second intermediate layer each contain the organic compound OCX and the organic compound ETMX, the organic compound OCX has an acid dissociation constant pKₐ larger than or equal to 8, and the organic compound ETMX has a polarization term δₚ of a solubility parameter δ of less than or equal to 4.0 MPa^{0.5}.

Another embodiment of the present invention is the display apparatus in which the organic compound OCX has a guanidine skeleton.

Another embodiment of the present invention is the display apparatus in which the organic compound OCX has a 1,3,4,6,7,8-hexahydro-2H-pyrimido[1,2-a]pyrimidine group.

Another embodiment of the present invention is the display apparatus in which the organic compound OCX does not have an electron-donating property with respect to the organic compound ETMX.

Accordingly, the first layer can supply electrons to the first unit. In addition, the second layer can supply electrons to the second unit. Furthermore, for example, the first layer and the second layer can be formed without a substance with high activity, such as an alkali metal or an alkaline earth metal. In addition, the resistance to the air or an impurity such as water can be increased. Moreover, a reduction in emission efficiency due to the air or an impurity such as water can be inhibited. As a result, a novel light-emitting device that is highly convenient, useful, or reliable can be provided.
(17) Another embodiment of the present invention is the display apparatus in which the first light-emitting device includes a third layer.

The third layer is positioned between the first unit and the first electrode, and the second light-emitting device includes a fourth layer.

The fourth layer is positioned between the second unit and the third electrode, and a second gap is positioned between the fourth layer and the third layer. The second gap overlaps with the first gap.

The third layer contains a material having a spin density higher than or equal to 1×10¹⁸ spins/cm³ in a film state observed by electron spin resonance spectroscopy, and the fourth layer contains a material having a spin density higher than or equal to 1×10¹⁸ spins/cm³ in a film state observed by electron spin resonance spectroscopy.
(18) Another embodiment of the present invention is the display apparatus in which a third gap is positioned between the second layer and the first layer and overlaps with the first gap.
(19) Another embodiment of the present invention is the display apparatus further including a fifth layer. The fifth layer includes the first layer and the second layer and overlaps with the first gap between the first layer and the second layer.

Accordingly, current flowing between the third layer and the fourth layer can be reduced. Occurrence of a phenomenon in which the second light-emitting device that is adjacent to the first light-emitting device unintentionally emits light in accordance with the operation of the first light-emitting device can be inhibited. Occurrence of a crosstalk phenomenon between the light-emitting devices can be inhibited. The color gamut that can be expressed by the display apparatus can be widened. The resolution of the display apparatus can be increased. As a result, a novel display apparatus that is highly convenient, useful, or reliable can be provided.
(20) Another embodiment of the present invention is the display apparatus further including a first insulating layer, a conductive film, and a second insulating layer.

The first insulating layer overlaps with the conductive film, and the first electrode and the third electrode are positioned between the first insulating layer and the conductive film. The conductive film includes the second electrode and the fourth electrode.

The second insulating layer is positioned between the conductive film and the first insulating layer and overlaps with the first gap. The second insulating layer fills the third gap.

The second insulating layer has a first opening portion and a second opening portion, the first opening portion overlaps with the first electrode, and the second opening portion overlaps with the third electrode.
(21) Another embodiment of the present invention is the display apparatus in which the second insulating layer is in contact with the conductive film.
(22) Another embodiment of the present invention is the display apparatus further including a fifth layer. The fifth layer includes the first layer and the second layer and is in contact with the second insulating layer between the first layer and the second layer.

Accordingly, the third gap can be filled with the second insulating layer. A step formed between the first light-emitting device and the second light-emitting device can be reduced so as to be close to a flat plane. A phenomenon in which a cut or a split due to the step is generated in the conductive film can be inhibited. As a result, a novel display apparatus that is highly convenient, useful, or reliable can be provided.
(23) Another embodiment of the present invention is a display module including any of the display apparatuses and at least one of a connector and an integrated circuit.
(24) Another embodiment of the present invention is an electronic device including any of the display apparatuses and at least one of a battery, a camera, a speaker, and a microphone.

Although the block diagram in drawings attached to this specification shows components classified based on their functions in independent blocks, it is difficult to classify actual components based on their functions completely, and one component can have a plurality of functions.

Note that the light-emitting apparatus in this specification includes, in its category, an image display device that uses a light-emitting device. The light-emitting apparatus may also include, in its category, a module in which a light-emitting device is provided with a connector such as an anisotropic conductive film or a tape carrier package (TCP), a module in which a printed wiring board is provided at the end of a TCP, and a module in which an integrated circuit (IC) is directly mounted on a light-emitting device by a chip on glass (COG) method. Furthermore, a lighting device or the like may include the light-emitting apparatus.

One embodiment of the present invention can provide a novel light-emitting device that is highly convenient, useful, or reliable. Another embodiment of the present invention can provide a novel display apparatus that is highly convenient, useful, or reliable. Another embodiment of the present invention can provide a novel display module that is highly convenient, useful, or reliable. Another embodiment of the present invention can provide a novel electronic device that is highly convenient, useful, or reliable. A novel light-emitting device can be provided. A novel display apparatus can be provided. A novel display module can be provided. A novel electronic device can be provided.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

In the accompanying drawings:

FIG. 1 illustrates a structure of a light-emitting device of an embodiment;

FIG. 2 illustrates a structure of a light-emitting device of an embodiment;

FIGS. 3A to 3D illustrate structures of a display apparatus of an embodiment;

FIG. 4 illustrates a structure of a display apparatus of an embodiment;

FIGS. 5A and 5B illustrate a structure of a display apparatus of an embodiment;

FIG. 6 illustrates a structure of a display apparatus of an embodiment;

FIGS. 7A to 7C illustrate a structure of a display apparatus of an embodiment;

FIG. 8 illustrates a structure of a display apparatus of an embodiment;

FIG. 9 illustrates a structure of a display module of an embodiment;

FIGS. 10A and 10B illustrate structures of display apparatuses of an embodiment;

FIG. 11 illustrates a structure of a display apparatus of an embodiment;

FIG. 12 illustrates a structure of a display apparatus of an embodiment;

FIG. 13 illustrates a structure of a display apparatus of an embodiment;

FIG. 14 illustrates a structure of a display apparatus of an embodiment;

FIG. 15 illustrates a structure of a display apparatus of an embodiment;

FIG. 16 illustrates a structure of a display module of an embodiment;

FIGS. 17A to 17C illustrate a structure of a display apparatus of an embodiment;

FIG. 18 illustrates a structure of a display apparatus of an embodiment;

FIG. 19 illustrates a structure of a display apparatus of an embodiment;

FIG. 20 illustrates a structure of a display apparatus of an embodiment;

FIG. 21 illustrates a structure of a display apparatus of an embodiment;

FIG. 22 illustrates a structure of a display apparatus of an embodiment;

FIGS. 23A to 23D illustrate examples of electronic devices of an embodiment;

FIGS. 24A to 24F illustrate examples of electronic devices of an embodiment;

FIGS. 25A to 25G illustrate examples of electronic devices of an embodiment;

FIGS. 26A and 26B illustrate a structure of a light-emitting device in Example;

FIG. 27 shows the current density-luminance characteristics of light-emitting devices in Example;

FIG. 28 shows the luminance-current efficiency characteristics of light-emitting devices in Example;

FIG. 29 shows the voltage-luminance characteristics of light-emitting devices in Example;

FIG. 30 shows the voltage-current characteristics of light-emitting devices in Example;

FIG. 31 shows emission spectra of light-emitting devices emitting light at a luminance of 1000 cd/m² in Example;

FIGS. 32A and 32B illustrate a structure of a light-emitting device in Example;

FIG. 33 shows the current density-luminance characteristics of light-emitting devices in Example;

FIG. 34 shows the luminance-current efficiency characteristics of light-emitting devices in Example;

FIG. 35 shows the voltage-luminance characteristics of light-emitting devices in Example;

FIG. 36 shows the voltage-current characteristics of light-emitting devices in Example; and

FIG. 37 shows emission spectra of light-emitting devices emitting light at a luminance of 1000 cd/m² in Example.

### DETAILED DESCRIPTION OF THE INVENTION

A light-emitting device of one embodiment of the present invention includes a first electrode, a second electrode, a first unit, and a first layer. The first unit is positioned between the first electrode and the second electrode and contains a first light-emitting material. The first layer is positioned between the second electrode and the first unit and contains a first organic compound and a second organic compound. The first organic compound has an acid dissociation constant pKₐ larger than or equal to 8, and the second organic compound has no pyridine ring, no phenanthroline ring, or one phenanthroline ring.

Accordingly, the first layer can supply electrons to the first unit. Furthermore, for example, the first layer can be formed without a substance with high activity, such as an alkali metal or an alkaline earth metal. In addition, the resistance to the air or an impurity such as water can be increased. Moreover, a reduction in emission efficiency due to the air or an impurity such as water can be inhibited. As a result, a novel light-emitting device that is highly convenient, useful, or reliable can be provided.

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

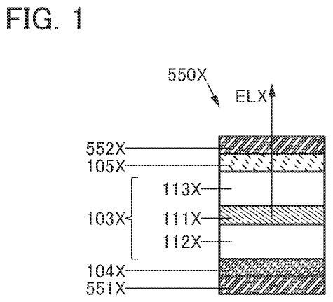

In this embodiment, a structure of a light-emitting device of one embodiment of the present invention will be described with reference to FIG. 1.

FIG. 1 is a cross-sectional view illustrating the structure of the light-emitting device of one embodiment of the present invention.

The structure of a light-emitting device 550X described in this embodiment is applicable to various light sources. Specifically, the structure of the light-emitting device 550X is applicable to a display apparatus, lighting, and the like of one embodiment of the present invention. For example, the description of the structure of the light-emitting device 550X can be referred to for a light-emitting device 550A in Embodiment 5 or Embodiment 6. Specifically, the description of the structure of the light-emitting device 550X can be referred to for the description of the light-emitting device 550A by replacing “X” in the reference numerals with “A”. Similarly, the structure of the light-emitting device 550X is applicable to a light-emitting device 550B or a light-emitting device 550C by replacing “X” with “B” or “C”.

### <Structure Example of Light-Emitting Device>

The light-emitting device 550X described in this embodiment includes an electrode 551X, an electrode 552X, a unit 103X, and a layer 105X. The light-emitting device 550X also includes a layer 104X.

The unit 103X is positioned between the electrode 551X and the electrode 552X and contains a light-emitting material EMX.

The layer 105X is positioned between the electrode 552X and the unit 103X. For example, the layer 105X is in contact with the electrode 552X. The layer 104X is positioned between the unit 103X and the electrode 551X. For example, the layer 104X is in contact with the electrode 551X.

Note that the details of a structure applicable to the unit 103X will be described in Embodiment 2. The details of structures applicable to the electrode 551X and the layer 104X will be described in Embodiment 3.

### <<Structure Example of Electrode 552X>>

A conductive material can be used for the electrode 552X, for example. Specifically, a single layer or a stack using a film containing a metal, an alloy, or a conductive compound can be used for the electrode 552X.

For example, a film that efficiently reflects light can be used for the electrode 552X. Specifically, an alloy containing silver, copper, and the like, an alloy containing silver, palladium, and the like, or a metal film of aluminum or the like can be used for the electrode 552X.

For example, a metal film that transmits part of light and reflects the other part of the light can be used for the electrode 552X. Thus, the light-emitting device 550X can have a microcavity structure. Alternatively, light with a predetermined wavelength can be extracted more efficiently than light with the other wavelengths. Alternatively, light with a narrow full width at half maximum of a spectrum can be extracted. Alternatively, light of a bright color can be extracted.

For example, a film having a property of transmitting visible light can be used for the electrode 552X. Specifically, a single layer or a stack using a metal film, an alloy film, a conductive oxide film, or the like that is thin enough to transmit light can be used for the electrode 552X.

For example, a conductive oxide containing indium can be used. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

For another example, a conductive oxide containing zinc can be used. Specifically, zinc oxide, zinc oxide to which gallium is added, zinc oxide to which aluminum is added, or the like can be used.

For example, gold (Au), platinum (Pt), nickel (Ni), tungsten (W), chromium (Cr), molybdenum (Mo), iron (Fe), cobalt (Co), copper (Cu), palladium (Pd), or a nitride of a metal material (e.g., titanium nitride) can be used. Graphene can also be used.

In particular, a material having a lower work function than the electrode 551X can be suitably used for the electrode 552X. Specifically, a material having a work function lower than or equal to 3.8 eV is preferably used.

For example, an element belonging to Group 1 of the periodic table, an element belonging to Group 2 of the periodic table, a rare earth metal, or an alloy containing any of these elements can be used for the electrode 552X.

Specifically, an element such as lithium (Li) or cesium (Cs), an element such as magnesium (Mg), calcium (Ca), or strontium (Sr), an element such as europium (Eu) or ytterbium (Yb), or an alloy containing any of these elements, such as an alloy of magnesium and silver or an alloy of aluminum and lithium, can be used for the electrode 552X.

### <<Structure Example of Layer 105X>>

The layer 105X contains an organic compound OCX and an organic compound ETMX. Note that a substance having a high electron-transport property can be used as the organic compound ETMX. In a substance having a high electron-transport property, electron mobility is higher than hole mobility. Specifically, the electron mobility is preferably higher than or equal to 1×10⁻⁷ cm²/Vs, further preferably higher than or equal to 1×10⁻⁶ cm²/Vs in the case where the square root of the electric field strength [V/cm] is 600. As the organic compound having a high electron-transport property, a heteroaromatic compound can be used, for example. The heteroaromatic compound refers to a cyclic compound containing at least two different kinds of elements in a ring. Examples of cyclic structures include a three-membered ring, a four-membered ring, a five-membered ring, and a six-membered ring, among which a five-membered ring and a six-membered ring are particularly preferable. The elements contained in the heteroaromatic compound are preferably one or more of nitrogen, oxygen, sulfur, and the like, in addition to carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and an organic compound having a π-electron deficient heteroaromatic ring including the nitrogen-containing heteroaromatic compound, is preferably used.

### [Organic Compound OCX]

A material having an acid dissociation constant pKₐ larger than or equal to 8 can be used as the organic compound OCX, for example. A material having an acid dissociation constant pKₐ larger than or equal to 12 is preferably used as the organic compound OCX.

A material having a large acid dissociation constant pKₐ has a large dipole moment. A material having a large dipole moment interacts with a hole. When a material having an acid dissociation constant pKₐ larger than or equal to 8 is used as the organic compound OCX, for example, the organic compound OCX interacts with a hole and the hole-transport property of the layer 105X can be significantly reduced.

In addition, a material having a large acid dissociation constant pKₐ has high nucleophilicity. A material having high nucleophilicity may react with a molecule, which has received a hole and become a cation radical, to generate a new molecule or a new intermediate state. When a material having an acid dissociation constant pKₐ larger than or equal to 8 is used as the organic compound OCX, for example, the organic compound OCX generates a new molecule or a new intermediate state and the hole-transport property of the layer 105X can be significantly reduced.

Some holes that have reached the layer 105X from the electrode 551X through the unit 103X remain at the interface between the unit 103X and the layer 105X or in the layer 105X. This attracts electrons from the electrode 552X so that an electric double layer is formed on the electrode 552X side of the layer 105X. Thus, a vacuum level between the layer 105X and the electrode 552X is distorted, and electrons are supplied from the electrode 552X to the layer 105X and then supplied to the unit 103X from the layer 105X.

Note that a material having a large acid dissociation constant pKₐ has high water solubility. When a material having an acid dissociation constant pKₐ larger than or equal to 8 is used as the organic compound OCX, for example, the water resistance of the layer 105X is lowered and a problem such as peeling of the layer 105X from another layer occurs in the fabrication process. This might cause a defect in the light-emitting device. Using the organic compound ETMX together with the organic compound OCX can improve the water resistance of the layer 105X. The organic compound ETMX will be described in detail later.

As an organic compound having a large acid dissociation constant pKₐ, an organic compound having a pyrrolidine skeleton, a piperidine skeleton, or a hexahydropyrimidopyrimidine skeleton is preferably used. An organic compound having a guanidine skeleton is preferably used. Specific examples include organic compounds having basic skeletons represented by Structural Formulae (120) to (123) below.

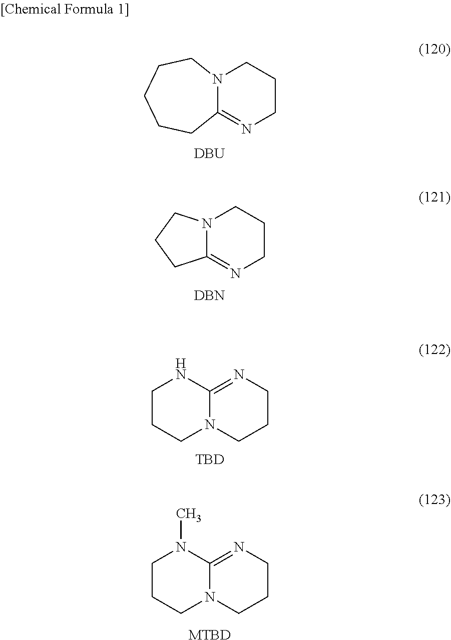

It is preferable that the organic compound having an acid dissociation constant pKₐ larger than or equal to 8 be specifically an organic compound that has a bicyclo ring structure having 2 or more nitrogen atoms in the bicyclo ring and a heteroaromatic hydrocarbon ring having 2 to 30 carbon atoms in the ring or an aromatic hydrocarbon ring having 6 to 30 carbon atoms in the ring, and more specifically be an organic compound that has a 1,3,4,6,7,8-hexahydro-2H-pyrimido[1,2-a]pyrimidine skeleton and a heteroaromatic hydrocarbon ring having 2 to 30 carbon atoms in the ring or an aromatic hydrocarbon ring having 6 to 30 carbon atoms in the ring. An organic compound that has a bicyclo ring structure having 2 or more nitrogen atoms in the bicyclo ring and a heteroaromatic hydrocarbon ring having 2 to 30 carbon atoms in the ring, more specifically an organic compound that has a 1,3,4,6,7,8-hexahydro-2H-pyrimido[1,2-a]pyrimidine skeleton and a heteroaromatic hydrocarbon ring having 2 to 30 carbon atoms in the ring is further preferred.

Further specifically, an organic compound represented by General Formula (G1) below is preferred.

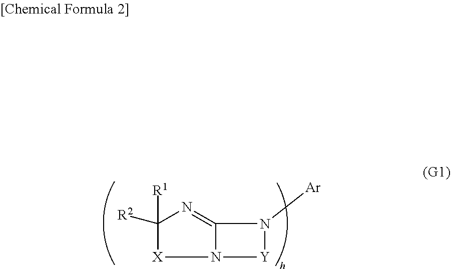

In the organic compound represented by General Formula (G1) above, X represents a group represented by General Formula (GT-1) below, and Y represents a group represented by General Formula (GT-2) below. Furthermore, R¹ and R² each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Note that Ar preferably represents the substituted or unsubstituted heteroaromatic hydrocarbon ring having 2 to 30 carbon atoms in the ring.

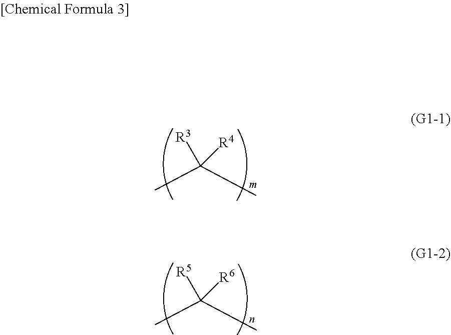

In General Formulae (G1-1) and (G1-2) above, R³ to R⁶ each independently represent hydrogen or deuterium, m represents an integer of 0 to 4, n represents an integer of 1 to 5, and m+1≥n (m+1 is greater than or equal to n) is satisfied. In the case where m or n is 2 or more, R³s may be the same or different from each other, and the same applies to R⁴s, R⁵s, and R⁶s.

The organic compound represented by General Formula (G1) above is preferably any one of compounds represented by General Formulae (G2-1) to (G2-6) below.

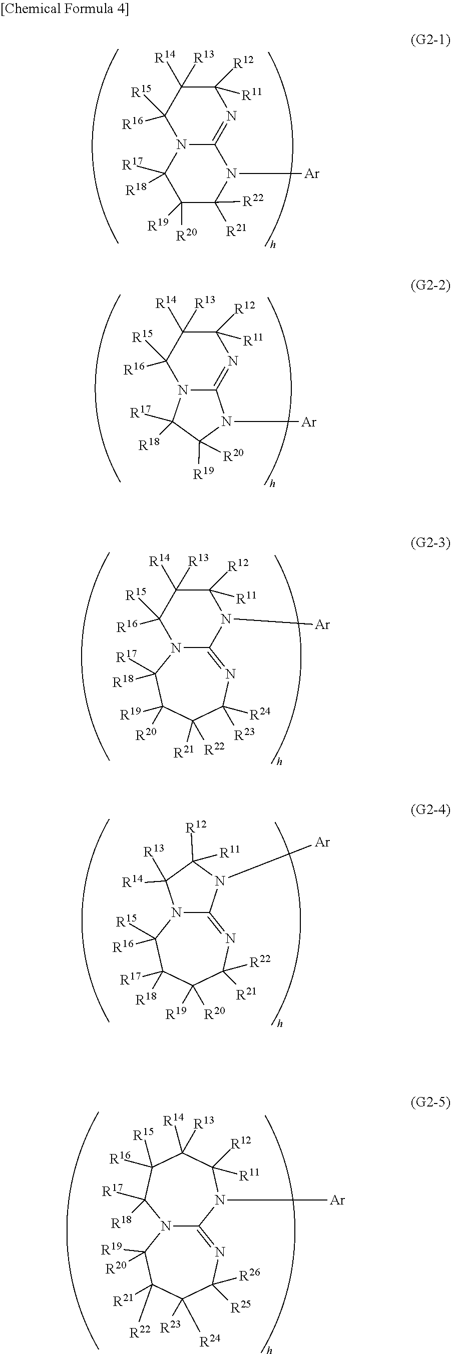

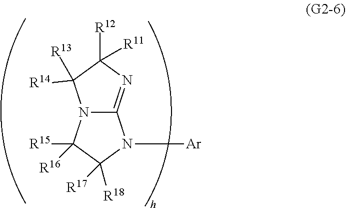

Note that R¹¹ to R²⁶ each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Note that Ar preferably represents the substituted or unsubstituted heteroaromatic hydrocarbon ring having 2 to 30 carbon atoms in the ring.

In General Formula (G1) and General Formulae (G2-1) to (G2-6) above, the substituted or unsubstituted heteroaromatic hydrocarbon ring having 2 to 30 carbon atoms in the ring or the substituted or unsubstituted aromatic hydrocarbon ring having 6 to 30 carbon atoms in the ring that is represented by Ar is specifically a pyridine ring, a bipyridine ring, a pyrimidine ring, a bipyrimidine ring, a pyrazine ring, a bipyrazine ring, a triazine ring, a quinoline ring, an isoquinoline ring, a benzoquinoline ring, a phenanthroline ring, a quinoxaline ring, a benzoquinoxaline ring, a dibenzoquinoxaline ring, an azofluorene ring, a diazofluorene ring, a carbazole ring, a benzocarbazole ring, a dibenzocarbazole ring, a dibenzofuran ring, a benzonaphthofuran ring, a dinaphthofuran ring, a dibenzothiophene ring, a benzonaphthothiophene ring, a dinaphthothiophene ring, a benzofuropyridine ring, a benzofuropyrimidine ring, a benzothiopyridine ring, a benzothiopyrimidine ring, a naphthofuropyridine ring, a naphthofuropyrimidine ring, a naphthothiopyridine ring, a naphthothiopyrimidine ring, an acridine ring, a xanthene ring, a phenothiazine ring, a phenoxazine ring, a phenazine ring, a triazole ring, an oxazole ring, an oxadiazole ring, a thiazole ring, a thiadiazole ring, an imidazole ring, a benzimidazole ring, a pyrazole ring, a pyrrole ring, or the like. In General Formula (G1) and General Formulae (G2-1) to (G2-6) above, the substituted or unsubstituted aromatic hydrocarbon ring having 6 to 30 carbon atoms in the ring that is represented by Ar is specifically a benzene ring, a naphthalene ring, a fluorene ring, a dimethylfluorene ring, a diphenylfluorene ring, a spirofluorene ring, an anthracene ring, a phenanthrene ring, a triphenylene ring, a pyrene ring, a tetracene ring, a chrysene ring, a benzo[a]anthracene ring, or the like. It is especially preferable that Ar be represented by any one of Structural Formulae (Ar-1) to (Ar-27) below.

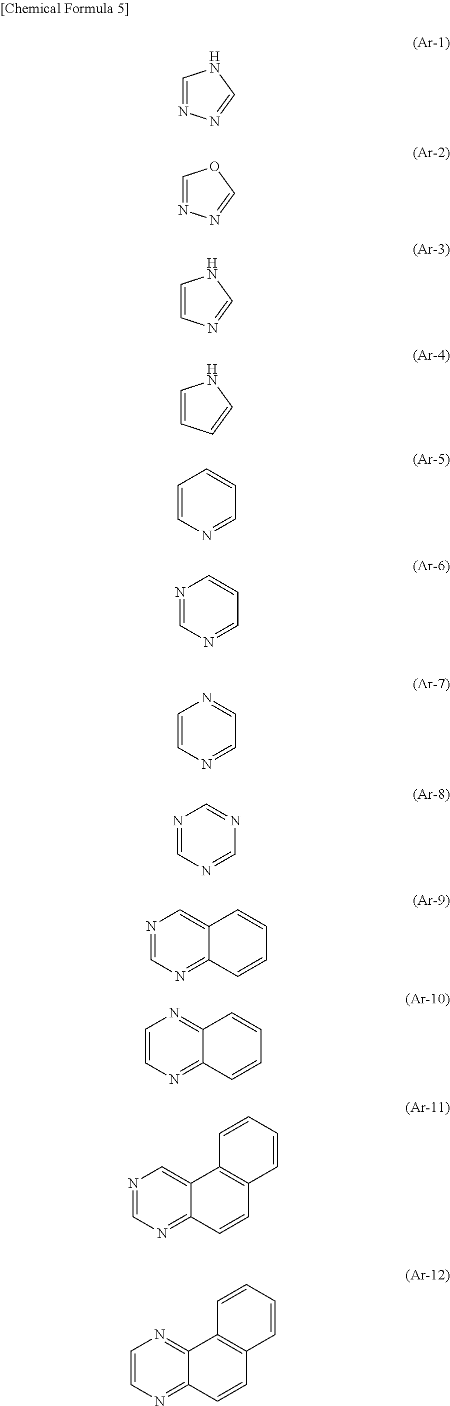

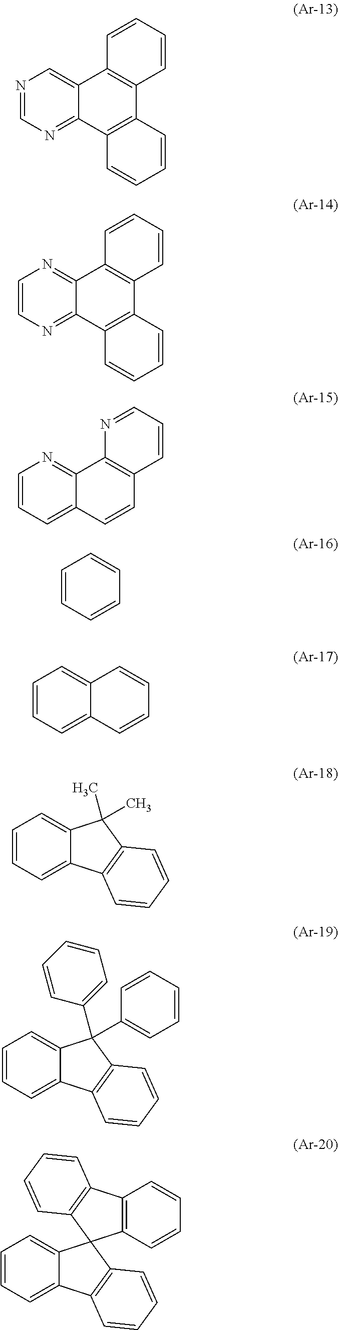

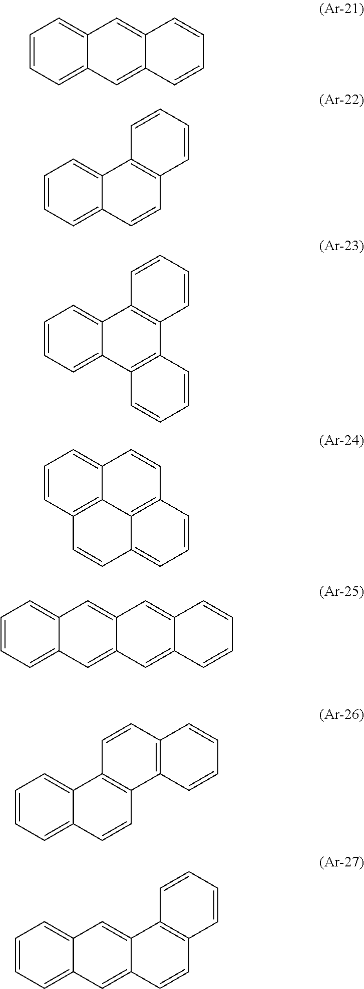

Note that Ar preferably has a nitrogen atom in its ring and is preferably bonded to the skeleton within parentheses in General Formula (G1) by a bond of the nitrogen atom or a carbon atom adjacent to the nitrogen atom.

Specific examples of the organic compounds represented by General Formula (G1) and General Formulae (G2-1) to (G2-6) above include organic compounds represented by Structural Formulae (101) to (117) below, such as 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF) (Structural Formula 108) and 1-(9,9′-spirobi[9H-fluoren]-2-yl)-1,3,4,6,7,8-hexahydro-2H-pyrimido[1,2-a]pyrimidine (abbreviation: 2hppSF) (Structural Formula 109).

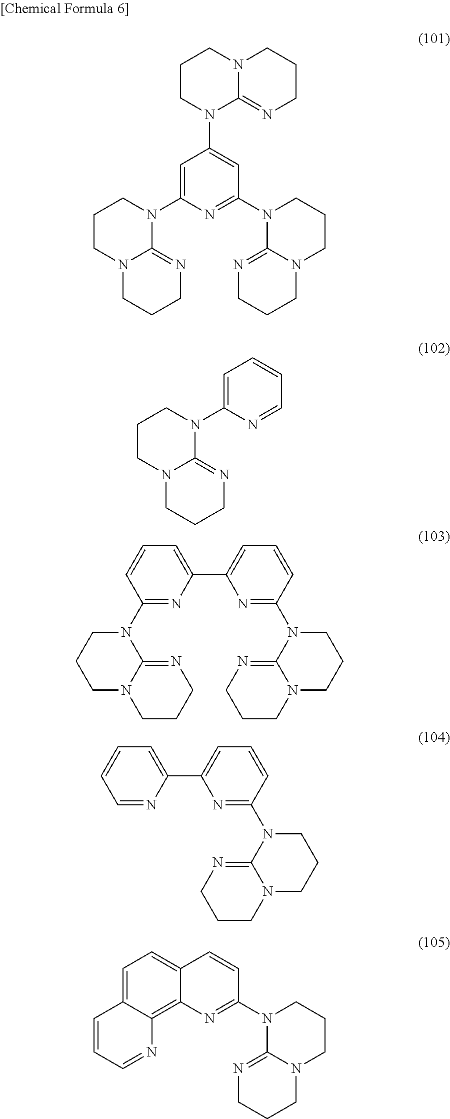

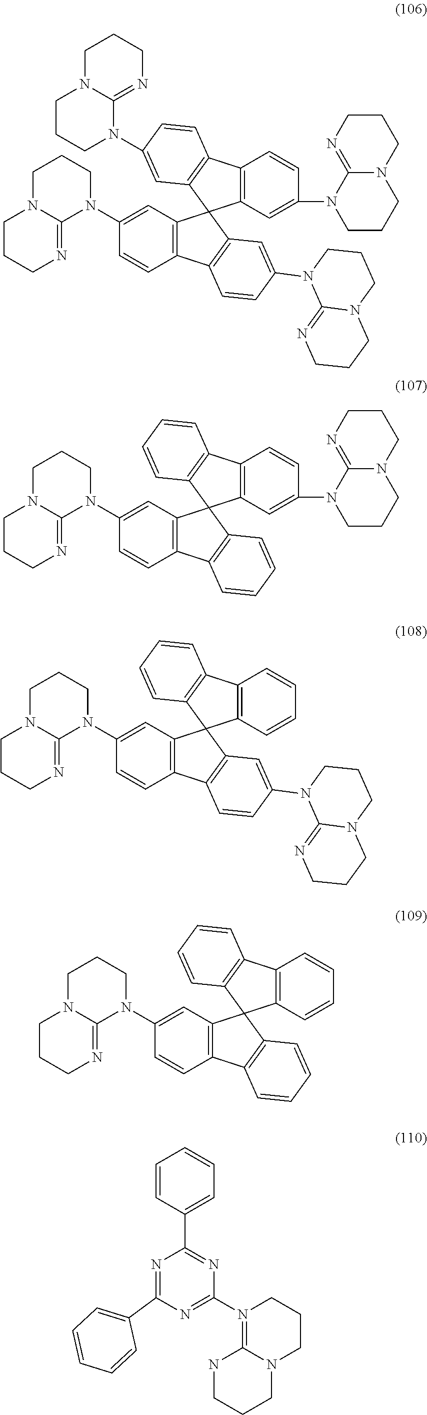

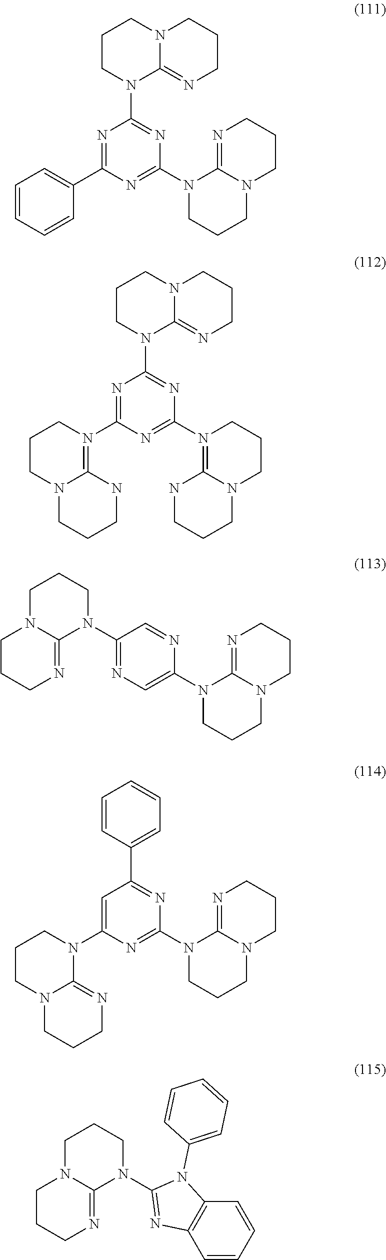

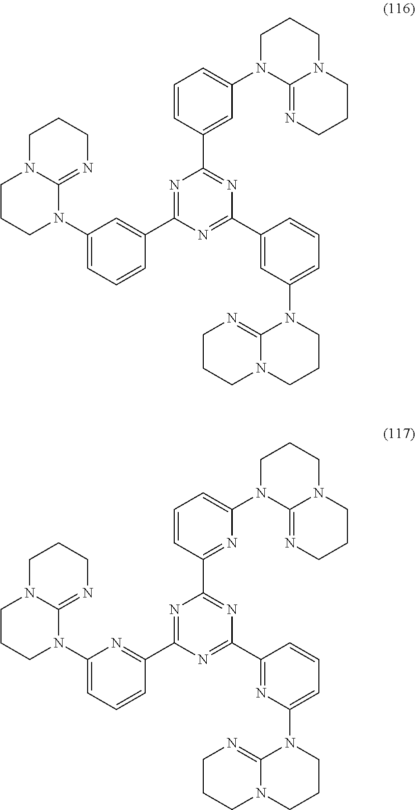 [SMILES: c1cc(-c2nc(-c3cccc(N4CCCN5CCCN=C54)c3)nc(-c3cccc(N4CCCN5CCCN=C54)c3)n2)cc(N2CCCN3CCCN=C32)c1 ; c1cc(-c2nc(-c3cccc(N4CCCN5CCCN=C54)n3)nc(-c3cccc(N4CCCN5CCCN=C54)n3)n2)nc(N2CCCN3CCCN=C32)c1]

Unlike an alkali metal, an alkaline earth metal, or a compound thereof, these organic compounds do not have a concern about metal contamination in a production line and can be easily evaporated as well as being stable, for example, and thus can be suitably used in light-emitting devices formed through a photolithography process. Needless to say, these organic compounds can be suitably used also in light-emitting devices formed not through a photolithography process.

It is preferable that the strongly basic substance having an acid dissociation constant pKₐ larger than or equal to 8 not have a skeleton with an electron-transport property so that electrons injected from the electrode 552X into the layer 105X and holes injected from the unit 103X and then blocked by the layer 105X can be inhibited from recombining on the strongly basic substance having an acid dissociation constant pKₐ larger than or equal to 8. As the strongly basic substance having an acid dissociation constant pKₐ larger than or equal to 8, an organic compound such as 1-(9,9′-spirobi[9H-fluoren]-2-yl)-1,3,4,6,7,8-hexahydro-2H-pyrimido[1,2-a]pyrimidine (abbreviation: 2hppSF), 2,9-bis(1,3,4,6,7,8-hexahydro-2H-pyrimido[1,2-a]pyrimidin-1-yl)-1,10-phenanthroline (abbreviation: 2,9hpp2Phen), 4,7-di-1-pyrrolidinyl-1,10-phenanthroline (abbreviation: Pyrrd-Phen), or 8,8′-pyridine-2,6-diyl-bis(5,6,7,8-tetrahydroimidazo[1,2-a]pyrimidine) (abbreviation: 2,6tip2Py) can be specifically used, for example.

A nitrogen-containing heterocyclic compound having a guanidine skeleton can be used as the organic compound OCX, for example. Specifically, an organic compound having a 1,3,4,6,7,8-hexahydro-2H-pyrimido[1,2-a]pyrimidine group, an organic compound having a 5,6,7,8-tetrahydroimidazo[1,2-a]pyrimidine group, or a nitrogen-containing heterocyclic compound having a pyrrolidine group can be used as the organic compound OCX.

For example, 1-(9,9′-spirobi[9H-fluoren]-2-yl)-1,3,4,6,7,8-hexahydro-2H-pyrimido[1,2-a]pyrimidine (abbreviation: 2hppSF), 2,9-bis(1,3,4,6,7,8-hexahydro-2H-pyrimido[1,2-a]pyrimidin-1-yl)-1,10-phenanthroline (abbreviation: 2,9hpp2Phen), 4,7-di-1-pyrrolidinyl-1,10-phenanthroline (abbreviation: Pyrrd-Phen), or 8,8′-pyridine-2,6-diyl-bis(5,6,7,8-tetrahydroimidazo[1,2-a]pyrimidine) (abbreviation: 2,6tip2Py) can be used as the organic compound OCX. The structures of 2hppSF, 2,9hpp2Phen, Pyrrd-Phen, and 2,6tip2Py are shown below.

Note that the acid dissociation constants pKₐ of 2hppSF, 2,9hpp2Phen, Pyrrd-Phen, and 2,6tip2Py are 13.95, 13.35, 11.23, and 9.58, respectively.

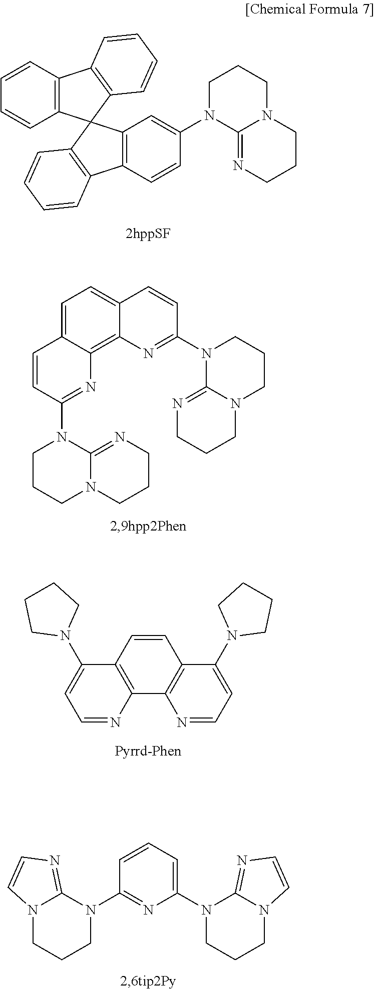 [SMILES: c1ccc2c(c1)-c1ccccc1C21c2ccccc2-c2ccc(N3CCCN4CCCN=C43)cc21 ; c1cc2ccc3ccc(N4CCCN5CCCN=C54)nc3c2nc1N1CCCN2CCCN=C21 ; c1cc(N2CCCC2)c2ccc3c(N4CCCC4)ccnc3c2n1 ; c1cc(N2CCCn3ccnc32)nc(N2CCCn3ccnc32)c1]

It is preferable that the organic compound OCX not have an electron-donating property with respect to the organic compound ETMX. When having an electron-donating property, the organic compound OCX easily reacts with an atmospheric component such as water or oxygen and thus becomes unstable. The layer 105X containing the organic compounds OCX and ETMX of one embodiment of the present invention has an extremely low hole-transport property; thus, the layer 105X can function as an electron-injection layer even though the organic compound OCX does not have an electron-donating property. Thus, an electron-injection layer and alight-emitting device that are stable with respect to an atmospheric component such as water or oxygen can be formed.

### Example 1 of Organic Compound ETMX

The organic compound ETMX has no pyridine ring, no phenanthroline ring, or one phenanthroline ring. For example, a material having no pyridine ring, no phenanthroline ring, or one phenanthroline ring can be used as the organic compound ETMX.

The acid dissociation constants pKₐ of a pyridine molecule and a phenanthroline molecule are 5.25 and 4.8, respectively. An organic compound having a pyridine ring or a phenanthroline ring has high water solubility; the larger the number of pyridine rings or phenanthroline rings is, the higher the water solubility is. For example, an organic compound having no pyridine ring, no phenanthroline ring, or one phenanthroline ring has lower water solubility than an organic compound having two or more pyridine rings or two or more phenanthroline rings.

The water resistance of the layer 105X containing a material having no pyridine ring, no phenanthroline ring, or one phenanthroline ring as the organic compound ETMX can be higher than that of the layer 105X containing an organic compound having two or more pyridine rings or two or more phenanthroline rings as the organic compound ETMX. Moreover, occurrence of a problem such as peeling of the layer 105X from another layer in the fabrication process can be inhibited. Accordingly, occurrence of a problem that causes a defect in a light-emitting device can be inhibited.

As the organic compound ETMX, any of the following compounds can be used, for example: 9-(1-naphthyl)-10-[4-(2-naphthyl)phenyl]anthracene (abbreviation: αN-PNPAnth), 2,9-di(naphthalen-2-yl)-4,7-diphenyl-1,10-phenanthroline (abbreviation: NBPhen), 9-[3′-(dibenzothiophen-4-yl)biphenyl-3-yl]naphtho[1′,2′:4,5]furo[2,3-b]pyrazine (abbreviation: 9mDBtBPNfpr), 8-(biphenyl-4-yl)-4-[3-(dibenzothiophen-4-yl)phenyl]-[1]benzofuro[3,2-d]pyrimidine (abbreviation: 8BP-4mDBtPBfpm), 9-[3-(4,6-diphenyl-1,3,5-triazin-2-yl)phenyl]-9′-phenyl-2,3′-bi-9H-carbazole (abbreviation: mPCCzPTzn-02), 4,8-bis[3-(dibenzothiophen-4-yl)phenyl]-[1]benzofuro[3,2-d]pyrimidine (abbreviation: 4,8mDBtP2Bfpm), 4-[3,5-bis(9H-carbazol-9-yl)phenyl]-2-phenyl-6-(biphenyl-4-yl)pyrimidine (abbreviation: 6BP-4Cz2PPm), 2-[3-(3′-dibenzothiophen-4-yl)biphenyl]dibenzo[f,h]quinoxaline (abbreviation: 2mDBTBPDBq-II), 11-[4-(biphenyl-4-yl)-6-phenyl-1,3,5-triazin-2-yl]-11,12-dihydro-12-(biphenyl-4-yl)indolo[2,3-a]carbazole (abbreviation: BP-BPIcz(II)Tzn), and 11-[(3′-dibenzothiophen-4-yl)biphenyl-3-yl]phenanthro[9′,10′:4,5]furo[2,3-b]pyrazine (abbreviation: 11mDBtBPPnfpr). Their structural formulae are shown below.

Note that none of αN-PNPAnth, 9mDBtBPNfpr, 8BP-4mDBtPBfpm, mPCCzPTzn-02, 4,8mDBtP2Bfpm, 6BP-4Cz2PPm, 2mDBTBPDBq-II, BP-BPIcz(II)Tzn, and 11mDBtBPPnfpr have a pyridine ring or a phenanthroline ring. In addition, NBPhen has one phenanthroline ring.

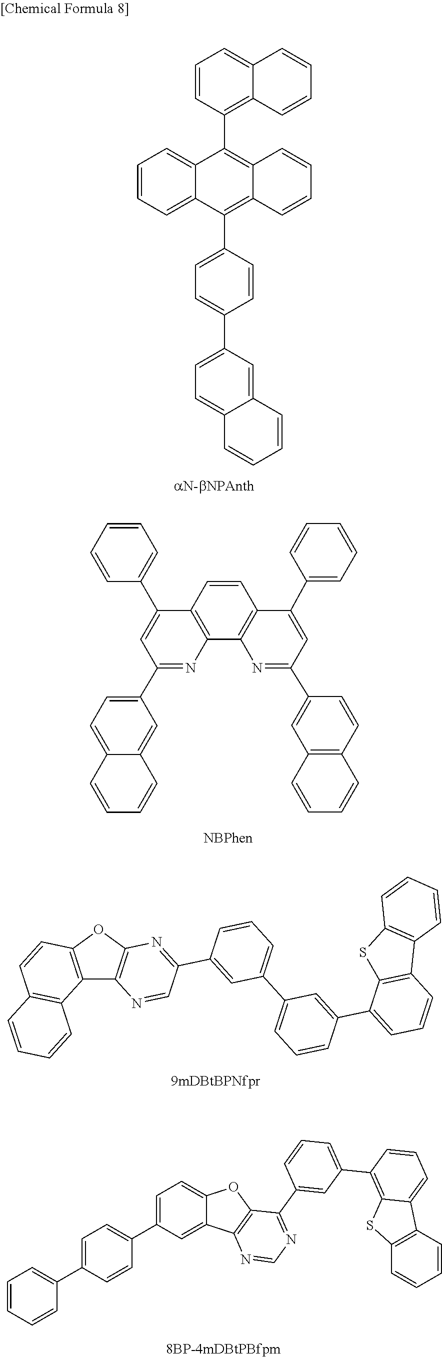

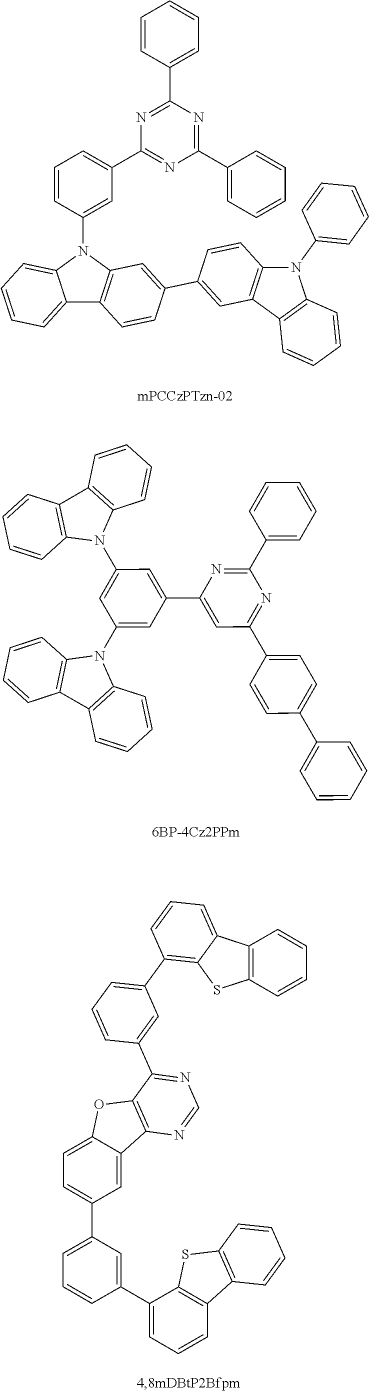 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1cc(-c2ccc3oc4c(-c5cccc(-c6cccc7c6sc6ccccc67)c5)ncnc4c3c2)cc(-c2cccc3c2sc2ccccc23)c1]

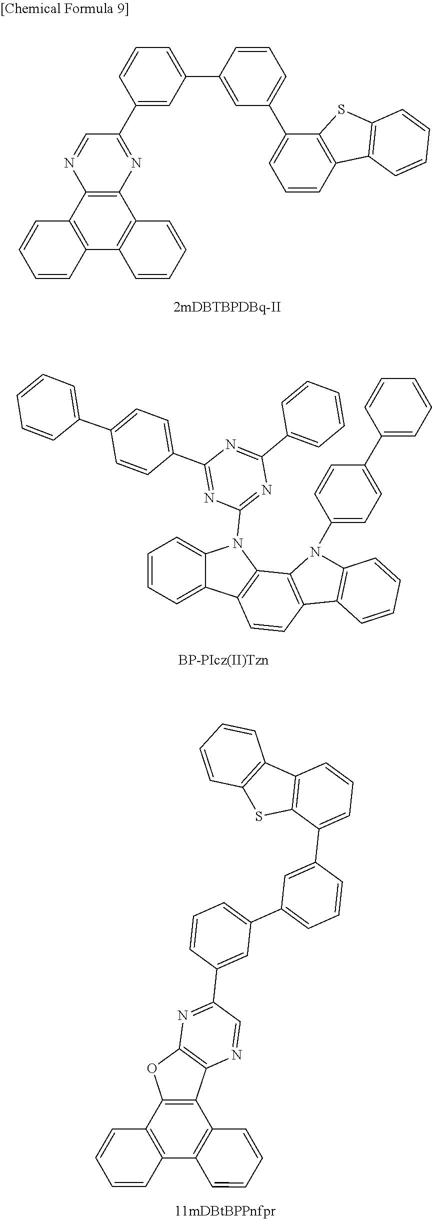 [SMILES: c1cc(-c2cccc(-c3cccc4c3sc3ccccc34)c2)cc(-c2cnc3c4ccccc4c4ccccc4c3n2)c1 ; c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1 ; c1cc(-c2cccc(-c3cccc4c3sc3ccccc34)c2)cc(-c2cnc3c(n2)oc2c4ccccc4c4ccccc4c32)c1]

### Example 2 of Organic Compound ETMX

A material having an acid dissociation constant pKₐ smaller than 4 can be used as the organic compound ETMX, for example. An organic compound having an acid dissociation constant pKₐ smaller than 4 has lower water solubility than an organic compound having an acid dissociation constant pKₐ larger than or equal to 4, for example. The water resistance of the layer 105X containing a material having an acid dissociation constant pKₐ smaller than 4 as the organic compound ETMX can be higher than that of the layer 105X containing an organic compound having an acid dissociation constant pKₐ larger than or equal to 4 as the organic compound ETMX. Moreover, occurrence of a problem such as peeling of the layer 105X from another layer in the fabrication process can be inhibited. Accordingly, occurrence of a problem that causes a defect in a light-emitting device can be inhibited.

For example, αN-PNPAnth, 9mDBtBPNfpr, 8BP-4mDBtPBfpm, mPCCzPTzn-02, 4,8mDBtP2Bfpm, 6BP-4Cz2PPm, 2mDBTBPDBq-II, BP-BPIcz(II)Tzn, or 11mDBtBPPnfpr can be used as the organic compound ETMX.

Note that the acid dissociation constants pKₐ of 4,8mDBtP2Bfpm and 11mDBtBPPnfpr are 0.60 and −1.85, respectively. In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound. For example, among the skeletons of 11mDBtBPPnfpr, a pyrazine skeleton has the largest acid dissociation constant pKₐ. Note that the acid dissociation constant of a pyrazine molecule is 0.37.

The acid dissociation constant pKₐ is calculated by the following calculation method.

As the initial molecular structure in each molecule that is a calculation model, the most stable structure (singlet ground state) obtained from the first-principles calculation is used.

For the first-principles calculation, Jaguar, which is the quantum chemical computational software produced by Schrodinger, Inc., is used, and the most stable structure in the singlet ground state is calculated by the density functional theory (DFT). As a basis function, 6-31G** is used, and as a functional, B3LYP-D3 is used. The structure subjected to quantum chemical calculation is sampled by conformational analysis in mixed torsional/low-mode sampling with Maestro GUI produced by Schrodinger, Inc.

In the calculation of pKₐ, one or more atoms in each molecule are designated as basic sites, Macro Model is used to search for the stable structure of the protonated molecule in water, conformational search is performed with OPLS2005 force field, and a conformational isomer having the lowest energy is used. Jaguar's pKₐ calculation module is used. After structure optimization is performed by B3LYP/6-31G*, single point calculation is performed by cc-pVTZ(+) and the pKₐ value is calculated using empirical correction for functional group(s). For the molecule with one or more atoms designated as basic sites, the largest pKₐ value among the obtained results is employed. The obtained pKₐ values are shown below.

TABLE 1

| | Acid |
|---|---|
| | dissociation |
| | constant pK ₐ |
| 2hppSF | 13.95 |
| 4,8mDBtP2Bfpm | 0.60 |
| 11mDBtBPPnfpr | −1.85 |

### Example 3 of Organic Compound ETMX

A material having a polarization term δₚ of a solubility parameter δ of less than or equal to 4.0 MPa^{0.5} can be used as the organic compound ETMX, for example. An organic compound having a polarization term δₚ of a solubility parameter δ of less than or equal to 4.0 MPa^{0.5} has lower water solubility than an organic compound having a polarization term δₚ of a solubility parameter δ of greater than 4.0 MPa^{0.5}, for example. The water resistance of the layer 105X containing a material having a polarization term δₚ less than or equal to 4.0 MPa^{0.5} as the organic compound ETMX can be higher than that of the layer 105X containing an organic compound having a polarization term δₚ greater than 4.0 MPa^{0.5} as the organic compound ETMX. Moreover, occurrence of a problem such as peeling of the layer 105X from another layer in the fabrication process can be inhibited. Accordingly, occurrence of a problem that causes a defect in a light-emitting device can be inhibited.

For example, αN-PNPAnth, NBPhen, 9mDBtBPNfpr, 8BP-4mDBtPBfpm, mPCCzPTzn-02, 4,8mDBtP2Bfpm, 6BP-4Cz2PPm, 2mDBTBPDBq-II, BP-BPIcz(II)Tzn, or 11mDBtBPPnfpr can be used as the organic compound ETMX.

Note that the polarization terms δₚ of the solubility parameters δ of αN-PNPAnth, NBPhen, 9mDBtBPNfpr, 8BP-4mDBtPBfpm, mPCCzPTzn-02, 6BP-4Cz2PPm, 4,8mDBtP2Bfpm, 2mDBTBPDBq-II, BP-BPIcz(II)Tzn, and 11mDBtBPPnfpr are 4.0 MPa^{0.5}, 4.0 MPa^{0.5}, 3.8 MPa^{0.5}, 3.5 MPa^{0.5}, 3.5 MPa^{0.5}, 3.4 MPa^{0.5}, 3.4 MPa^{0.5}, 3.2 MPa^{0.5}, 3.2 MPa^{0.5}, and 3.1 MPa^{0.5}, respectively.

The polarization term δₚ of the solubility parameter δ is calculated by the following calculation method.

As the classical molecular dynamics calculation software, Desmond produced by Schrodinger, Inc. is used. Furthermore, the OPLS2005 force field is used. The calculation is performed with Apollo 6500 produced by Hewlett Packard Enterprise Development.

As a calculation model, a standard cell containing approximately 32 molecules is used. As the initial molecular structure of each of the materials, the most stable structures (singlet ground states) obtained from the first-principles calculation and structures having energy close to that of the most stable structures are mixed in equal proportions and randomly arranged such that molecules do not collide. Then, by Monte Carlo simulated annealing using the OPLS2005 force field, the structures are randomly moved and rotated to move the molecules. Furthermore, the molecules are moved toward the center of the standard cell to maximize the density, so that the initial arrangement is obtained.

For the first-principles calculation, Jaguar, which is the quantum chemical computational software, is used, and the most stable structure in the singlet ground state is calculated by the density functional theory (DFT). As a basis function, 6-31G** is used, and as a functional, B3LYP-D3 is used. The structure subjected to quantum chemical calculation is sampled by conformational analysis in mixed torsional/low-mode sampling with Maestro GUI produced by Schrodinger, Inc. The calculation is performed with Apollo 6500 produced by Hewlett Packard Enterprise Development.

The aforementioned initial arrangement is subjected to Brownian motion simulation and then defined in an NVT ensemble; subsequently, calculation in an NPT ensemble is performed for an enough relaxation time (30 ns) under the conditions of 1 atm and 300 K with respect to time steps that reproduce molecular vibration (2 fs), so that an amorphous solid is calculated. The solubility parameter δ of the obtained amorphous solid is defined by the following formula.

$$δ = {( \frac{Δ Hv - RT}{Vm} )}^{1 / 2} \qquad [ Formula 1 ]$$

Here, ΔHv represents heat of evaporation obtained by subtracting total energy of individual molecules averaged in the whole molecular dynamics calculation from energy of the standard cell, Vm represents the molar volume, R represents the gas constant, and T represents the temperature. Note that there is a tendency for the solubility of a solute to decrease as the difference in the solubility parameter increases between a substance serving as a solvent and a substance serving as the solute.

The solubility parameter δ can be separated into a diffusion term δ_{d} and a polarization term δₚ. The Van der Waals interaction contributes to the diffusion term δ_{d}, and the electrostatic interaction contributes to the polarization term δₚ. In particular, the electrostatic interaction between a solute and the dipoles of a water molecule greatly contributes to the water solubility of the solute. The water solubility of a material that can be used as the organic compound ETMX actually correlates well with the calculated polarization term δₚ of the solubility parameter δ.

The calculated polarization terms δₚ of the solubility parameters δ are shown in a table below. Note that the value disclosed in Japanese Published Patent Application No. 2017-173056 is cited as the polarization term δₚ of the solubility parameter δ of water.

TABLE 2

| | Polarization term δₚ of |
|---|---|
| | solubility parameter |
| | (MPa^{0.5}) |
| 2hppSF | 6.5 |
| αN-βNP Anth | 4.0 |
| NBPhen | 4.0 |
| 9mDBtBPNfpr | 3.8 |
| 8BP-4mDBtPBfpm | 3.5 |
| mPCCzPTzn-02 | 3.5 |
| 6BP-4Cz2PPm | 3.4 |
| 4,8mDBtP2Bfpm | 3.4 |
| 2mDBTBPDBq-II | 3.2 |
| BP-BPIcz(II)Tzn | 3.2 |
| 11mDBtBPPnfpr | 3.1 |
| Water | 16.0 |

The organic compound having a larger difference in the polarization term δₚ of the solubility parameter δ from water serving as a solvent in the above table has a lower water solubility.

### <<Structure Example 2 of Layer 105X>>

It is preferable that a small signal or no signal be observed by electron spin resonance (ESR) spectroscopy in the layer 105X. For example, the spin density attributed to a signal observed at a g-factor of around 2.00 is preferably lower than or equal to 1×10¹⁷ spins/cm³, further preferably lower than 1×10¹⁶ spins/cm³. Note that a film of the materials used for the layer 105X is formed over a quartz substrate to obtain a sample and the spin density of the film can be measured by ESR spectroscopy. For example, the measurement can be performed with an ESR spectrometer E500 (produced by Bruker Corporation) at room temperature under the conditions where the resonance frequency is 9.56 GHz, the output power is 1 mW, the modulated magnetic field is 50 mT, the modulation width is 0.5 mT, the time constant is 0.04 s, and the sweep time is 1 min. For another example, the measurement can be performed with an ESR spectrometer JES FA300 (produced by JEOL Ltd.) at room temperature under the conditions where the resonance frequency is 9.18 GHz, the output power is 1 mW, the modulated magnetic field is 50 mT, the modulation width is 0.5 mT, the time constant is 0.03 s, and the sweep time is 1 min. This method can be employed for observing a signal in the layer 105X by ESR spectroscopy.

Thus, the layer 105X can supply electrons to the unit 103X. For example, the layer 105X can be formed without a substance with high activity, such as an alkali metal or an alkaline earth metal. In addition, the resistance to the air or an impurity such as water can be increased. Moreover, a reduction in emission efficiency due to the air or an impurity such as water can be inhibited. As a result, a novel light-emitting device that is highly convenient, useful, or reliable can be provided.

This embodiment can be combined with any of the other embodiments in this specification as appropriate.

### Embodiment 2

In this embodiment, the structure of the light-emitting device 550X of one embodiment of the present invention will be described with reference to FIG. 1.

FIG. 1 is the cross-sectional view illustrating the structure of the light-emitting device of one embodiment of the present invention.

### <Structure Example of Light-Emitting Device 550X>

The light-emitting device 550X described in this embodiment includes the electrode 551X, the electrode 552X, and the unit 103X. The electrode 552X overlaps with the electrode 551X, and the unit 103X is positioned between the electrode 552X and the electrode 551X.

### <Structure Example of Unit 103X>

The unit 103X has a single-layer structure or a stacked-layer structure. For example, the unit 103X includes a layer 111X, a layer 112X, and a layer 113X (see FIG. 1). The unit 103X has a function of emitting light ELX.

The layer 111X is positioned between the layer 113X and the layer 112X, the layer 113X is positioned between the electrode 552X and the layer 111X, and the layer 112X is positioned between the layer 111X and the electrode 551X.

For example, a layer selected from functional layers such as a light-emitting layer, a hole-transport layer, an electron-transport layer, and a carrier-blocking layer can be used for the unit 103X. A layer selected from functional layers such as a hole-injection layer, an electron-injection layer, an exciton-blocking layer, and a charge-generation layer can also be used for the unit 103X.

### <<Structure Example of Layer 112X>>

A hole-transport material can be used for the layer 112X, for example. The layer 112X can be referred to as a hole-transport layer. A material having a wider band gap than a light-emitting material contained in the layer 111X is preferably used for the layer 112X. In that case, transfer of energy from excitons generated in the layer 111X to the layer 112X can be inhibited.

### [Hole-Transport Material]

A material having a hole mobility of 1×10⁻⁶ cm²/Vs or higher can be suitably used as the hole-transport material.

As the hole-transport material, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds are highly reliable and have high hole-transport properties to contribute to a reduction in driving voltage.

The following are examples that can be used as a compound having an aromatic amine skeleton: 4,4′-bis[N-(1-naphthyl)-N-phenylamino]biphenyl (abbreviation: NPB), N,N-diphenyl-N,N′-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP) can be used.

As a compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV) can be used.

As a compound having a furan skeleton, for example, 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II) can be used.

### <<Structure Example of Layer 113X>>

An electron-transport material, a material having an anthracene skeleton, and a mixed material can be used for the layer 113X, for example. The layer 113X can be referred to as an electron-transport layer. A material having a wider band gap than the light-emitting material contained in the layer 111X is preferably used for the layer 113X. In that case, transfer of energy from excitons generated in the layer 111X to the layer 113X can be inhibited.

### [Electron-Transport Material]

For example, a material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. In this case, the electron-transport property in the electron-transport layer can be suppressed. The amount of electrons injected into the light-emitting layer can be controlled. The light-emitting layer can be prevented from having excess electrons.

For example, a metal complex or an organic compound having a π-electron deficient heteroaromatic ring skeleton can be used as the electron-transport material.

As a metal complex, bis(10-hydroxybenzo[h]quinolinato)beryllium(II) (abbreviation: BeBq2), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ) can be used, for example.

As an organic compound having a π-electron deficient heteroaromatic ring skeleton, a heterocyclic compound having a polyazole skeleton, a heterocyclic compound having a diazine skeleton, a heterocyclic compound having a pyridine skeleton, a heterocyclic compound having a triazine skeleton, or the like can be used, for example. In particular, the heterocyclic compound having a diazine skeleton or the heterocyclic compound having a pyridine skeleton has high reliability and thus is preferable. In addition, the heterocyclic compound having a diazine (pyrimidine or pyrazine) skeleton has a high electron-transport property to contribute to a reduction in driving voltage.

As a heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II) can be used, for example.

As a heterocyclic compound having a diazine skeleton, 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,8-bis[3-(dibenzothiophen-4-yl)phenyl]benzo[h]quinazoline (abbreviation: 4,8mDBtP2Bqn) can be used, for example.

As a heterocyclic compound having a pyridine skeleton, 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB) can be used, for example.

As a heterocyclic compound having a triazine skeleton, 2-[3′-(9,9-dimethyl-9H-fluoren-2-yl)biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), or 2-{3-[3-(benzo[b]naphtho[1,2-d]furan-6-yl)phenyl]phenyl}-4,6-diphenyl-1,3,5-triazine (abbreviation: mBnfBPTzn-02) can be used, for example.

### [Material Having Anthracene Skeleton]

An organic compound having an anthracene skeleton can be used for the layer 113X. In particular, an organic compound having both an anthracene skeleton and a heterocyclic skeleton can be suitably used.

For example, an organic compound having both an anthracene skeleton and a nitrogen-containing five-membered ring skeleton can be used for the layer 113X. Alternatively, an organic compound having both an anthracene skeleton and a nitrogen-containing five-membered ring skeleton where two heteroatoms are included in a ring can be used for the layer 113X. Specifically, a pyrazole ring, an imidazole ring, an oxazole ring, a thiazole ring, or the like can be suitably used as the heterocyclic skeleton.

For example, an organic compound having both an anthracene skeleton and a nitrogen-containing six-membered ring skeleton can be used for the layer 113X. Alternatively, an organic compound having both an anthracene skeleton and a nitrogen-containing six-membered ring skeleton where two heteroatoms are included in a ring can be used for the layer 113X. Specifically, a pyrazine ring, a pyrimidine ring, a pyridazine ring, or the like can be suitably used as the heterocyclic skeleton.

### [Structure Example of Mixed Material]

A material in which a plurality of kinds of substances are mixed can be used for the layer 113X. Specifically, a mixed material containing an alkali metal, an alkali metal compound, or an alkali metal complex and an electron-transport substance can be used for the layer 113X. Note that the electron-transport material preferably has a HOMO level of −6.0 eV or higher.

The mixed material can be suitably used for the layer 113X in combination with a structure using a composite material, which is described in Embodiment 3, for the layer 104X. For example, a composite material of an electron-accepting substance and a hole-transport material can be used for the layer 104X. Specifically, a composite material of an electron-accepting substance and a substance having a relatively deep HOMO level HM1, which is higher than or equal to −5.7 eV and lower than or equal to −5.4 eV, can be used for the layer 104X. Using the mixed material for the layer 113X in combination with the structure using such a composite material for the layer 104X leads to an increase in the reliability of the light-emitting device.

Furthermore, a structure using a hole-transport material for the layer 112X is preferably combined with the structure using the mixed material for the layer 113X and the composite material for the layer 104X. For example, a substance having a HOMO level HM2, which differs by −0.2 eV to 0 eV from the relatively deep HOMO level HM1, can be used for the layer 112X. This leads to an increase in the reliability of the light-emitting device. Note that in this specification and the like, the structure of the above-described light-emitting device may be referred to as a Recombination-Site Tailoring Injection structure (ReSTI structure).

The concentration of the alkali metal, the alkali metal compound, or the alkali metal complex preferably differs in the thickness direction of the layer 113X (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

As the metal complex having an 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

### <<Structure Example 1 of Layer 111X>>

Either a structure containing a light-emitting material or a structure containing a light-emitting material and a host material can be employed for the layer 111X, for example. The layer 111X can be referred to as a light-emitting layer. The layer 111X is preferably provided in a region where holes and electrons are recombined. This allows efficient conversion of energy generated by recombination of carriers into light and emission of the light.

Furthermore, the layer 111X is preferably provided apart from a metal used for the electrode or the like. In that case, a quenching phenomenon caused by the metal used for the electrode or the like can be inhibited.

It is preferable that a distance from an electrode or the like having reflectivity to the layer 111X be adjusted and the layer 111X be placed in an appropriate position in accordance with an emission wavelength. With this structure, the amplitude can be increased by utilizing an interference phenomenon between light reflected by the electrode or the like and light emitted from the layer 111X. Light with a predetermined wavelength can be intensified and the spectrum of the light can be narrowed. In addition, bright light emission colors with high intensity can be obtained. In other words, the layer 111X is placed in an appropriate position between electrodes and the like, and thus a microcavity structure can be formed.

For example, a fluorescent substance, a phosphorescent substance, or a substance exhibiting thermally activated delayed fluorescence (TADF) (also referred to as a TADF material) can be used as the light-emitting material. Thus, energy generated by recombination of carriers can be released as the light ELX from the light-emitting material (see FIG. 1).

### [Fluorescent Substance]

A fluorescent substance can be used for the layer 111X. For example, fluorescent substances exemplified below can be used for the layer 111X. Note that fluorescent substances that can be used for the layer 111X are not limited to the following, and a variety of known fluorescent substances can be used for the layer 111X.

Specifically, any of the following fluorescent substances can be used: 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N′-bis[4-(9-phenyl-9H-fluoren-9-yl)phenyl]pyrene-1,6-diamine (abbreviation: 1,6FLPAPm), N,N-bis(3-methylphenyl)-N,N-bis[3-(9-phenyl-9H-fluoren-9-yl)phenyl]pyrene-1,6-diamine (abbreviation: 1,6mMemFLPAPm), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N,N′-(pyrene-1,6-diyl)bis[(6,N-diphenylbenzo[b]naphtho[1,2-d]furan)-8-amine](abbreviation: 1,6BnfAPrn-03), N,N-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), and the like.

Condensed aromatic diamine compounds typified by pyrenediamine compounds such as 1,6FLPAPrn, 1,6mMemFLPAPrn, and 1,6BnfAPm-03 are particularly preferable because they have high hole-trapping properties and have high emission efficiency or high reliability.

Other examples of fluorescent substances include N-[4-(9,10-diphenyl-2-anthryl)phenyl]-N,N′,N-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, 9,10-diphenyl-2-[N-phenyl-N-(9-phenyl-carbazol-3-yl)-amino]-anthracene (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracene-2-amine (abbreviation: 2YGABPhA), N,N,9-triphenylanthracene-9-amine (abbreviation: DPhAPhA), coumarin 545T, N,N′-diphenylquinacridone (abbreviation: DPQd), rubrene, and 5,12-bis(biphenyl-4-yl)-6,11-diphenyltetracene (abbreviation: BPT).

Other examples of fluorescent substances include 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,NN-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), and 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM).

### [Phosphorescent Substance]

A phosphorescent substance can be used for the layer 111X. For example, phosphorescent substances exemplified below can be used for the layer 111X. Note that phosphorescent substances that can be used for the layer 111X are not limited to the following, and a variety of known phosphorescent substances can be used for the layer 111X.

For example, any of the following can be used for the layer 111X: an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, a platinum complex, and the like.

### [Phosphorescent Substance (Blue)]

As an organometallic iridium complex having a 4H-triazole skeleton or the like, for example, tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As an organometallic iridium complex having a 1H-triazole skeleton or the like, for example, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato)iridium(III) (abbreviation: [Ir(Prptz1-Me)₃]), or the like can be used.

As an organometallic iridium complex having an imidazole skeleton or the like, for example, fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or the like can be used.

As an organometallic iridium complex having a phenylpyridine derivative with an electron-withdrawing group as a ligand, or the like, for example, bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: [Ir(CF3ppy)₂(pic)]), bis[2-(4′,6′-difluorophenyl)pyridinato-N,C²′]iridium(III) acetylacetonate (abbreviation: FIracac), or the like can be used.

These compounds emit blue phosphorescent light and have an emission wavelength peak at 440 nm to 520 nm.

### [Phosphorescent Substance (Green)]

As an organometallic iridium complex having a pyrimidine skeleton or the like, for example, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)2(acac)]), (acetylacetonato)bis(6-tert-butyl-4-phenylpyrimidinato)iridium(III) (abbreviation: [Ir(tBuppm)2(acac)]), (acetylacetonato)bis[6-(2-norbornyl)-4-phenylpyrimidinato]iridium(III) (abbreviation: [Ir(nbppm)2(acac)]), (acetylacetonato)bis[5-methyl-6-(2-methylphenyl)-4-phenylpyrimidinato]iridium(III) (abbreviation: [Ir(mpmppm)2(acac)]), (acetylacetonato)bis(4,6-diphenylpyrimidinato)iridium(III) (abbreviation: [Ir(dppm)2(acac)]), or the like can be used.

As an organometallic iridium complex having a pyrazine skeleton or the like, for example, (acetylacetonato)bis(3,5-dimethyl-2-phenylpyrazinato)iridium(III) (abbreviation: [Ir(mppr-Me)2(acac)]), (acetylacetonato)bis(5-isopropyl-3-methyl-2-phenylpyrazinato)iridium(III) (abbreviation: [Ir(mppr-iPr)2(acac)]), or the like can be used.

As an organometallic iridium complex having a pyridine skeleton or the like, for example, tris(2-phenylpyridinato-N,C²′)iridium(III) (abbreviation: [Ir(ppy)3]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²′)iridium(III) acetylacetonate (abbreviation: [Ir(pq)₂(acac)]), [2-d3-methyl-8-(2-pyridinyl-KN)benzofuro[2,3-b]pyridine-κC]bis[2-(5-d₃-methyl-2-pyridinyl-xN²)phenyl-κC]iridium(III) (abbreviation: [Ir(5mppy-d3)₂(mbfpypy-d3)]), [2-d3-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), or the like can be used.

Examples of a rare earth metal complex include tris(acetylacetonato) (monophenanthroline)terbium(III) (abbreviation: [Tb(acac)₃(Phen)]).

These compounds mainly emit green phosphorescent light and have an emission wavelength peak at 500 nm to 600 nm. An organometallic iridium complex having a pyrimidine skeleton has distinctively high reliability or emission efficiency.

### [Phosphorescent Substance (Red)]

As an organometallic iridium complex having a pyrimidine skeleton or the like, for example, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(dlnpm)₂(dpm)]), or the like can be used.

As an organometallic iridium complex having a pyrazine skeleton or the like, for example, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

As an organometallic iridium complex having a pyridine skeleton or the like, for example, tris(1-phenylisoquinolinato-N,C²′)iridium(III) (abbreviation: [Ir(piq)₃]), bis(1-phenylisoquinolinato-N,C²′)iridium(III) acetylacetonate (abbreviation: [Ir(piq)₂(acac)]), or the like can be used.

As a rare earth metal complex or the like, for example, tris(1,3-diphenyl-1,3-propanedionato)(monophenanthroline)europium(III) (abbreviation: [Eu(DBM)₃(Phen)]), tris[1-(2-thenoyl)-3,3,3-trifluoroacetonato](monophenanthroline)europium(III) (abbreviation: [Eu(TTA)₃(Phen)]), or the like can be used.

As a platinum complex or the like, for example, 2,3,7,8,12,13,17,18-octaethyl-21H,23H-porphyrin platinum(II) (abbreviation: PtOEP) or the like can be used.

These compounds emit red phosphorescent light and have an emission peak at 600 nm to 700 nm. Furthermore, the organometallic iridium complexes having a pyrazine skeleton can provide red light emission with chromaticity favorably used for display apparatuses.

### [Substance Exhibiting TADF]

A TADF material can be used for the layer 111X. When a TADF material is used as the light-emitting substance, the S1 level of a host material is preferably higher than that of the TADF material. In addition, the T1 level of the host material is preferably higher than that of the TADF material.

For example, any of the TADF materials exemplified below can be used as the light-emitting material. Note that without being limited thereto, a variety of known TADF materials can be used.

In the TADF material, the difference between the S1 level and the T1 level is small, and reverse intersystem crossing (upconversion) from the triplet excited state into the singlet excited state can be achieved by a small amount of thermal energy. Thus, the singlet excited state can be efficiently generated from the triplet excited state. In addition, the triplet excitation energy can be converted into light emission.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used as the TADF material.

Specifically, the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

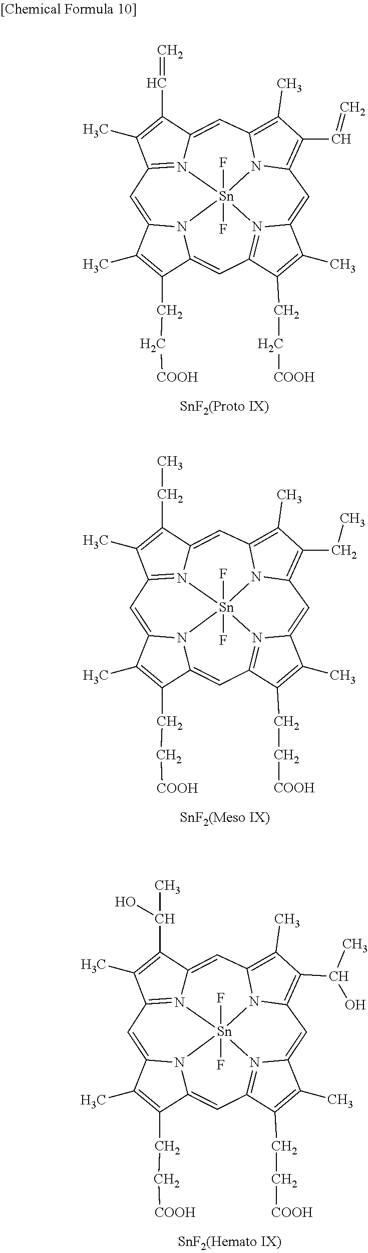

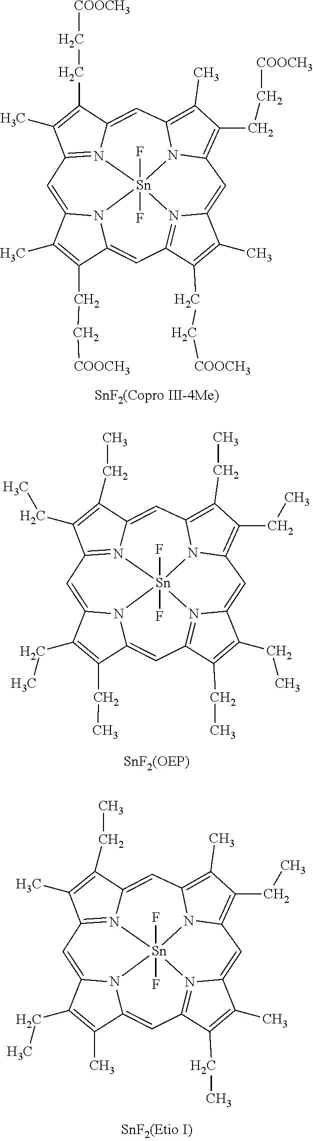

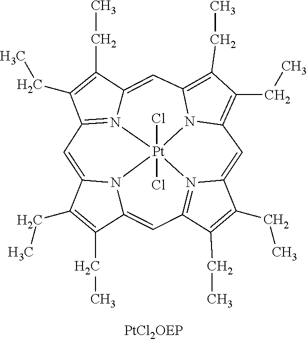

Furthermore, a heterocyclic compound having one or both of a π-electron rich heteroaromatic ring and a π-electron deficient heteroaromatic ring can be used, for example, as the TADF material.

Specifically, the following compounds whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

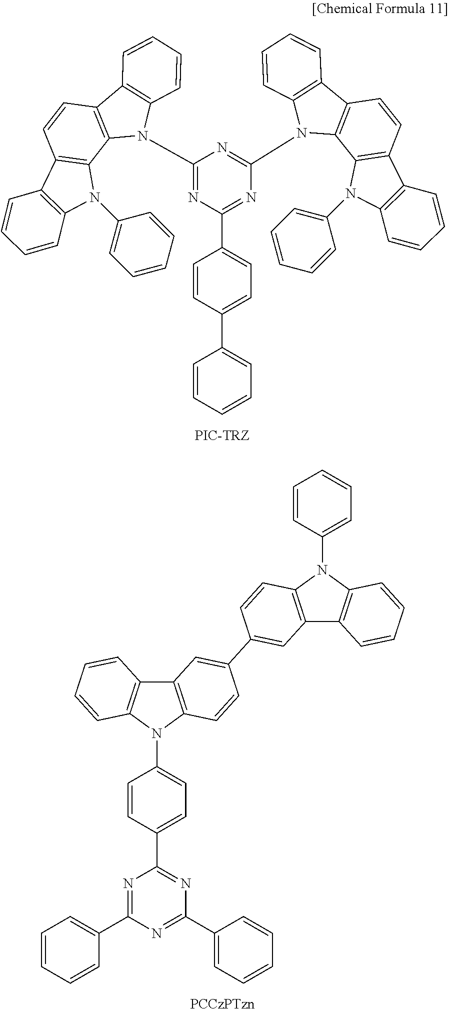 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

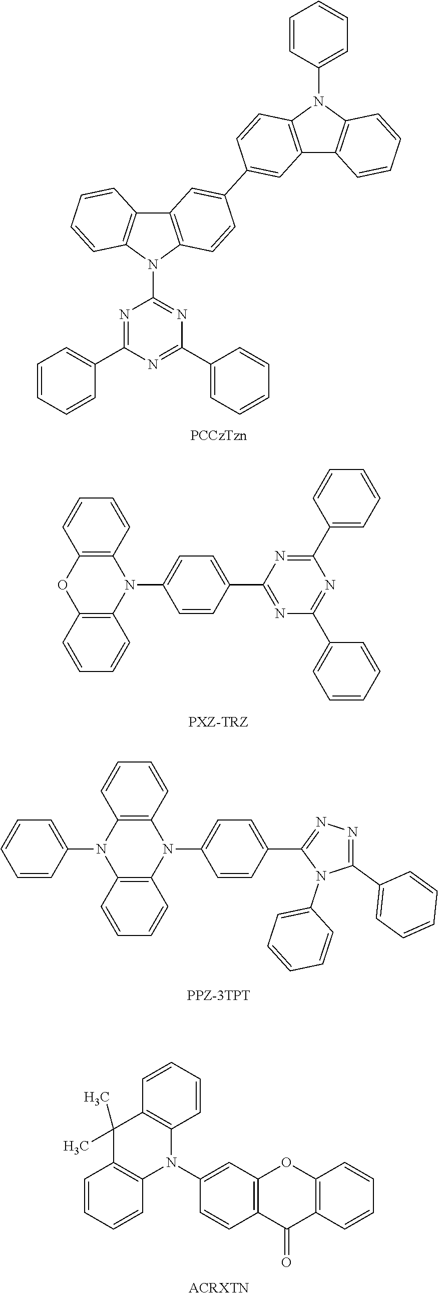 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21]

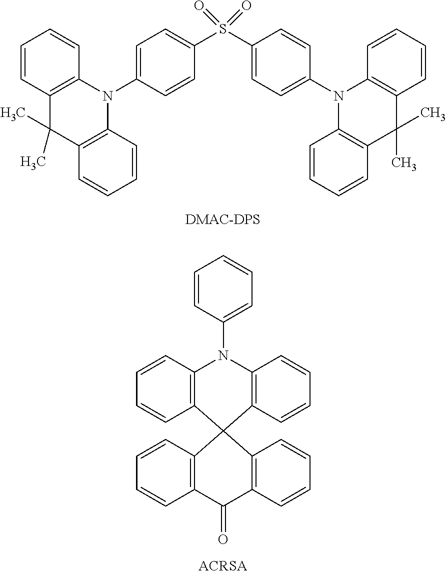 [SMILES: CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Such a heterocyclic compound is preferable because of having high electron-transport and hole-transport properties ow ing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high electron-accepting properties and high reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane and boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

### <<Structure Example 2 of Layer 111X>>

A carrier-transport material can be used as the host material. For example, a hole-transport material, an electron-transport material, a substance exhibiting TADF, a material having an anthracene skeleton, or a mixed material can be used as the host material. A material having a wider band gap than the light-emitting material contained in the layer 111X is preferably used as the host material. Thus, transfer of energy from excitons generated in the layer 111X to the host material can be inhibited.

### [Hole-Transport Material]

A material having a hole mobility of 1×10⁻⁶ cm²/Vs or higher can be suitably used as the hole-transport material. For example, a hole-transport material that can be used for the layer 112X can be used for the layer 111X.

### [Electron-Transport Material]

A metal complex or an organic compound having a π-electron deficient heteroaromatic ring skeleton can be used as the electron-transport material. For example, an electron-transport material that can be used for the layer 113X can be used for the layer 111X.

### [Material Having Anthracene Skeleton]

An organic compound having an anthracene skeleton can be used as the host material. An organic compound having an anthracene skeleton is particularly preferable in the case where a fluorescent substance is used as the light-emitting substance. Thus, a light-emitting device with high emission efficiency and high durability can be obtained.

Among the organic compounds having an anthracene skeleton, an organic compound having a diphenylanthracene skeleton, in particular, a 9,10-diphenylanthracene skeleton, is chemically stable and thus is preferable. The host material preferably has a carbazole skeleton because the hole-injection and hole-transport properties are improved. In particular, the host material preferably has a dibenzocarbazole skeleton because the HOMO level thereof is shallower than that of the host material having a carbazole skeleton by approximately 0.1 eV so that holes enter the host material easily, the hole-transport property is improved, and the heat resistance is increased. Note that in terms of the hole-injection and hole-transport properties, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

For example, 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-[4-(2-naphthyl)phenyl]anthracene (abbreviation: αN-βNPAnth), 9-[4-(9-phenylcarbazol-3-yl)]phenyl-10-phenylanthracene (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 3-[4-(1-naphthyl)phenyl]-9-phenyl-9H-carbazole (abbreviation: PCPN), or the like can be used.

In particular, CzPA, cgDBCzPA, 2mBnfPPA, and PCzPA have excellent properties.

### [Substance Exhibiting TADF]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than that of the fluorescent substance in order that high emission efficiency can be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on the lowest-energy-side absorption band of the fluorescent substance, in which case excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton that causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance; therefore, the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a π bond, further preferably has an aromatic ring, and still further preferably has a condensed aromatic ring or a condensed heteroaromatic ring.

Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. In particular, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

For example, the TADF material that can be used as the light-emitting material can be used as the host material.

### [Structure Example 1 of Mixed Material]

A material in which a plurality of kinds of substances are mixed can be used as the host material. For example, a material that includes an electron-transport material and a hole-transport material can be used as the mixed material. The weight ratio of the hole-transport material to the electron-transport material contained in the mixed material is (the hole-transport material/the electron-transport material)=(1/19) or more and (19/1) or less. Thus, the carrier-transport property of the layer 111X can be easily adjusted and a recombination region can be easily controlled.

### [Structure Example 2 of Mixed Material]

In addition, a material mixed with a phosphorescent substance can be used as the host material. When a fluorescent substance is used as the light-emitting substance, a phosphorescent substance can be used as an energy donor for supplying excitation energy to the fluorescent substance.

### [Structure Example 3 of Mixed Material]

A mixed material containing a material to form an exciplex can be used as the host material. For example, a material in which an emission spectrum of a formed exciplex overlaps with a wavelength on the lowest-energy-side absorption band of the light-emitting substance can be used as the host material. This enables smooth energy transfer and improves emission efficiency. The driving voltage can be reduced. With such a structure, light emission can be efficiently obtained by exciplex-triplet energy transfer (ExTET), which is energy transfer from the exciplex to the light-emitting substance (phosphorescent material).

A phosphorescent substance can be used as at least one of the materials forming an exciplex. Accordingly, reverse intersystem crossing can be used. Triplet excitation energy can be efficiently converted into singlet excitation energy.

Combination of an electron-transport material and a hole-transport material whose HOMO level is higher than or equal to that of the electron-transport material is preferable for forming an exciplex. The lowest unoccupied molecular orbital (LUMO) level of the hole-transport material is preferably higher than or equal to that of the electron-transport material. Thus, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of the mixed film in which the hole-transport material and the electron-transport material are mixed is shifted to the longer wavelength side than the emission spectrum of each of the materials (or has another peak on the longer wavelength side) observed by comparison of the emission spectra of the hole-transport material, the electron-transport material, and the mixed film of these materials, for example. Alternatively, the formation of an exciplex can be confirmed by a difference in transient response, such as a phenomenon in which the transient photoluminescence (PL) lifetime of the mixed film has longer lifetime components or a larger proportion of delayed components than the transient PL lifetime of each of the materials, observed by comparison of transient PL of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of these materials.

This embodiment can be combined with any of the other embodiments in this specification as appropriate.

### Embodiment 3

In this embodiment, the structure of the light-emitting device 550X of one embodiment of the present invention will be described with reference to FIG. 1.

### <Structure Example of Light-Emitting Device 550X>

The light-emitting device 550X described in this embodiment includes the electrode 551X, the electrode 552X, the unit 103X, and the layer 104X (see FIG. 1).

The electrode 552X overlaps with the electrode 551X, and the unit 103X is positioned between the electrode 551X and the electrode 552X. The layer 104X is positioned between the unit 103X and the electrode 551X. For example, the structure described in Embodiment 2 can be employed for the unit 103X.

### <Structure Example of Electrode 551X>

A conductive material can be used for the electrode 551X, for example. Specifically, a single layer or a stack using a film containing a metal, an alloy, or a conductive compound can be used for the electrode 551X.

A film that efficiently reflects light can be used for the electrode 551X, for example. Specifically, an alloy containing silver, copper, and the like, an alloy containing silver, palladium, and the like, or a metal film of aluminum or the like can be used for the electrode 551X.

For example, a metal film that transmits part of light and reflects the other part of the light can be used for the electrode 551X. Thus, the light-emitting device 550X can have a microcavity structure. Alternatively, light with a predetermined wavelength can be extracted more efficiently than light with the other wavelengths. Alternatively, light with a narrow full width at half maximum of a spectrum can be extracted. Alternatively, light of a bright color can be extracted.

For example, a film having a property of transmitting visible light can be used for the electrode 551X. Specifically, a single layer or a stack using a metal film, an alloy film, a conductive oxide film, or the like that is thin enough to transmit light can be used for the electrode 551X.

In particular, a material having a work function higher than or equal to 4.0 eV can be suitably used for the electrode 551X.

For example, a conductive oxide containing indium can be used. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

For another example, a conductive oxide containing zinc can be used. Specifically, zinc oxide, zinc oxide to which gallium is added, zinc oxide to which aluminum is added, or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), or a nitride of a metal material (e.g., titanium nitride) can be used. Graphene can also be used.

### <<Structure Example 1 of Layer 104X>>

A hole-injection material can be used for the layer 104X, for example. The layer 104X can be referred to as a hole-injection layer.

For example, a material having a hole mobility lower than or equal to 1×10⁻³ cm²/Vs when the square root of the electric field strength [V/cm] is 600 can be used for the layer 104X. A film having an electrical resistivity greater than or equal to 1×10⁴ Ω·cm and less than or equal to 1×10⁷ Ω·cm can be used as the layer 104X. The electrical resistivity of the layer 104X is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### <<Structure Example 2 of Layer 104X>>

Specifically, an electron-accepting substance can be used for the layer 104X. Alternatively, a composite material containing a plurality of kinds of substances can be used for the layer 104X. This can facilitate the injection of holes from the electrode 551X, for example. Alternatively, the driving voltage of the light-emitting device 550X can be reduced.

### [Electron-Accepting Substance]

An organic compound or an inorganic compound can be used as the electron-accepting substance. The electron-accepting substance can extract electrons from an adjacent hole-transport layer or a hole-transport material by the application of an electric field.

For example, a compound having an electron-withdrawing group (a halogen group or a cyano group) can be used as the electron-accepting substance. Note that an electron-accepting organic compound is easily evaporated, which facilitates film deposition. Thus, the productivity of the light-emitting device 550X can be increased.

Specifically, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylene-1,3,4,5,6,8,9,10-octafluoro-7H-pyren-2-ylidene)malononitrile, or the like can be used.

A compound in which electron-withdrawing groups are bonded to a condensed aromatic ring having a plurality of heteroatoms, such as HAT-CN, is particularly preferable because it is thermally stable.

A [3]radialene derivative having an electron-withdrawing group (in particular, a cyano group or a halogen group such as a fluoro group) has a very high electron-accepting property and thus is preferred.

Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like can be used.

For the electron-accepting substance, a transition metal oxide such as a molybdenum oxide, a vanadium oxide, a ruthenium oxide, a tungsten oxide, or a manganese oxide can be used.

It is possible to use any of the following materials: phthalocyanine-based compounds such as phthalocyanine (abbreviation: H₂Pc); phthalocyanine-based complex compounds such as copper(II) phthalocyanine (abbreviation: CuPc); and compounds having an aromatic amine skeleton, such as 4,4′-bis[N-(4-diphenylaminophenyl)-N-phenylamino]biphenyl (abbreviation: DPAB) and N,N-bis[4-bis(3-methylphenyl)aminophenyl]-N,N′-diphenyl-4,4′-diaminobiphenyl (abbreviation: DNTPD).

In addition, high molecular compounds such as poly(3,4-ethylenedioxythiophene)/polystyrenesulfonic acid (abbreviation: PEDOT/PSS), and the like can be used.

### [Structure Example 1 of Composite Material]

For example, a composite material containing an electron-accepting substance and a hole-transport material can be used for the layer 104X. Accordingly, not only a material having a high work function but also a material having a low work function can also be used for the electrode 551X. Alternatively, a material used for the electrode 551X can be selected from a wide range of materials regardless of its work function.

For the hole-transport material in the composite material, for example, a compound having an aromatic amine skeleton, a carbazole derivative, an aromatic hydrocarbon, an aromatic hydrocarbon having a vinyl group, or a high molecular compound (such as an oligomer, a dendrimer, or a polymer) can be used. A material having a hole mobility of 1×10⁻⁶ cm²/Vs or higher can be suitably used as the hole-transport material in the composite material. For example, the hole-transport material that can be used for the layer 112X can be used for the composite material.

A substance having a relatively deep HOMO level can be suitably used as the hole-transport material in the composite material. Specifically, the HOMO level is preferably higher than or equal to −5.7 eV and lower than or equal to −5.4 eV. Accordingly, hole injection to the unit 103X can be facilitated. Hole injection to the layer 112X can also be facilitated. The reliability of the light-emitting device 550X can be increased.

As the compound having an aromatic amine skeleton, for example, N,N-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N-diphenyl-4,4′-diaminobiphenyl (abbreviation: DNTPD), or 1,3,5-tris[N-(4-diphenylaminophenyl)-N-phenylamino]benzene (abbreviation: DPA3B) can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, or coronene can be used.

As the aromatic hydrocarbon having a vinyl group, for example, 4,4′-bis(2,2-diphenylvinyl)biphenyl (abbreviation: DPVBi) or 9,10-bis[4-(2,2-diphenylvinyl)phenyl]anthracene (abbreviation: DPVPA) can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N-phenylamino}phenyl)methacrylamide](abbreviation: PTPDMA), or poly[N,N′-bis(4-butylphenyl)-N,N′-bis(phenyl)benzidine](abbreviation: Poly-TPD) can be used.

Furthermore, a substance having any of a carbazole skeleton, a dibenzofuran skeleton, a dibenzothiophene skeleton, and an anthracene skeleton can be suitably used as the hole-transport material in the composite material, for example. Moreover, a substance including any of the following can be used as the hole-transport material in the composite material: an aromatic amine having a substituent that has a dibenzofuran ring or a dibenzothiophene ring, an aromatic monoamine that has a naphthalene ring, and an aromatic monoamine in which a 9-fluorenyl group is bonded to nitrogen of amine through an arylene group. With the use of a substance including an N,N-bis(4-biphenyl)amino group, the reliability of the light-emitting device 550X can be increased.

Specific examples of the above-described substances include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: aNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

### [Structure Example 2 of Composite Material]

For example, a composite material containing an electron-accepting substance, a hole-transport material, and a fluoride of an alkali metal or a fluoride of an alkaline earth metal can be used as the hole-injection material. In particular, a composite material in which the proportion of fluorine atoms is higher than or equal to 20% can be suitably used. Thus, the refractive index of the layer 104X can be reduced. A layer with a low refractive index can be formed inside the light-emitting device 550X. The external quantum efficiency of the light-emitting device 550X can be improved.

This embodiment can be combined with any of the other embodiments in this specification as appropriate.

### Embodiment 4

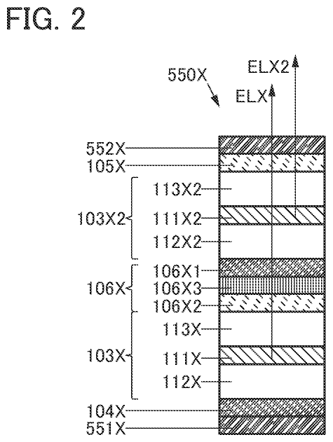

In this embodiment, a structure of the light-emitting device 550X of one embodiment of the present invention will be described with reference to FIG. 2.

FIG. 2 is a cross-sectional view illustrating a structure of the light-emitting device of one embodiment of the present invention.

### <Structure Example of Light-Emitting Device 550X>

The light-emitting device 550X described in this embodiment includes the electrode 551X, the electrode 552X, the unit 103X, an intermediate layer 106X, and a unit 103X2 (see FIG. 2). The light-emitting device 550X also includes the layer 105X and the layer 104X.

The unit 103X is positioned between the electrode 552X and the electrode 551X, and the intermediate layer 106X is positioned between the electrode 552X and the unit 103X.

The unit 103X2 is positioned between the electrode 552X and the intermediate layer 106X. The unit 103X2 has a function of emitting light ELX2. The layer 105X is positioned between the electrode 552X and the unit 103X2, and the layer 104X is positioned between the unit 103X and the electrode 551X.

In other words, the light-emitting device 550X includes the stacked units between the electrode 551X and the electrode 552X. The number of stacked units is not limited to two and may be three or more. A structure including the stacked units positioned between the electrode 551X and the electrode 552X and the intermediate layer 106X positioned between the units is referred to as a stacked light-emitting device or a tandem light-emitting device in some cases.

This structure enables high luminance emission while the current density is kept low. The reliability can be improved. The driving voltage can be reduced in comparison with that of the light-emitting device with the same luminance. The power consumption can be reduced.

### <<Structure Example 1 of Unit 103X2>>

The unit 103X2 has a single-layer structure or a stacked-layer structure. For example, the unit 103X2 includes a layer 111X2, a layer 112X2, and a layer 113X2. The unit 103X2 has a function of emitting the light ELX2.

The layer 111X2 is positioned between the layer 112X2 and the layer 113X2, the layer 113X2 is positioned between the electrode 552X and the layer 111X2, and the layer 112X2 is positioned between the layer 111X2 and the intermediate layer 106X.

The structure that can be employed for the unit 103X can be employed for the unit 103X2. Specifically, the description of the structure of the unit 103X can be referred to for the description of the unit 103X2 by replacing “X” in the reference numerals with “X2”. For example, the unit 103X2 can have the same structure as the unit 103X.

### <<Structure Example 2 of Unit 103X2>>

A structure different from the structure of the unit 103X can be employed for the unit 103X2. For example, the unit 103X2 can have a structure emitting light whose hue is different from that of light emitted from the unit 103X.

Specifically, a stack including the unit 103X emitting red light and green light and the unit 103X2 emitting blue light can be employed. With this structure, a light-emitting device emitting light of a desired color can be provided. For example, a light-emitting device emitting white light can be provided.

### <<Structure Example 1 of Intermediate Layer 106X>>

The intermediate layer 106X has a function of supplying electrons to the anode side and supplying holes to the cathode side. The intermediate layer 106X has a function of supplying electrons to one of the unit 103X and the unit 103X2 and supplying holes to the other.

For example, the hole-injection material that can be used for the layer 104X described in Embodiment 3 can be used for the intermediate layer 106X. Specifically, the electron-accepting material or the composite material can be used for the intermediate layer 106X.

Alternatively, for example, a stacked-layer film in which a film containing the composite material and a film containing a hole-transport material are stacked can be used for the intermediate layer 106X. Note that the film containing a hole-transport material is positioned between the film containing the composite material and the cathode.

### <<Structure Example 2 of Intermediate Layer 106X>>

A stacked-layer film in which a layer 106X1 and a layer 106X2 are stacked can be used as the intermediate layer 106X. The layer 106X1 includes a region positioned between the electrode 552X and the unit 103X, and the layer 106X2 includes a region positioned between the layer 106X1 and the unit 103X.

### <<Structure Example of Layer 106X1>>

For example, the hole-injection material that can be used for the layer 104X described in Embodiment 3 can be used for the layer 106X1. Specifically, the electron-accepting material or the composite material can be used for the layer 106X1. A film having an electrical resistivity greater than or equal to 1×10⁴ Ω·cm and less than or equal to 1×10⁷ Ω·cm can be used as the layer 106X1. The electrical resistivity of the layer 106X1 is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### <<Structure Example 1 of Layer 106X2>>

The material that can be used for the layer 105X described in Embodiment 1 can be used for the layer 106X2, for example.

A material having a large acid dissociation constant pKₐ has a large dipole moment. A material having a large dipole moment interacts with a hole. When a material having an acid dissociation constant pKₐ larger than or equal to 8 is used as the organic compound OCX, for example, the organic compound OCX interacts with a hole and the hole-transport property of the layer 106X2 can be significantly reduced.

In addition, a material having a large acid dissociation constant pKₐ has high nucleophilicity. A material having high nucleophilicity may react with a molecule, which has received a hole and become a cation radical, to generate a new molecule or a new intermediate state. When a material having an acid dissociation constant pKₐ larger than or equal to 8 is used as the organic compound OCX, for example, the organic compound OCX generates a new molecule or a new intermediate state and the hole-transport property of the layer 106X2 can be significantly reduced.

Some holes that have reached the layer 106X2 from the electrode 551X through the unit 103X remain at the interface between the unit 103X and the layer 106X2 or in the layer 106X2. This attracts electrons from the layer 106X1 so that an electric double layer is formed on the layer 106X1 side of the layer 106X2. Moreover, a vacuum level between the unit 103X and the layer 106X2 or between the layer 106X2 and the layer 106X1 is distorted and electrons are supplied from the layer 106X2 to the unit 103X.

Note that a material having a large acid dissociation constant pKₐ has high water solubility. When a material having an acid dissociation constant pKₐ larger than or equal to 8 is used as the organic compound OCX, for example, the water resistance of the layer 106X2 is lowered and a problem such as peeling of the layer 106X2 from another layer occurs in the fabrication process. This might cause a defect in the light-emitting device.

Thus, the organic compound ETMX has no pyridine ring, no phenanthroline ring, or one phenanthroline ring. For example, a material having no pyridine ring, no phenanthroline ring, or one phenanthroline ring can be used as the organic compound ETMX.

The acid dissociation constants pKₐ of a pyridine molecule and a phenanthroline molecule are 5.25 and 4.8, respectively. An organic compound having a pyridine ring or a phenanthroline ring has high water solubility; the larger the number of pyridine rings or phenanthroline rings is, the higher the water solubility is. For example, an organic compound having no pyridine ring, no phenanthroline ring, or one phenanthroline ring has lower water solubility than an organic compound having two or more pyridine rings or two or more phenanthroline rings.

The water resistance of the layer 106X2 containing a material having no pyridine ring, no phenanthroline ring, or one phenanthroline ring as the organic compound ETMX can be higher than that of the layer 106X2 containing an organic compound having two or more pyridine rings or two or more phenanthroline rings as the organic compound ETMX. Moreover, occurrence of a problem such as peeling of the layer 106X2 from another layer in the fabrication process can be inhibited. Accordingly, occurrence of a problem that causes a defect in a light-emitting device can be inhibited.

A material having an acid dissociation constant pKₐ smaller than 4 can be used as the organic compound ETMX, for example. An organic compound having an acid dissociation constant pKₐ smaller than 4 has lower water solubility than an organic compound having an acid dissociation constant pKₐ larger than or equal to 4, for example. The water resistance of the layer 106X2 containing a material having an acid dissociation constant pKₐ smaller than 4 as the organic compound ETMX can be higher than that of the layer 106X2 containing an organic compound having an acid dissociation constant pKₐ larger than or equal to 4 as the organic compound ETMX. Moreover, occurrence of a problem such as peeling of the layer 106X2 from another layer in the fabrication process can be inhibited. Accordingly, occurrence of a problem that causes a defect in a light-emitting device can be inhibited.

A material having a polarization term δₚ of a solubility parameter δ of less than or equal to 4.0 MPa^{0.5} can be used as the organic compound ETMX, for example. An organic compound having a polarization term δₚ less than or equal to 4.0 MPa^{0.5} has lower water solubility than an organic compound having a polarization term δₚ greater than 4.0 MPa^{0.5}, for example. The water resistance of the layer 106X2 containing a material having a polarization term δₚ less than or equal to 4.0 MPa^{0.5} as the organic compound ETMX can be higher than that of the layer 106X2 containing an organic compound having a polarization term δₚ greater than 4.0 MPa^{0.5} as the organic compound ETMX. Moreover, occurrence of a problem such as peeling of the layer 106X2 from another layer in the fabrication process can be inhibited. Accordingly, occurrence of a problem that causes a defect in a light-emitting device can be inhibited.

It is preferable that the organic compound OCX not have an electron-donating property with respect to the organic compound ETMX. When having an electron-donating property, the organic compound OCX easily reacts with an atmospheric component such as water or oxygen and thus becomes unstable. The layer 106X2 containing the organic compounds OCX and ETMX of one embodiment of the present invention has an extremely low hole-transport property; thus, the layer 106X2 can function as an intermediate layer of a tandem light-emitting device even though the organic compound OCX does not have an electron-donating property. Thus, an intermediate layer and a tandem light-emitting device that are stable with respect to an atmospheric component such as water or oxygen can be fabricated.

Therefore, the intermediate layer 106X can supply holes to the unit 103X2 and supply electrons to the unit 103X. Furthermore, the intermediate layer 106X can be formed without a substance with high activity, such as an alkali metal or an alkaline earth metal. In addition, the resistance to the air or an impurity such as water can be increased. Moreover, a reduction in emission efficiency due to the air or an impurity such as water can be inhibited. As a result, a novel light-emitting device that is highly convenient, useful, or reliable can be provided.

### <<Structure Example 2 of Layer 106X2>>

An electron-injection material can be used for the layer 106X2, for example.

Specifically, an electron-donating substance can be used for the layer 106X2. Alternatively, a material in which an electron-donating substance and an electron-transport material are combined can be used for the layer 106X2. Alternatively, electride can be used for the layer 106X2.

### [Electron-Donating Substance]

For example, an alkali metal, an alkaline earth metal, a rare earth metal, or a compound thereof (an oxide, a halide, a carbonate, or the like) can be used as the electron-donating substance. Alternatively, an organic compound such as tetrathianaphthacene (abbreviation: TTN), nickelocene, or decamethylnickelocene can be used as the electron-donating substance.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### [Structure Example 1 of Composite Material]

A material composed of two or more kinds of substances can be used as the electron-injection material. For example, an electron-donating substance and an electron-transport material can be used for the composite material.

### [Electron-Transport Material]

For example, a material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. In that case, the amount of electrons injected into the light-emitting layer can be controlled. The light-emitting layer can be prevented from having excess electrons.

A metal complex or an organic compound having a π-electron deficient heteroaromatic ring skeleton can be used as the electron-transport material. For example, an electron-transport material that can be used for the layer 113X can be used for the layer 106X2.

### [Structure Example 2 of Composite Material]

A material including a fluoride of an alkali metal in a microcrystalline state and an electron-transport material can be used for the composite material. Alternatively, a material including a fluoride of an alkaline earth metal in a microcrystalline state and an electron-transport material can be used for the composite material. In particular, a composite material including a fluoride of an alkali metal or a fluoride of an alkaline earth metal at 50 wt % or higher can be suitably used. Alternatively, a composite material including an organic compound having a bipyridine skeleton can be suitably used. Thus, the refractive index of the layer 106X2 can be reduced.

### [Structure Example 3 of Composite Material]

For example, a composite material of a first organic compound including an unshared electron pair and a first metal can be used for the layer 106X2. The sum of the number of electrons of the first organic compound and the number of electrons of the first metal is preferably an odd number. The molar ratio of the first metal to 1 mol of the first organic compound is preferably greater than or equal to 0.1 and less than or equal to 10, further preferably greater than or equal to 0.2 and less than or equal to 2, still further preferably greater than or equal to 0.2 and less than or equal to 0.8.

Accordingly, the first organic compound including an unshared electron pair interacts with the first metal and thus can form a singly occupied molecular orbital (SOMO). In the case where electrons are injected from the electrode 552X into the layer 106X2, a barrier therebetween can be reduced.

For the layer 106X2, it is possible to use a composite material in which the spin density measured by ESR spectroscopy is preferably higher than or equal to 1×10¹⁶ spins/cm³, further preferably higher than or equal to 5×10¹⁶ spins/cm³, still further preferably higher than or equal to 1×10¹⁷ spins/cm³.

### [Organic Compound Including Unshared Electron Pair]

For example, an electron-transport material can be used for the organic compound including an unshared electron pair. For example, a compound having an electron deficient heteroaromatic ring can be used. Specifically, a compound having at least one of a pyridine ring, a diazine ring (a pyrimidine ring, a pyrazine ring, and a pyridazine ring), and a triazine ring can be used. Accordingly, the driving voltage of the light-emitting device 550X can be reduced.

Note that the LUMO level of the organic compound including an unshared electron pair is preferably higher than or equal to −3.6 eV and lower than or equal to −2.3 eV. In general, the HOMO level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), 2,2′-(1,3-phenylene)bis(9-phenyl-1,10-phenanthroline) (abbreviation: mPPhen2P), or the like can be used as the organic compound including an unshared electron pair. Note that NBPhen has a higher glass transition temperature (Tg) than BPhen and thus has high heat resistance.

Alternatively, for example, copper phthalocyanine can be used as the organic compound including an unshared electron pair. The number of electrons of the copper phthalocyanine is an odd number.

### [First Metal]

When the number of electrons of the first organic compound including an unshared electron pair is an even number, for example, a composite material of the first organic compound and the first metal that belongs to an odd-numbered group in the periodic table can be used for the layer 106X2.

For example, manganese (Mn), which is a metal belonging to Group 7, cobalt (Co), which is a metal belonging to Group 9, copper (Cu), silver (Ag), and gold (Au), which are metals belonging to Group 11, and aluminum (Al) and indium (In), which are metals belonging to Group 13, are elements belonging to odd-numbered groups in the periodic table. Note that elements belonging to Group 11 have a lower melting point than elements belonging to Group 7 or Group 9 and thus are suitable for vacuum evaporation. In particular, Ag is preferable because of its low melting point. By using a metal having a low reactivity with water or oxygen as the first metal, the moisture resistance of the light-emitting device 550X can be improved.

The use of Ag for the electrode 552X and the layer 106X2 can increase the adhesion between the layer 106X2 and the electrode 552X.

When the number of electrons of the first organic compound including an unshared electron pair is an odd number, a composite material of the first organic compound and the first metal that belongs to an even-numbered group in the periodic table can be used for the layer 106X2. For example, iron (Fe), which is a metal belonging to Group 8, is an element belonging to an even-numbered group in the periodic table.

### [Electride]

For example, a substance obtained by adding electrons at high concentration to a mixed oxide of calcium and aluminum can be used as the electron-injection material.

### <<Structure Example 3 of Intermediate Layer 106X>>

A stacked-layer film in which the layer 106X1, the layer 106X2, and a layer 106X3 are stacked can be used for the intermediate layer 106X. The layer 106X3 includes a region positioned between the layer 106X2 and the layer 106X1.

### <<Structure Example of Layer 106X3>>

An electron-transport material can be used for the layer 106X3, for example. The layer 106X3 can be referred to as an electron-relay layer. With the layer 106X3, a layer that is on the anode side and in contact with the layer 106X3 can be distanced from a layer that is on the cathode side and in contact with the layer 106X3. Interaction between the layer that is on the anode side and in contact with the layer 106X3 and the layer that is on the cathode side and in contact with the layer 106X3 can be reduced. Electrons can be smoothly supplied to the layer that is on the anode side and in contact with the layer 106X3.

A substance whose LUMO level is between the LUMO level of the electron-accepting substance contained in the layer 106X1 and the LUMO level of the substance contained in the layer 106X2 can be suitably used for the layer 106X3.

For example, a material having a LUMO level in a range higher than or equal to −5.0 eV, preferably higher than or equal to −5.0 eV and lower than or equal to −3.0 eV, can be used for the layer 106X3.

Specifically, a phthalocyanine-based material can be used for the layer 106X3. For example, phthalocyanine (abbreviation: H₂Pc), copper(II) phthalocyanine (abbreviation: CuPc), zinc phthalocyanine (abbreviation: ZnPc), or a metal complex having a metal-oxygen bond and an aromatic ligand can be used for the layer 106X3.

### <Method for Fabricating Light-Emitting Device 550X>

For example, each of the electrode 551X, the electrode 552X, the unit 103X, the intermediate layer 106X, and the unit 103X2 can be formed by a dry process, a wet process, an evaporation method, a droplet discharging method, a coating method, a printing method, or the like. A formation method may differ between the components.

Specifically, the light-emitting device 550X can be fabricated with a vacuum evaporation apparatus, an inkjet apparatus, a coating apparatus such as a spin coater, a gravure printing apparatus, an offset printing apparatus, a screen printing apparatus, or the like.

For example, the electrode can be formed by a wet process or a sol-gel method using a paste of a metal material. In addition, an indium oxide-zinc oxide film can be formed by a sputtering method using a target obtained by adding zinc oxide to indium oxide at a concentration higher than or equal to 1 wt % and lower than or equal to 20 wt %. Furthermore, an indium oxide film containing tungsten oxide and zinc oxide (IWZO) can be formed by a sputtering method using a target containing, with respect to indium oxide, tungsten oxide at a concentration higher than or equal to 0.5 wt % and lower than or equal to 5 wt % and zinc oxide at a concentration higher than or equal to 0.1 wt % and lower than or equal to 1 wt %.

This embodiment can be combined with any of the other embodiments in this specification as appropriate.

### Embodiment 5

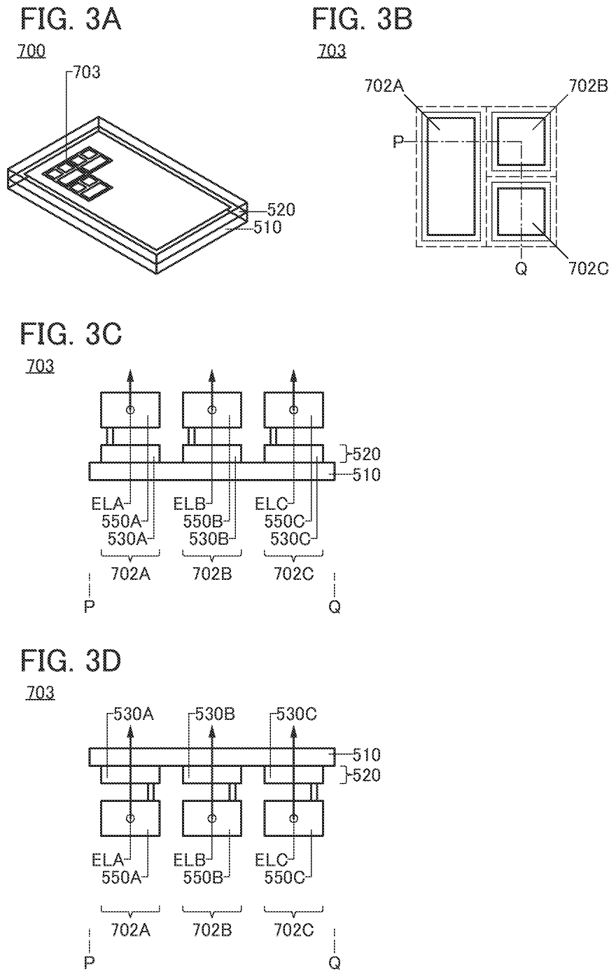

In this embodiment, a structure of a display apparatus of one embodiment of the present invention will be described with reference to FIGS. 3A to 3D, FIG. 4, FIGS. 5A and 5B, and FIG. 6.

FIG. 3A is a perspective view illustrating a structure of the display apparatus of one embodiment of the present invention, and FIG. 3B is a front view illustrating part of FIG. 3A. FIG. 3C is a cross-sectional view taken along the cutting line P-Q in FIG. 3B, and FIG. 3D is a cross-sectional view illustrating a structure different from that in FIG. 3C.

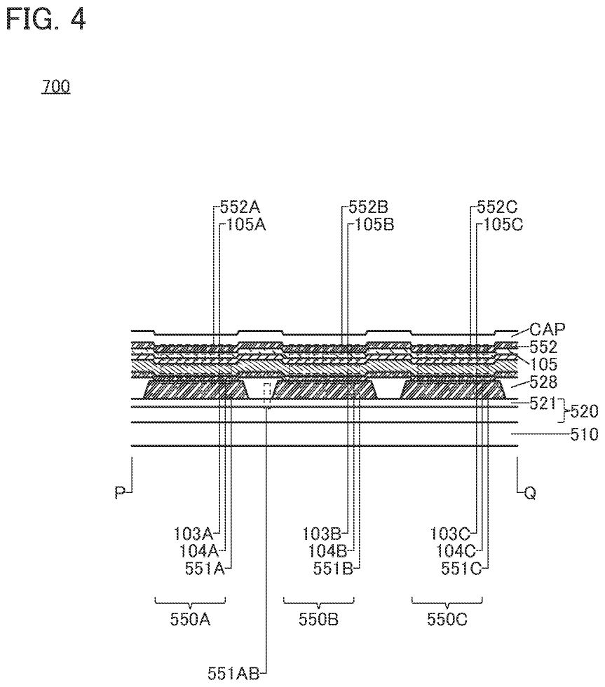

FIG. 4 is a cross-sectional view illustrating the structure of the display apparatus of one embodiment of the present invention.

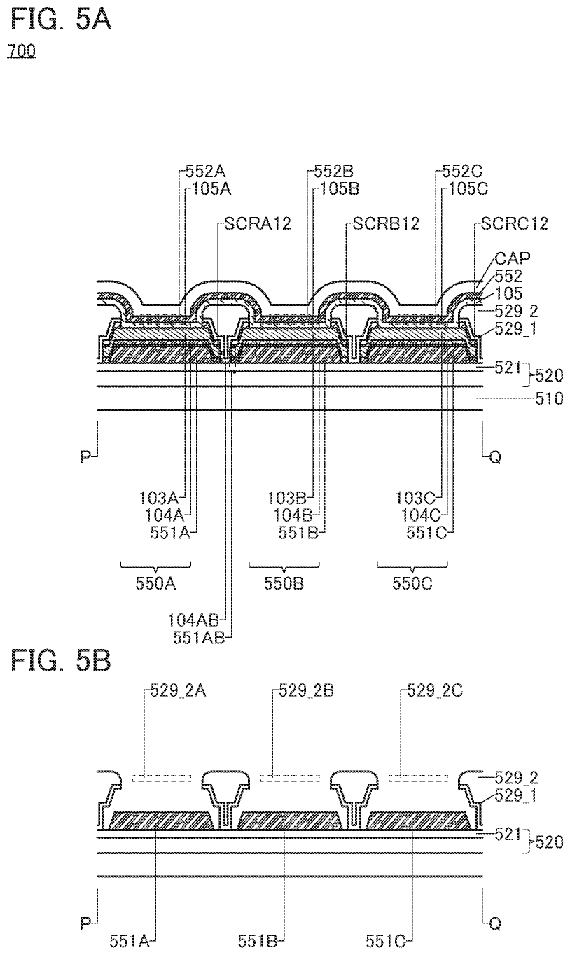

FIG. 5A is a cross-sectional view illustrating a structure of the display apparatus of one embodiment of the present invention, which is different from the structure described with reference to FIG. 4, and FIG. 5B is a cross-sectional view illustrating part of FIG. 5A.

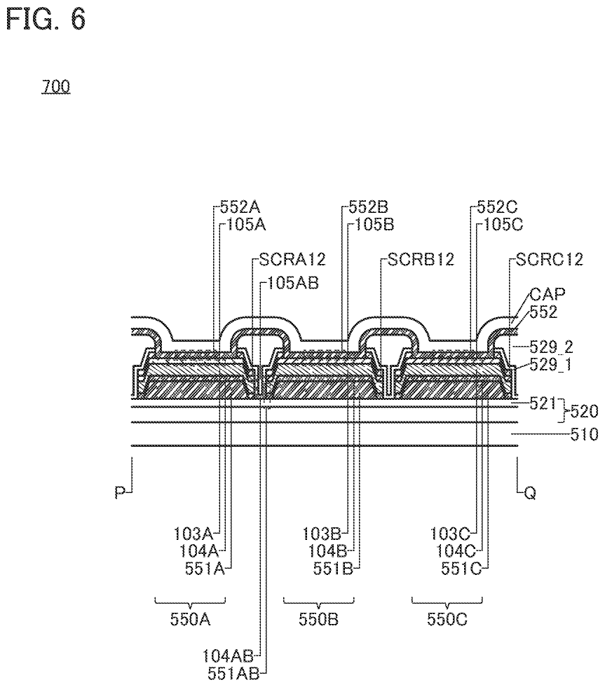

FIG. 6 is a cross-sectional view illustrating a structure of the display apparatus of one embodiment of the present invention.

### <Structure Example 1 of Display Apparatus>

A display apparatus 700 described in this embodiment includes a pixel set 703 (see FIG. 3A). The display apparatus 700 includes a substrate 510 and a functional layer 520.

The pixel set 703 includes a pixel 702A, a pixel 702B, and a pixel 702C (see FIG. 3B).

The pixel 702A includes the light-emitting device 550A and a pixel circuit 530A. The light-emitting device 550A is electrically connected to the pixel circuit 530A (see FIGS. 3C and 3D). A light-emitting device that emits blue light, green light, red light, or white light can be used as the light-emitting device 550A, for example.

The pixel 702B includes the light-emitting device 550B and a pixel circuit 530B. The light-emitting device 550B is electrically connected to the pixel circuit 530B. A light-emitting device that emits light of a color different from that of light emitted from the light-emitting device 550A can be used as the light-emitting device 550B, for example. Alternatively, a light-emitting device that emits light of the same color as light emitted from the light-emitting device 550A can be used as the light-emitting device 550B.

The pixel 702C includes the light-emitting device 550C and a pixel circuit 530C. The light-emitting device 550C is electrically connected to the pixel circuit 530C. A light-emitting device that emits light of a color different from that of light emitted from the light-emitting device 550A or the light-emitting device 550B can be used as the light-emitting device 550C, for example. Alternatively, a light-emitting device that emits light of the same color as light emitted from the light-emitting device 550A or the light-emitting device 550B can be used as the light-emitting device 550C.

Note that the functional layer 520 includes the pixel circuits 530A, 530B, and 530C. The pixel circuit 530A is positioned between the light-emitting device 550A and the substrate 510, the pixel circuit 530B is positioned between the light-emitting device 550B and the substrate 510, and the pixel circuit 530C is positioned between the light-emitting device 550C and the substrate 510.

In the display apparatus 700 of one embodiment of the present invention, for example, the light-emitting device 550A emits light ELA in a direction where the pixel circuit 530A is not provided, the light-emitting device 550B emits light ELB in a direction where the pixel circuit 530B is not provided, and the light-emitting device 550C emits light ELC in a direction where the pixel circuit 530C is not provided (see FIG. 3C). In other words, the display apparatus 700 of one embodiment of the present invention is a top-emission display apparatus.

Alternatively, in the display apparatus 700 of one embodiment of the present invention, for example, the light-emitting device 550A emits the light ELA in a direction where the pixel circuit 530A is provided, the light-emitting device 550B emits the light ELB in a direction where the pixel circuit 530B is provided, and the light-emitting device 550C emits the light ELC in a direction where the pixel circuit 530C is provided (see FIG. 3D). In other words, the display apparatus 700 of one embodiment of the present invention is a bottom-emission display apparatus.

The display apparatus 700 of one embodiment of the present invention includes a layer 105, a conductive film 552, and a layer CAP (see FIG. 4). The layer 105 includes a layer 105A, a layer 105B, and a layer 105C. The conductive film 552 includes an electrode 552A, an electrode 552B, and an electrode 552C.

### <<Structure Example 1 of Light-Emitting Device 550A>>

The light-emitting device 550A includes an electrode 551A, the electrode 552A, a unit 103A, and the layer 105A (see FIG. 4). The light-emitting device 550A further includes a layer 104A. The layer 104A is positioned between the electrode 551A and the unit 103A.

The unit 103A is positioned between the electrode 551A and the electrode 552A and contains a light-emitting material EMA.

The layer 105A is positioned between the electrode 552A and the unit 103A. For example, the layer 105A is in contact with the electrode 552A.

The light-emitting device described in any of Embodiments 1 to 4 can be used as the light-emitting device 550A.

### <<Structure Example 1 of Light-Emitting Device 550B>>

The light-emitting device 550B includes an electrode 551B, the electrode 552B, a unit 103B, and the layer 105B (see FIG. 4). The light-emitting device 550B further includes a layer 104B. The layer 104B is positioned between the electrode 551B and the unit 103B.

The electrode 551B is adjacent to the electrode 551A and a gap 551AB is provided between the electrode 551B and the electrode 551A.

The unit 103B is positioned between the electrode 551B and the electrode 552B and contains a light-emitting material EMB.

The layer 105B is positioned between the electrode 552B and the unit 103B. For example, the layer 105B is in contact with the electrode 552B.

The light-emitting device described in any of Embodiments 1 to 4 can be used as the light-emitting device 550B.

### <<Structure Example 1 of Light-Emitting Device 550C>>

The light-emitting device 550C includes an electrode 551C, the electrode 552C, a unit 103C, and the layer 105C (see FIG. 4). The light-emitting device 550C further includes a layer 104C. The layer 104C is positioned between the electrode 551C and the unit 103C.

The unit 103C is positioned between the electrode 551C and the electrode 552C and contains a light-emitting material EMC.

The layer 105C is positioned between the electrode 552C and the unit 103C. For example, the layer 105C is in contact with the electrode 552C.

The light-emitting device described in any of Embodiments 1 to 4 can be used as the light-emitting device 550C.

Thus, the layer 105A can supply electrons to the unit 103A. In addition, the layer 105B can supply electrons to the unit 103B. Furthermore, for example, the layer 105A and the layer 105B can be formed without a substance with high activity, such as an alkali metal or an alkaline earth metal. In addition, the resistance to the air or an impurity such as water can be increased. Moreover, a reduction in emission efficiency due to the air or an impurity such as water can be inhibited. As a result, a novel light-emitting device that is highly convenient, useful, or reliable can be provided.

### <Structure Example 2 of Display Apparatus>

The display apparatus 700 described in this embodiment includes the pixel set 703 (see FIG. 3A). The display apparatus 700 includes the substrate 510 and the functional layer 520.

The pixel set 703 includes the pixel 702A, the pixel 702B, and the pixel 702C (see FIG. 3B).

The pixel 702A includes the light-emitting device 550A and the pixel circuit 530A. The light-emitting device 550A is electrically connected to the pixel circuit 530A (see FIGS. 3C and 3D).

The pixel 702B includes the light-emitting device 550B and the pixel circuit 530B. The light-emitting device 550B is electrically connected to the pixel circuit 530B.

The display apparatus 700 of one embodiment of the present invention includes the layer 105, the conductive film 552, and the layer CAP (see FIGS. 5A and 5B). The layer 105 includes the layer 105A, the layer 105B, and the layer 105C. The conductive film 552 includes the electrode 552A, the electrode 552B, and the electrode 552C.

### <<Structure Example 2 of Light-Emitting Device 550A>>

The light-emitting device 550A includes the layer 104A. The layer 104A is positioned between the unit 103A and the electrode 551A (see FIG. 5A).

The layer 104A contains a material having a spin density higher than or equal to 1×10¹⁸ spins/cm³ observed by ESR spectroscopy when the material is in a film state.

### <<Structure Example 2 of Light-Emitting Device 550B>>

The light-emitting device 550B includes the layer 104B. The layer 104B is positioned between the unit 103B and the electrode 551B.

A gap 104AB is provided between the layer 104B and the layer 104A and overlaps with the gap 551AB.

The layer 104B contains a material having a spin density higher than or equal to 1×10¹⁸ spins/cm³ observed by ESR spectroscopy when the material is in a film state.

### <<Structure Example 3 of Light-Emitting Device 550B>>

In the display apparatus 700 described in this embodiment, a gap 105AB is provided between the layer 105B and the layer 105A (see FIG. 6). The gap 105AB overlaps with the gap 551AB.

Accordingly, current flowing between the layer 104A and the layer 104B can be reduced. Occurrence of a phenomenon in which the light-emitting device 550B that is adjacent to the light-emitting device 550A unintentionally emits light in accordance with the operation of the light-emitting device 550A can be inhibited. Occurrence of a crosstalk phenomenon between the light-emitting devices can be inhibited. The color gamut that can be expressed by the display apparatus can be widened. The resolution of the display apparatus can be increased. As a result, a novel display apparatus that is highly convenient, useful, or reliable can be provided.

### <Structure Example 3 of Display Apparatus>

The display apparatus 700 described in this embodiment includes an insulating layer 521, the conductive film 552, and an insulating layer 529_2 (see FIG. 5A). The display apparatus 700 also includes the layer 105, a layer SCRA12, a layer SCRB12, a layer SCRC12, a layer 5291, and the insulating layer 5292. The layer 105 includes the layers 105A, 105B, and 105C.

### <<Structure Example of Insulating Layer 521>>

The insulating layer 521 overlaps with the conductive film 552 with the electrodes 551A and 551B therebetween.

### <<Structure Example of Conductive Film 552>>

The conductive film 552 includes the electrodes 552A and 552B.

### <<Structure Example of Insulating Layer 529_2>>

The insulating layer 529_2 is positioned between the conductive film 552 and the insulating layer 521. The insulating layer 529_2 overlaps with the gap 551AB and fills the gap 105AB.

The insulating layer 529_2 has an opening portion 529_2A and an opening portion 529_2B (see FIG. 5B). The insulating layer 529_2 also has an opening portion 529_2C. The opening portion 529_2A overlaps with the electrode 551A, and the opening portion 529_2B overlaps with the electrode 551B. The insulating layer 529_2 is in contact with the layer 105.

Thus, the gap 105AB can be filled with the insulating layer 529_2. A step formed between the light-emitting devices 550A and 550B can be reduced so as to be close to a flat plane. A phenomenon in which a cut or a split due to the step is generated in the conductive film 552 can be inhibited. As a result, a novel display apparatus that is highly convenient, useful, or reliable can be provided.

### <<Structure Examples of Layer SCRA12, Layer SCRB12, and Layer SCRC12>>

The layer SCRA12 is positioned between the conductive film 552 and the unit 103A. The layer SCRA12 has an opening portion overlapping with the electrode 551A.

A film containing a metal, a metal oxide, an organic material, or an inorganic insulating material can be used as the layer SCRA12, for example. Specifically, alight-blocking metal film can be used. This can block light with which the components are irradiated during the processing process to inhibit the characteristics of the light-emitting device from being degraded by the light. Moreover, in the processing process, the layer SCRA12 can reduce the influence of plasma or the like on the components that are positioned closer to the substrate 510 than the layer SCRA12 is.

The layer SCRB12 is positioned between the conductive film 552 and the unit 103B. The layer SCRB12 has an opening portion overlapping with the electrode 551B. For example, a material that can be used for the layer SCRA12 can be used for the layer SCRB12.

The layer SCRC12 is positioned between the conductive film 552 and the unit 103C. The layer SCRC12 has an opening portion overlapping with the electrode 551C. For example, a material that can be used for the layer SCRA12 can be used for the layer SCRC12.

### <Structure Example 4 of Display Apparatus>

The display apparatus 700 described in this embodiment has a structure in which the insulating layer 529_2 is in contact with the conductive film 552 (see FIG. 6), for example.

This embodiment can be combined with any of the other embodiments in this specification as appropriate.

### Embodiment 6

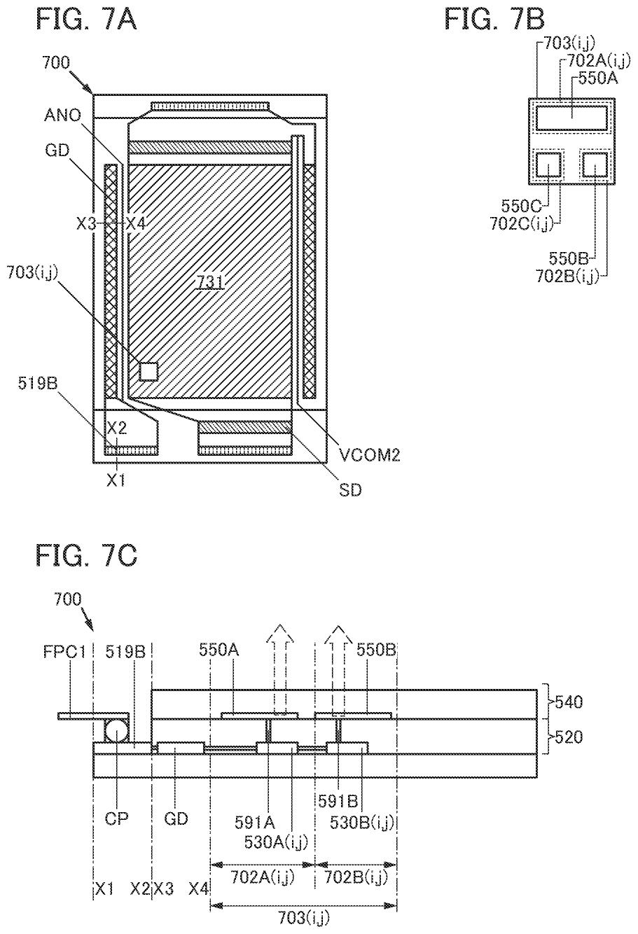

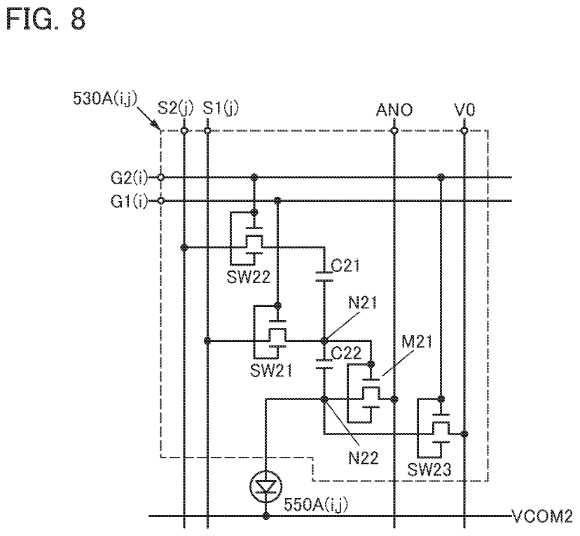

In this embodiment, a structure of the display apparatus of one embodiment of the present invention will be described with reference to FIGS. 7A to 7C and FIG. 8.

FIGS. 7A to 7C illustrate a structure of the display apparatus of one embodiment of the present invention. FIG. 7A is a top view of the display apparatus of one embodiment of the present invention, and FIG. 7B is a top view illustrating part of FIG. 7A. FIG. 7C illustrates cross sections taken along the cutting lines X1-X2 and X3-X4 in FIG. 7A and a cross section of a pixel set 703(i,j).

FIG. 8 is a circuit diagram illustrating the structure of the display apparatus of one embodiment of the present invention.

In this specification, an integer variable of 1 or more may be used for reference numerals. For example, “(p)” where p is an integer variable of 1 or more may be used for part of a reference numeral that specifies any one of up top components. For another example, “(m,n)” where each of m and n is an integer variable of 1 or more may be used for part of a reference numeral that specifies any one of up to m×n components.

### <Structure Example 1 of Display Apparatus 700>

The display apparatus 700 of one embodiment of the present invention includes a region 731 (see FIG. 7A). The region 731 includes the pixel set 703(i,j).

<<Structure Example 1 of Pixel Set 703(i,j)>>

The pixel set 703(i,j) includes a pixel 702A(i,j), a pixel 702B(i,j), and a pixel 702C(i,j) (see FIGS. 7B and 7C).

The pixel 702A(i,j) includes a pixel circuit 530A(i,j) and the light-emitting device 550A. The light-emitting device 550A is electrically connected to the pixel circuit 530A(i,j).

For example, the light-emitting device described in any of Embodiments 1 to 4 can be used as the light-emitting device 550A.

The pixel 702B(i,j) includes a pixel circuit 530B(i,j) and the light-emitting device 550B. The light-emitting device 550B is electrically connected to the pixel circuit 530B(i,j). Similarly, the pixel 702C(i,j) includes the light-emitting device 550C.

For example, the structure described in any of Embodiments 1 to 4 can be employed for the light-emitting devices 550B and 550C.

### <Structure Example 2 of Display Apparatus 700>

The display apparatus 700 of one embodiment of the present invention includes a functional layer 540 and the functional layer 520 (see FIG. 7C). The functional layer 540 overlaps with the functional layer 520.

The functional layer 540 includes the light-emitting device 550A.

The functional layer 520 includes the pixel circuit 530A(i,j) and a wiring (see FIG. 7C). The pixel circuit 530A(i,j) is electrically connected to the wiring. For example, a conductive film provided in an opening portion 591A in the functional layer 520 can be used for the wiring. The wiring electrically connects a terminal 519B to the pixel circuit 530A(i,j). Note that a conductive material CP electrically connects the terminal 519B to a flexible printed circuit FPC1. In addition, a conductive film provided in an opening portion 591B in the functional layer 520 can be used for the wiring, for example.

### <Structure Example 3 of Display Apparatus 700>

The display apparatus 700 of one embodiment of the present invention includes a driver circuit GD and a driver circuit SD (see FIG. 7A).

### <<Structure Example of Driver Circuit GD>>

The driver circuit GD supplies a first selection signal and a second selection signal.

### <<Structure Example of Driver Circuit SD>>

The driver circuit SD supplies a first control signal and a second control signal.

### <<Structure Example of Wiring>>

As the wiring, a conductive film G1(i), a conductive film G2(i), a conductive film S1(j), a conductive film S2(j), a conductive film ANO, a conductive film VCOM2, and a conductive film VO are included (see FIG. 8).

The conductive film G1(i) is supplied with the first selection signal, and the conductive film G2(i) is supplied with the second selection signal.

The conductive film S1(j) is supplied with the first control signal, and the conductive film S2(j) is supplied with the second control signal.

### <<Structure Example 1 of Pixel Circuit 530A(i,j)>>

The pixel circuit 530A(i,j) is electrically connected to the conductive film G1(i) and the conductive film S1(1). The conductive film G1(i) supplies the first selection signal, and the conductive film S1(j) supplies the first control signal.

The pixel circuit 530A(i,j) drives the light-emitting device 550A in response to the first selection signal and the first control signal. The light-emitting device 550A emits light.

One electrode of the light-emitting device 550A is electrically connected to the pixel circuit 530A(i,j) and the other electrode is electrically connected to the conductive film VCOM2.

### <<Structure Example 2 of Pixel Circuit 530A(i,j)>>

The pixel circuit 530A(i,j) includes a switch SW21, a switch SW22, a transistor M21, a capacitor C21, and a node N21.

The transistor M21 includes a gate electrode electrically connected to the node N21, a first electrode electrically connected to the light-emitting device 550A, and a second electrode electrically connected to the conductive film ANO.

The switch SW21 includes a first terminal electrically connected to the node N21, a second terminal electrically connected to the conductive film S1(j), and a gate electrode having a function of controlling an on/off state of the switch SW21 on the basis of the potential of the conductive film G1(i).

The switch SW22 includes a first terminal electrically connected to the conductive film S2(j), and a gate electrode having a function of controlling an on/off state of the switch SW22 on the basis of the potential of the conductive film G2(i).

The capacitor C21 includes a conductive film electrically connected to the node N21 and a conductive film electrically connected to a second terminal of the switch SW22.

Accordingly, an image signal can be stored in the node N21. Alternatively, the potential of the node N21 can be changed using the switch SW22. Alternatively, the intensity of light emitted from the light-emitting device 550A can be controlled with the potential of the node N21. As a result, a novel apparatus that is highly convenient, useful, or reliable can be provided.

### <<Structure Example 3 of Pixel Circuit 530A(i,j)>>

The pixel circuit 530A(i,j) includes a switch SW23, a node N22, and a capacitor C22.

The switch SW23 includes a first terminal electrically connected to the conductive film VO, a second terminal electrically connected to the node N22, and a gate electrode having a function of controlling an on/off state of the switch SW23 on the basis of the potential of the conductive film G2(i).

The capacitor C22 includes a conductive film electrically connected to the node N21 and a conductive film electrically connected to the node N22.

The first electrode of the transistor M21 is electrically connected to the node N22.

This embodiment can be combined with any of the other embodiments in this specification as appropriate.

### Embodiment 7

In this embodiment, a display module of one embodiment of the present invention will be described.

### <Display Module>

FIG. 9 is a perspective view illustrating a structure of a display module 280.

The display module 280 includes a display apparatus 100 and one of an FPC 290 and a connector. The display apparatus 100 includes a display region 80. The display apparatus described in Embodiment 5 can be used as the display apparatus 100, for example.

The FPC 290 is supplied with a signal and electric power from the outside and supplies the signal and the electric power to the display apparatus 100. An IC may be mounted on the FPC 290. Note that a connector is a mechanical component for electrical connection through a conductor, and the conductor can electrically connect the display apparatus 100 to a component to be connected. For example, the FPC 290 can be used as the conductor. The connector can detach the display apparatus 100 from the connected component.

### <<Display Apparatus 100A>>

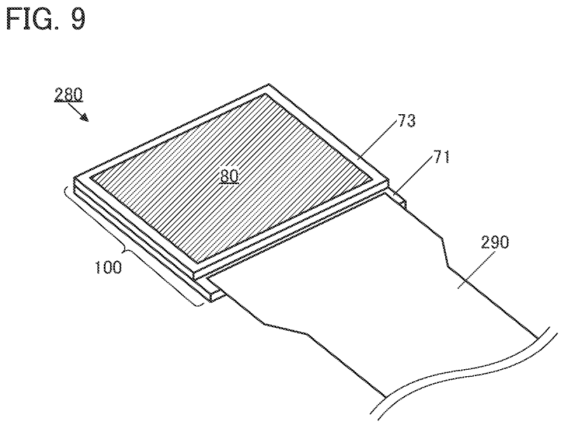

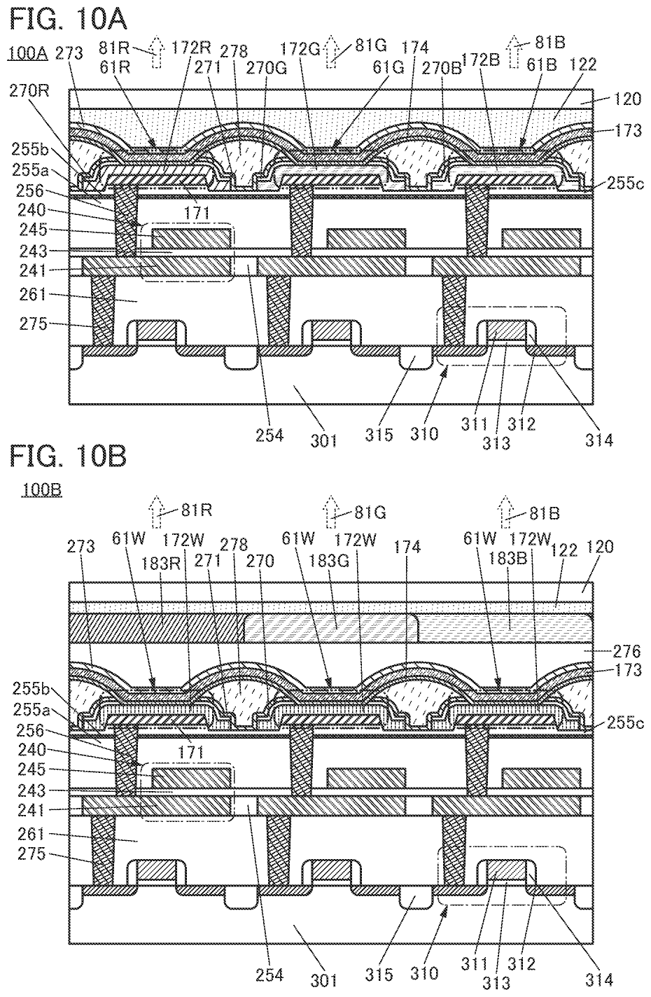

FIG. 10A is a cross-sectional view illustrating a structure of a display apparatus 100A. The display apparatus 100A can be used as the display apparatus 100 of the display module 280, for example. A substrate 301 corresponds to a substrate 71 in FIG. 9.

The display apparatus 100A includes the substrate 301, a transistor 310, an element isolation layer 315, an insulating layer 261, a capacitor 240, an insulating layer 255a, an insulating layer 255b, an insulating layer 255c, a light-emitting device 61R, a light-emitting device 61G, and a light-emitting device 61B. The insulating layer 261 is provided over the substrate 301, and the transistor 310 is positioned between the substrate 301 and the insulating layer 261. The insulating layer 255a is provided over the insulating layer 261, the capacitor 240 is positioned between the insulating layer 261 and the insulating layer 255a, and the insulating layer 255a is positioned between the capacitors 240 and the light-emitting devices 61R, 61G, and 61B.

### [Transistor 310]

The transistor 310 includes a conductive layer 311, a pair of low-resistance regions 312, an insulating layer 313, and an insulating layer 314, and its channel is formed in part of the substrate 301. The conductive layer 311 functions as a gate electrode. The insulating layer 313 is positioned between the substrate 301 and the conductive layer 311 and functions as a gate insulating layer. The substrate 301 includes the pair of low-resistance regions 312 doped with an impurity. Note that such regions function as a source and a drain. The side surface of the conductive layer 311 is covered with the insulating layer 314.

The element isolation layer 315 is embedded in the substrate 301, and positioned between two adjacent transistors 310.

### [Capacitor 240]

The capacitor 240 includes a conductive layer 241, a conductive layer 245, and an insulating layer 243, and the insulating layer 243 is positioned between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is positioned over the insulating layer 261 and is embedded in an insulating layer 254. The conductive layer 241 is electrically connected to one of the source and the drain of the transistor 310 through a plug 275 embedded in the insulating layer 261. The insulating layer 243 covers the conductive layer 241. The conductive layer 245 overlaps with the conductive layer 241 with the insulating layer 243 therebetween.

[Insulating Layer 255a, Insulating Layer 255b, and Insulating Layer 255c]

The display apparatus 100A includes the insulating layer 255a, the insulating layer 255b, and the insulating layer 255c, and the insulating layer 255b is positioned between the insulating layer 255a and the insulating layer 255c.

### [Light-Emitting Device 61R, Light-Emitting Device 61G, and Light-Emitting Device 61B]

The light-emitting devices 61R, 61G, and 61B are provided over the insulating layer 255c. For example, the light-emitting device described in any of Embodiments 1 to 4 can be used as each of the light-emitting devices 61R, 61G, and 61B. The light-emitting device 61R, the light-emitting device 61G, and the light-emitting device 61B emit light 81R, light 81G, and light 81B, respectively. The light-emitting devices include a common layer 174.

The light-emitting device 61R includes a conductive layer 171 and an EL layer 172R, and the EL layer 172R covers the top and side surfaces of the conductive layer 171. A sacrificial layer 270 includes sacrificial layers 270R, 270G, and 270B. The sacrificial layer 270R is positioned over the EL layer 172R. The light-emitting device 61G includes the conductive layer 171 and an EL layer 172G, and the EL layer 172G covers the top and side surfaces of the conductive layer 171. The sacrificial layer 270G is positioned over the EL layer 172G. The light-emitting device 61B includes the conductive layer 171 and an EL layer 172B, and the EL layer 172B covers the top and side surfaces of the conductive layer 171. The sacrificial layer 270B is positioned over the EL layer 172B.

The conductive layer 171 is electrically connected to one of the source and the drain of the transistor 310 through a plug 256 embedded in the insulating layers 243, 255a, 255b, and 255c, the conductive layer 241 embedded in the insulating layer 254, and the plug 275 embedded in the insulating layer 261. The top surface of the insulating layer 255c and the top surface of the plug 256 are level with or substantially level with each other. Any of a variety of conductive materials can be used for the plugs.

### [Protective Layer 271, Insulating Layer 278, Protective Layer 273, and Bonding Layer 122]

A protective layer 271 and an insulating layer 278 are positioned between adjacent light-emitting devices, e.g., between the light-emitting device 61R and the light-emitting device 61G, and the insulating layer 278 is provided over the protective layer 271. A protective layer 273 is provided over the light-emitting devices 61R, 61G, and 61B.

A bonding layer 122 attaches the protective layer 273 to a substrate 120.

### [Substrate 120]

The substrate 120 corresponds to a substrate 73 in FIG. 9. A light-blocking layer can be provided on the surface of the substrate 120 on the bonding layer 122 side, for example. A variety of optical members can be provided on the outer surface of the substrate 120.

A film can be used as the substrate. In particular, a film with a low water absorption rate can be suitably used. For example, the water absorption rate is preferably 1% or lower, further preferably 0.1% or lower. Thus, a change in size of the film can be inhibited. Furthermore, generation of wrinkles or the like can be inhibited. Moreover, a change in shape of the display apparatus can be inhibited.

For example, a polarizing plate, a retardation plate, a light diffusion layer (e.g., a diffusion film), an anti-reflection layer, a light-condensing film, or the like can be used as the optical member.

It is possible that a highly optically isotropic material, i.e., a material with a low birefringence index, is used for the substrate and a circularly polarizing plate is provided to overlap with the display apparatus. For example, it is possible to use, for the substrate, a material that has an absolute value of a retardation (phase difference) of 30 nm or less, preferably 20 nm or less, further preferably 10 nm or less. For example, a triacetyl cellulose (TAC, also referred to as cellulose triacetate) film, a cycloolefin polymer (COP) film, a cycloolefin copolymer (COC) film, or an acrylic resin film can be used as a highly optically isotropic film.

Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer, a silica layer (SiOₓ layer), diamond like carbon (DLC), aluminum oxide (AlOₓ), a polyester-based material, a polycarbonate-based material, or the like can be used for the surface protective layer. Note that a material having a high visible light transmittance can be suitably used for the surface protective layer. In addition, a material having high hardness can be suitably used for the surface protective layer.

### <<Display Apparatus 100B>>

FIG. 10B is a cross-sectional view illustrating a structure of a display apparatus 100B. The display apparatus 100B can be used as the display apparatus 100 of the display module 280, for example (see FIG. 9).

The display apparatus 100B includes the substrate 301, a light-emitting device 61W, the capacitor 240, and the transistor 310. The light-emitting device 61W can emit white light, for example.

The display apparatus 100B includes a coloring layer 183R, a coloring layer 183G, and a coloring layer 183B. The coloring layer 183R includes a region overlapping with one light-emitting device 61W, the coloring layer 183G includes a region overlapping with another light-emitting device 61W, and the coloring layer 183B includes a region overlapping with another light-emitting device 61W. In the display apparatus 100B, a gap 276 is positioned between the light-emitting devices and the coloring layers.

For example, the coloring layer 183R, the coloring layer 183G, and the coloring layer 183B can transmit red light, green light, and blue light, respectively.

### <<Display Apparatus 100C>>

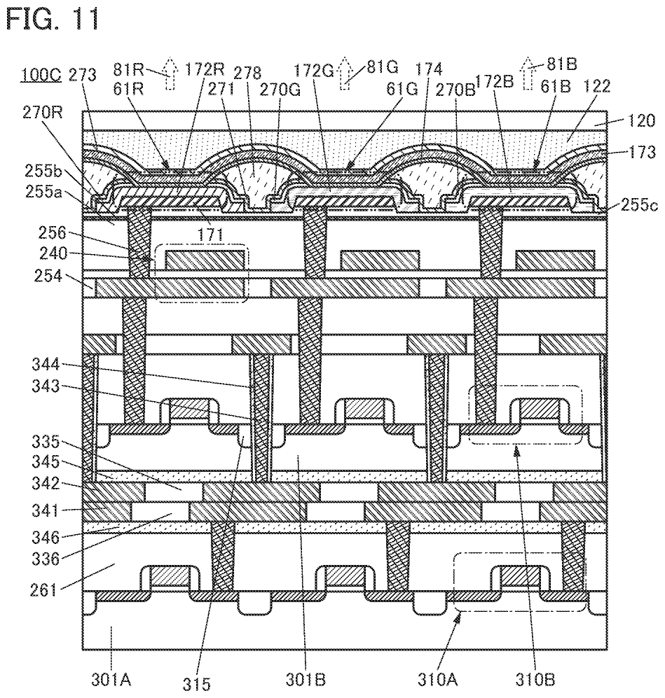

FIG. 11 is a cross-sectional view illustrating a structure of a display apparatus 100C. The display apparatus 100C can be used as the display apparatus 100 of the display module 280, for example (see FIG. 9). Note that in the following description of display apparatuses, the description of portions similar to those of the above-described display apparatuses may be omitted.

The display apparatus 100C includes a substrate 301B and a substrate 301A. The display apparatus 100C includes a transistor 310B, the capacitor 240, the light-emitting devices 61R, 61G, and 61B, and a transistor 310A. A channel of the transistor 310A is formed in part of the substrate 301A and a channel of the transistor 310B is formed in part of the substrate 301B.

### [Insulating Layer 345 and Insulating Layer 346]

An insulating layer 345 is in contact with the bottom surface of the substrate 301B, and an insulating layer 346 is positioned over the insulating layer 261. For example, the inorganic insulating film that can be used as the protective layer 273 can be used as the insulating layers 345 and 346. The insulating layers 345 and 346 function as protective layers and can inhibit diffusion of impurities into the substrates 301B and 301A.

### [Plug 343]

A plug 343 penetrates the substrate 301B and the insulating layer 345. An insulating layer 344 covers the side surface of the plug 343. For example, the inorganic insulating film that can be used as the protective layer 273 can be used as the insulating layer 344. The insulating layer 344 functions as a protective layer and can inhibit diffusion of impurities into the substrate 301B.

### [Conductive Layer 342]

A conductive layer 342 is positioned between the insulating layer 345 and the insulating layer 346. It is preferable that the conductive layer 342 be embedded in an insulating layer 335 and a plane formed by the conductive layer 342 and the insulating layer 335 be flat. Note that the conductive layer 342 is electrically connected to the plug 343.

### [Conductive Layer 341]

A conductive layer 341 is positioned between the insulating layer 346 and the insulating layer 335. It is preferable that the conductive layer 341 be embedded in an insulating layer 336 and a plane formed by the conductive layer 341 and the insulating layer 336 be flat. The conductive layer 341 is bonded to the conductive layer 342. Thus, the substrate 301A is electrically connected to the substrate 301B.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). It is particularly preferable to use copper for the conductive layers 341 and 342. In that case, it is possible to employ copper-to-copper (Cu-to-Cu) direct bonding (a technique for achieving electrical continuity by connecting copper (Cu) pads).

### <<Display Apparatus 100D>>

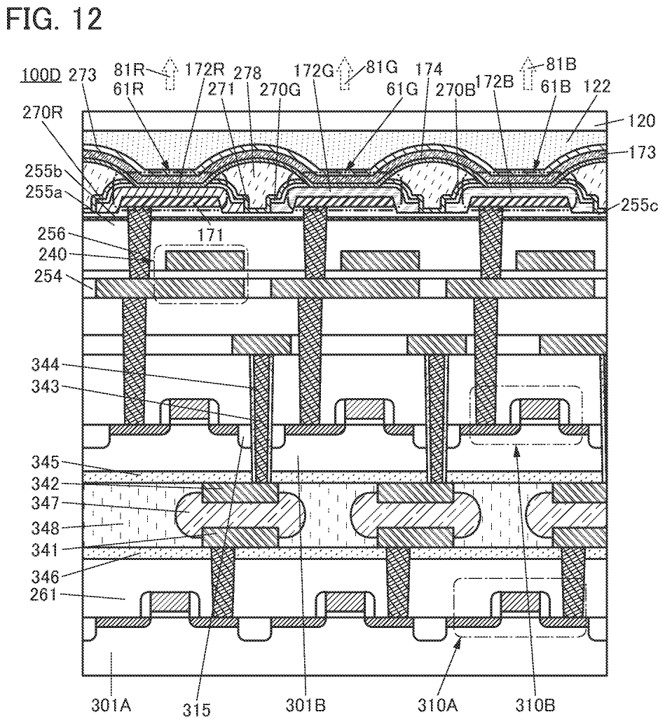

FIG. 12 is a cross-sectional view illustrating a structure of a display apparatus 100D. The display apparatus 100D can be used as the display apparatus 100 of the display module 280, for example (see FIG. 9).

The display apparatus 100D includes a bump 347, and the bump 347 bonds the conductive layer 341 to the conductive layer 342. The bump 347 electrically connects the conductive layer 341 to the conductive layer 342. The bump 347 can be formed using a conductive material containing gold (Au), nickel (Ni), indium (In), tin (Sn), or the like, for example. Solder can be used for the bump 347, for example.

The display apparatus 100D includes a bonding layer 348. The bonding layer 348 attaches the insulating layer 345 to the insulating layer 346.

### <<Display Apparatus 100E>>

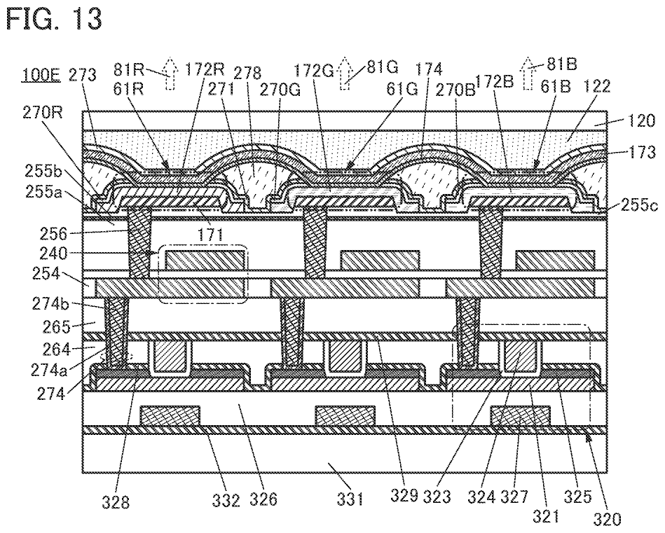

FIG. 13 is a cross-sectional view illustrating a structure of a display apparatus 100E. The display apparatus 100E can be used as the display apparatus 100 of the display module 280, for example (see FIG. 9). A substrate 331 corresponds to the substrate 71 in FIG. 9. An insulating substrate or a semiconductor substrate can be used as the substrate 331. The display apparatus 100E includes a transistor 320. Note that the display apparatus 100E is different from the display apparatus 100A in that the transistor is an OS transistor.

### [Insulating Layer 332]

An insulating layer 332 is provided over the substrate 331. For example, a film in which hydrogen or oxygen is less likely to diffuse than in a silicon oxide film can be used as the insulating layer 332. Specifically, an aluminum oxide film, a hafnium oxide film, a silicon nitride film, or the like can be used as the insulating layer 332. Thus, the insulating layer 332 can prevent diffusion of impurities such as water and hydrogen from the substrate 331 into the transistor 320. Furthermore, release of oxygen from a semiconductor layer 321 to the insulating layer 332 side can be prevented.

### [Transistor 320]

The transistor 320 includes the semiconductor layer 321, an insulating layer 323, a conductive layer 324, a pair of conductive layers 325, an insulating layer 326, and a conductive layer 327.

The conductive layer 327 is provided over the insulating layer 332 and functions as a first gate electrode of the transistor 320. The insulating layer 326 covers the conductive layer 327. Part of the insulating layer 326 functions as a first gate insulating layer. The insulating layer 326 includes an oxide insulating film at least in a region in contact with the semiconductor layer 321. Specifically, a silicon oxide film or the like is preferably used. The insulating layer 326 has a flat top surface. The semiconductor layer 321 is provided over the insulating layer 326. A metal oxide film having semiconductor characteristics can be used as the semiconductor layer 321. The pair of conductive layers 325 is provided over and in contact with the semiconductor layer 321, and functions as a source electrode and a drain electrode.

### [Insulating Layer 328 and Insulating Layer 264]

An insulating layer 328 covers the top and side surfaces of the pair of conductive layers 325, the side surface of the semiconductor layer 321, and the like. An insulating layer 264 is provided over the insulating layer 328 and functions as an interlayer insulating layer. The insulating layers 328 and 264 have an opening portion reaching the semiconductor layer 321. For example, an insulating film similar to the insulating layer 332 can be used as the insulating layer 328. Thus, the insulating layer 328 can prevent diffusion of impurities such as water and hydrogen from the insulating layer 264 into the semiconductor layer 321, for example. Furthermore, release of oxygen from the semiconductor layer 321 can be prevented.

### [Insulating Layer 323]

The insulating layer 323 is in contact with the side surfaces of the insulating layers 264 and 328 and the conductive layer 325 and the top surface of the semiconductor layer 321 inside the opening portion.

### [Conductive Layer 324]

Inside the opening portion, the conductive layer 324 is embedded and in contact with the insulating layer 323. The top surface of the conductive layer 324 is subjected to planarization treatment and is level with or substantially level with the top surfaces of the insulating layers 323 and 264. The conductive layer 324 functions as a second gate electrode, and the insulating layer 323 functions as a second gate insulating layer.

### [Insulating Layer 329 and Insulating Layer 265]

An insulating layer 329 covers the conductive layer 324 and the insulating layers 323 and 264. An insulating layer 265 is provided over the insulating layer 329 and functions as an interlayer insulating layer. For example, an insulating film similar to the insulating layers 328 and 332 can be used as the insulating layer 329. Thus, diffusion of impurities such as water and hydrogen from the insulating layer 265 into the transistor 320 can be prevented, for example.

### [Plug 274]

A plug 274 is embedded in the insulating layers 265, 329, 264, and 328 and is electrically connected to one of the pair of conductive layers 325. The plug 274 includes a conductive layer 274a and a conductive layer 274b. The conductive layer 274a is in contact with the side surface of an opening portion formed in the insulating layers 265, 329, 264, and 328. In addition, the conductive layer 274a covers part of the top surface of the conductive layer 325. The conductive layer 274b is in contact with the top surface of the conductive layer 274a. For example, a conductive material in which hydrogen and oxygen are unlikely to diffuse can be suitably used for the conductive layer 274a.

### <<Display Apparatus 100F>>

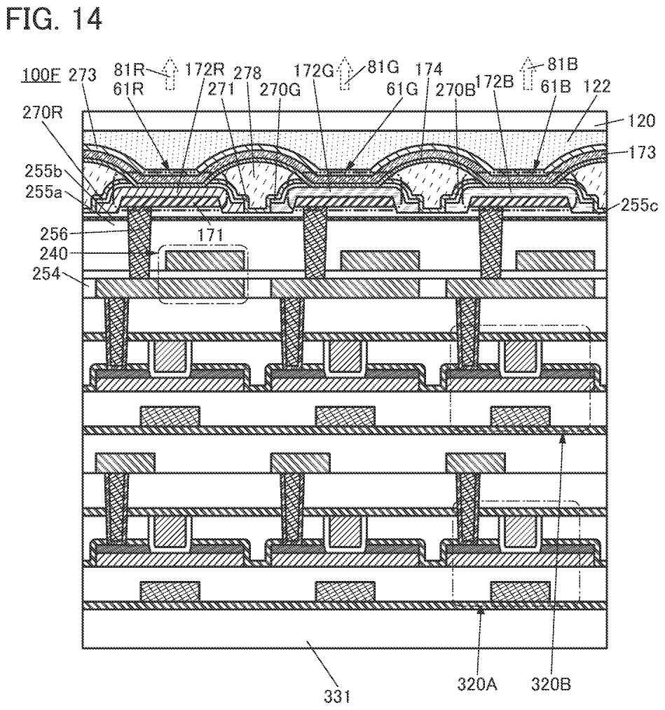

FIG. 14 is a cross-sectional view illustrating a structure of a display apparatus 100F. The display apparatus 100F has a structure in which a transistor 320A and a transistor 320B are stacked. Each of the transistors 320A and 320B includes an oxide semiconductor and a channel formed in the oxide semiconductor. Note that the number of stacked transistors is not limited to two, and three or more transistors may be stacked, for example.

The structures of the transistor 320A and the peripheral components are the same as those of the transistor 320 and the peripheral components of the display apparatus 100E. The structures of the transistor 320B and the peripheral components are the same as those of the transistor 320 and the peripheral components of the display apparatus 100E.

### <<Display Apparatus 100G>>

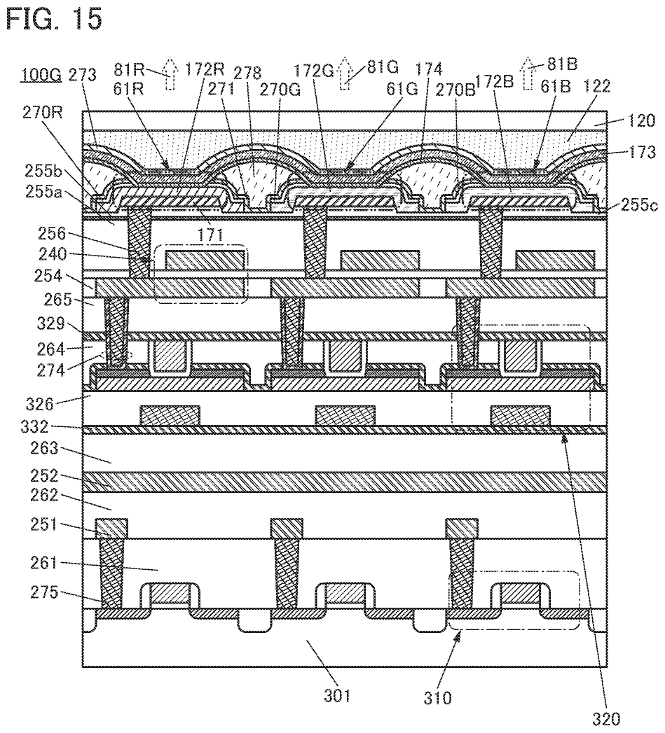

FIG. 15 is a cross-sectional view illustrating a structure of a display apparatus 100G. The display apparatus 100G has a structure in which the transistor 310 and the transistor 320 are stacked. The channel of the transistor 310 is formed in the substrate 301. The transistor 320 includes an oxide semiconductor and the channel formed in the oxide semiconductor.

The insulating layer 261 covers the transistor 310 and a conductive layer 251 is provided over the insulating layer 261. An insulating layer 262 covers the conductive layer 251 and a conductive layer 252 is provided over the insulating layer 262. An insulating layer 263 and the insulating layer 332 cover the conductive layer 252. The conductive layer 251 and the conductive layer 252 each function as a wiring.

The transistor 320 is provided over the insulating layer 332 and the insulating layer 265 covers the transistor 320. The capacitor 240 is provided over the insulating layer 265 and is electrically connected to the transistor 320 through the plug 274.

For example, the transistor 320 can be used as a transistor included in a pixel circuit. For another example, the transistor 310 can be used as a transistor included in a pixel circuit or for a driver circuit (e.g., a gate driver circuit or a source driver circuit) for driving the pixel circuit. The transistor 310 and the transistor 320 can be used for a variety of circuits such as an arithmetic circuit and a memory circuit. Thus, not only a pixel circuit but also a driver circuit can be provided directly under the light-emitting device, for example. The display apparatus can be downsized as compared to the case where a driver circuit is provided around a display region.

At least part of this embodiment can be implemented in combination with any of the other embodiments described in this specification, as appropriate.

### Embodiment 8

In this embodiment, a display module of one embodiment of the present invention will be described.

### <Display Module>

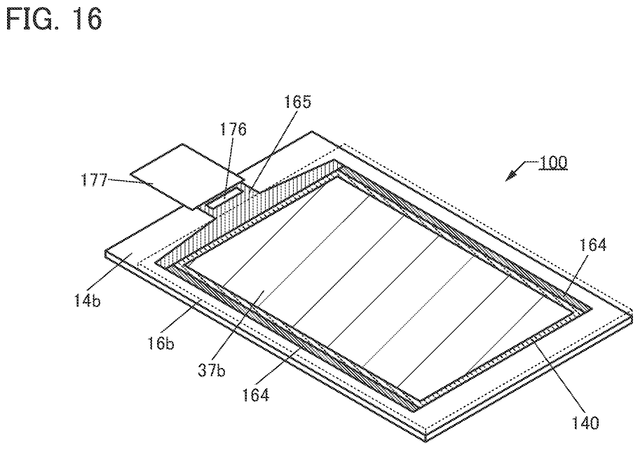

FIG. 16 is a perspective view illustrating a structure of a display module.

The display module includes the display apparatus 100, an integrated circuit (IC) 176, and one of an FPC 177 and a connector. The display apparatus described in Embodiment 5 can be used as the display apparatus 100, for example.

The display apparatus 100 is electrically connected to the IC 176 and the FPC 177. The FPC 177 is supplied with a signal and electric power from the outside and supplies the signal and the electric power to the display apparatus 100. Note that a connector is a mechanical component for electrical connection through a conductor, and the conductor can electrically connect the display apparatus 100 to a component to be connected. For example, the FPC 177 can be used as the conductor. The connector can detach the display apparatus 100 from the connected component.

The display module includes the IC 176. For example, the IC 176 can be provided for a substrate 14b by a chip on glass (COG) method or the like. Alternatively, for example, the IC 176 can be provided for an FPC by a chip on film (COF) method or the like. Note that a gate driver circuit, a source driver circuit, or the like can be used as the IC 176, for example.

### <<Display Apparatus 100H>>

FIG. 17A is a cross-sectional view illustrating a structure of a display apparatus 100H.

The display apparatus 100H includes a display portion 37b, a connection portion 140, a circuit 164, a wiring 165, and the like. The display apparatus 100H includes a substrate 16b and the substrate 14b, which are bonded to each other. The display apparatus 100H includes one or more connection portions 140. The connection portion(s) 140 can be provided outside the display portion 37b. For example, the connection portion(s) 140 can be provided along one side of the display portion 37b. Alternatively, the connection portion(s) 140 can be provided along a plurality of sides; for example, the connection portion(s) 140 can be provided to surround four sides. In the connection portion 140, a common electrode of a light-emitting device is electrically connected to a conductive layer, which supplies a predetermined potential to the common electrode.

The wiring 165 is supplied with a signal and electric power from the FPC 177 or the IC 176. The wiring 165 supplies the signal and the electric power to the display portion 37b and the circuit 164.

For example, a gate driver circuit can be used as the circuit 164.

The display apparatus 100H includes the substrate 14b, the substrate 16b, a transistor 201, a transistor 205, a light-emitting device 63R, a light-emitting device 63G, alight-emitting device 63B, and the like (see FIG. 17A). For example, the light-emitting device 63R emits red light 83R, the light-emitting device 63G emits green light 83G, and the light-emitting device 63B emits blue light 83B. Note that a variety of optical members can be provided on the outer surface of the substrate 16b. For example, a polarizing plate, a retardation plate, a light diffusion layer (e.g., a diffusion film), an anti-reflection layer, a light-condensing film, or the like can be provided.

For example, the light-emitting device described in any of Embodiments 1 to 4 can be used as each of the light-emitting devices 63R, 63G, and 63B.

The light-emitting devices include the conductive layer 171, which functions as a pixel electrode. The conductive layer 171 has a depressed portion, which overlaps with an opening portion provided in an insulating layer 214, an insulating layer 215, and an insulating layer 213. The transistor 205 includes a conductive layer 222b, which is electrically connected to the conductive layer 171.

The display apparatus 100H includes an insulating layer 272. The insulating layer 272 covers an end portion of the conductive layer 171 to fill the depressed portion of the conductive layer 171 (see FIG. 17A).

The display apparatus 100H includes the protective layer 273 and a bonding layer 142. The protective layer 273 covers the light-emitting devices 63R, 63G, and 63B. The protective layer 273 and the substrate 16b are bonded to each other with the bonding layer 142. The bonding layer 142 fills a gap between the substrate 16b and the protective layer 273. For example, the bonding layer 142 may be formed in a frame shape so as not to overlap with the light-emitting devices, and a region surrounded by the bonding layer 142, the substrate 16b, and the protective layer 273 may be filled with a resin different from the material of the bonding layer 142. Alternatively, a hollow sealing structure may be employed, in which the region is filled with an inert gas (e.g., nitrogen or argon). For example, the material that can be used for the bonding layer 122 can be used for the bonding layer 142.

The display apparatus 100H includes the connection portion 140, which includes a conductive layer 168. Note that a power supply potential is supplied to the conductive layer 168. The light-emitting devices include a conductive layer 173. The conductive layer 173 is electrically connected to the conductive layer 168 and is supplied with a power supply potential. Note that the conductive layer 173 functions as a common electrode. For example, the conductive layer 171 and the conductive layer 168 can be formed by processing one conductive film.

The display apparatus 100H has a top-emission structure. The light-emitting devices emit light to the substrate 16b side. The conductive layer 171 contains a material reflecting visible light, and the conductive layer 173 transmits visible light.

### [Insulating Layer 211, Insulating Layer 213, Insulating Layer 215, and Insulating Layer 214]

An insulating layer 211, the insulating layer 213, the insulating layer 215, and the insulating layer 214 are provided in this order over the substrate 14b. Note that the number of insulating layers is not limited and may be one, or two or more.

For example, an inorganic insulating film can be used as each of the insulating layers 211, 213, and 215. For example, a silicon nitride film, a silicon oxynitride film, a silicon oxide film, a silicon nitride oxide film, an aluminum oxide film, an aluminum nitride film, or the like can be used. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

The insulating layers 215 and 214 cover the transistors. The insulating layer 214 functions as a planarization layer. For example, a material in which impurities such as water and hydrogen are unlikely to diffuse is preferably used for the insulating layer 215 or the insulating layer 214. This can effectively inhibit diffusion of impurities to the transistors from the outside. Furthermore, the reliability of the display apparatus can be improved.

For example, an organic insulating layer can be suitably used as the insulating layer 214. Specifically, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the organic insulating layer. Alternatively, the insulating layer 214 can have a stacked-layer structure of an organic insulating layer and an inorganic insulating layer. Thus, the outermost layer of the insulating layer 214 can be used as an etching protective layer. For example, a phenomenon in which a depressed portion is formed in the insulating layer 214 at the time of processing the conductive layer 171 into a predetermined shape can be inhibited when such a phenomenon should be avoided.

### [Transistor 201 and Transistor 205]

The transistor 201 and the transistor 205 are formed over the substrate 14b. These transistors can be fabricated using the same materials in the same steps.

Each of the transistors 201 and 205 includes a conductive layer 221, the insulating layer 211, a conductive layer 222a, the conductive layer 222b, a semiconductor layer 231, the insulating layer 213, and a conductive layer 223. The insulating layer 211 is positioned between the conductive layer 221 and the semiconductor layer 231. The conductive layer 221 functions as a gate and the insulating layer 211 functions as a first gate insulating layer. The conductive layer 222a and the conductive layer 222b function as a source and a drain. The insulating layer 213 is positioned between the conductive layer 223 and the semiconductor layer 231. The conductive layer 223 functions as a gate and the insulating layer 213 functions as a second gate insulating layer. Here, a plurality of layers obtained by processing the same conductive film are shown with the same hatching pattern.

There is no particular limitation on the structure of the transistors included in the display apparatus of this embodiment. For example, a planar transistor, a staggered transistor, an inverted staggered transistor, or the like can be used. A top-gate transistor or a bottom-gate transistor may be used. Alternatively, gates may be provided above and below a semiconductor layer where a channel is formed.

The transistors 201 and 205 each have the structure in which the semiconductor layer where a channel is formed is positioned between two gates. The two gates may be connected to each other and supplied with the same signal to operate the transistor. Alternatively, the threshold voltage of the transistor may be controlled by supplying a potential for controlling the threshold voltage to one of the two gates and a potential for driving to the other of the two gates.

There is no particular limitation on the crystallinity of the semiconductor layer of each of the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable to use a semiconductor having crystallinity, in which case deterioration of the transistor characteristics can be inhibited.

The semiconductor layer of each of the transistors preferably contains a metal oxide. That is, an OS transistor is preferably used as each of the transistors included in the display apparatus of this embodiment.

### [Semiconductor Layer]

For example, indium oxide, gallium oxide, and zinc oxide can be used for the semiconductor layer. The metal oxide preferably contains two or three selected from indium, an element M, and zinc. The element M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more of aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). It is preferable to use an oxide containing indium, gallium, tin, and zinc. It is preferable to use an oxide containing indium (In), aluminum (Al), and zinc (Zn) (also referred to as IAZO). It is preferable to use an oxide containing indium (In), aluminum (Al), gallium (Ga), and zinc (Zn) (also referred to as IAGZO).

When the metal oxide used for the semiconductor layer is an In-M-Zn oxide, the atomic ratio of In is preferably greater than or equal to the atomic ratio of M in the In-M-Zn oxide. Examples of the atomic ratio of the metal elements in such an In-M-Zn oxide include In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, when the atomic ratio is described as In:Ga:Zn=4:2:3 or a composition in the vicinity thereof, the case is included where the atomic ratio of Ga is greater than or equal to 1 and less than or equal to 3 and the atomic ratio of Zn is greater than or equal to 2 and less than or equal to 4 with the atomic ratio of In being 4. In addition, when the atomic ratio is described as In:Ga:Zn=5:1:6 or a composition in the vicinity thereof, the case is included where the atomic ratio of Ga is greater than 0.1 and less than or equal to 2 and the atomic ratio of Zn is greater than or equal to 5 and less than or equal to 7 with the atomic ratio of In being 5. Furthermore, when the atomic ratio is described as In:Ga:Zn=1:1:1 or a composition in the vicinity thereof, the case is included where the atomic ratio of Ga is greater than 0.1 and less than or equal to 2 and the atomic ratio of Zn is greater than 0.1 and less than or equal to 2 with the atomic ratio of In being 1.

The semiconductor layer may include two or more metal oxide layers having different compositions. For example, a stacked-layer structure of a first metal oxide layer having an atomic ratio of In:M:Zn=1:3:4 or a composition in the vicinity thereof and a second metal oxide layer having an atomic ratio of In:M:Zn=1:1:1 or a composition in the vicinity thereof and being formed over the first metal oxide layer can be suitably employed. In particular, gallium or aluminum is preferably used as the element M.

Alternatively, a stacked-layer structure of one selected from indium oxide, indium gallium oxide, and IGZO, and one selected from IAZO, IAGZO, and ITZO (registered trademark) may be employed, for example.

Examples of an oxide semiconductor having crystallinity include a c-axis-aligned crystalline oxide semiconductor (CAAC-OS) and a nanocrystalline oxide semiconductor (nc-OS).

Alternatively, a transistor containing silicon in its channel formation region (a S1 transistor) may be used. Examples of silicon include single crystal silicon, polycrystalline silicon, and amorphous silicon. In particular, a transistor containing low-temperature polysilicon (LTPS) in its semiconductor layer (also referred to as an LTPS transistor) can be used. The LTPS transistor has high field-effect mobility and excellent frequency characteristics.

With the use of S1 transistors such as LTPS transistors, a circuit required to be driven at a high frequency (e.g., a data driver circuit) can be formed on the same substrate as the display portion. This allows simplification of an external circuit mounted on the display apparatus and a reduction in costs of parts and mounting costs.

An OS transistor has much higher field-effect mobility than a transistor containing amorphous silicon. In addition, an OS transistor has an extremely low leakage current between a source and a drain in an off state (also referred to as off-state current), and charge accumulated in a capacitor that is connected in series to the transistor can be retained for a long period. Furthermore, the use of an OS transistor can reduce the power consumption of the display apparatus.

To increase the luminance of a light-emitting device included in a pixel circuit, the amount of current fed through the light-emitting device needs to be increased. To increase the current amount, the source-drain voltage of a driving transistor included in the pixel circuit needs to be increased. An OS transistor has a higher withstand voltage between a source and a drain than a S1 transistor; hence, a high voltage can be applied between the source and the drain of the OS transistor. Therefore, when an OS transistor is used as the driving transistor included in the pixel circuit, the amount of current flowing through the light-emitting device can be increased, so that the luminance of the light-emitting device can be increased.

When transistors are driven in a saturation region, a change in source-drain current relative to a change in gate-source voltage can be smaller in an OS transistor than in a S1 transistor. Accordingly, when an OS transistor is used as the driving transistor included in the pixel circuit, current flowing between the source and the drain can be minutely determined by controlling the gate-source voltage. Thus, the amount of current flowing through the light-emitting device can be controlled. Consequently, the number of gray levels expressed by the pixel circuit can be increased.

Regarding saturation characteristics of current flowing when transistors are driven in the saturation region, even when the source-drain voltage of an OS transistor increases gradually, a more stable current (saturation current) can be fed through the OS transistor than through a S1 transistor. Thus, by using an OS transistor as the driving transistor, a stable current can be fed through light-emitting devices even when the current-voltage characteristics of the light-emitting devices vary, for example. In other words, when the OS transistor is driven in the saturation region, the source-drain current hardly changes with an increase in the source-drain voltage. Hence, the luminance of the light-emitting device can be stable.

As described above, by using OS transistors as the driving transistors included in the pixel circuits, it is possible to inhibit black-level degradation, increase the luminance, increase the number of gray levels, and inhibit variations in characteristics of light-emitting devices, for example.

The transistors included in the circuit 164 and the transistors included in a display portion 107 may have the same structure or different structures. The plurality of transistors included in the circuit 164 may have the same structure or two or more kinds of structures. Similarly, the plurality of transistors included in the display portion 107 may have the same structure or two or more kinds of structures.

All the transistors included in the display portion 107 may be OS transistors or S1 transistors. Alternatively, some of the transistors included in the display portion 107 may be OS transistors and the others may be S1 transistors.

For example, when both an LTPS transistor and an OS transistor are used in the display portion 107, the display apparatus can have low power consumption and high driving capability. Note that a structure in which an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling current.

For example, one transistor included in the display portion 107 functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased.

Another transistor included in the display portion 107 functions as a switch for controlling selection or non-selection of a pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML structure. This structure can significantly reduce leakage current that would flow through a transistor and leakage current that would flow between adjacent light-emitting devices. Displaying images on the display apparatus having this structure can bring one or more of image crispness, image sharpness, high color saturation, and a high contrast ratio to the viewer. When leakage current that would flow through the transistor and lateral leakage current that would flow between light-emitting devices are extremely low, display with little leakage of light at the time of black display (black-level degradation), for example, can be achieved.

In particular, current flowing between adjacent light-emitting devices having the MML structure can be significantly reduced.

### [Transistor 209 and Transistor 210]

FIGS. 17B and 17C are cross-sectional views each illustrating another example of a cross-sectional structure of a transistor that can be used for the display apparatus 100H.

A transistor 209 and a transistor 210 each include the conductive layer 221, the insulating layer 211, the semiconductor layer 231, the conductive layer 222a, the conductive layer 222b, an insulating layer 225, the conductive layer 223, and the insulating layer 215. The semiconductor layer 231 includes a channel formation region 231i and a pair of low-resistance regions 231n. The insulating layer 211 is positioned between the conductive layer 221 and the channel formation region 231i. The conductive layer 221 functions as a gate, and the insulating layer 211 functions as a first gate insulating layer. The insulating layer 225 is positioned at least between the conductive layer 223 and the channel formation region 231i. The conductive layer 223 functions as a gate, and the insulating layer 225 functions as a second gate insulating layer. The conductive layer 222a is electrically connected to one of the pair of low-resistance regions 231n, and the conductive layer 222b is electrically connected to the other of the pair of low-resistance regions 231n. The insulating layer 215 covers the conductive layer 223. An insulating layer 218 covers the transistor.

### [Structure Example 1 of Insulating Layer 225]

In the transistor 209, the insulating layer 225 covers the top and side surfaces of the semiconductor layer 231 (see FIG. 17B). The insulating layer 225 and the insulating layer 215 have opening portions, through which the conductive layers 222a and 222b are electrically connected to the low-resistance regions 231n. One of the conductive layers 222a and 222b functions as a source, and the other functions as a drain.

### [Structure Example 2 of Insulating Layer 225]

In the transistor 210, the insulating layer 225 overlaps with the channel formation region 231i of the semiconductor layer 231 and does not overlap with the low-resistance regions 231n (see FIG. 17C). For example, the insulating layer 225 can be processed into a predetermined shape using the conductive layer 223 as a mask. The insulating layer 215 covers the insulating layer 225 and the conductive layer 223. The insulating layer 215 has opening portions, and the conductive layers 222a and 222b are electrically connected to the low-resistance regions 231n.

### [Connection Portion 204]

A connection portion 204 is provided for the substrate 14b. The connection portion 204 includes a conductive layer 166, which is electrically connected to the wiring 165. Note that the connection portion 204 does not overlap with the substrate 16b, and the conductive layer 166 is exposed. Note that the conductive layer 166 and the conductive layer 171 can be formed by processing one conductive film. The conductive layer 166 is electrically connected to the FPC 177 through a connection layer 242. As the connection layer 242, for example, an anisotropic conductive film (ACF) or an anisotropic conductive paste (ACP) can be used.

### <<Display Apparatus 100I>>

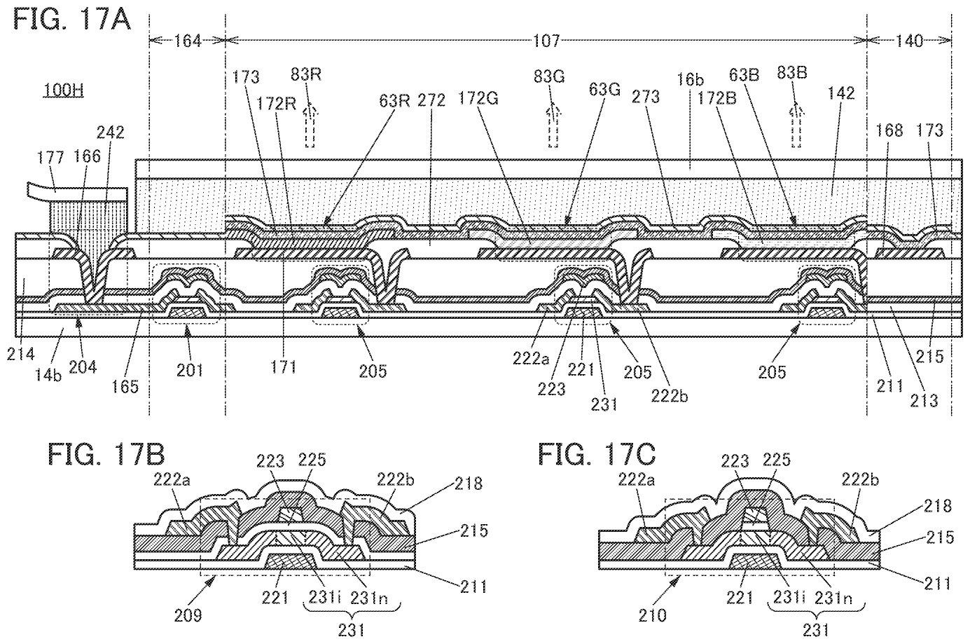

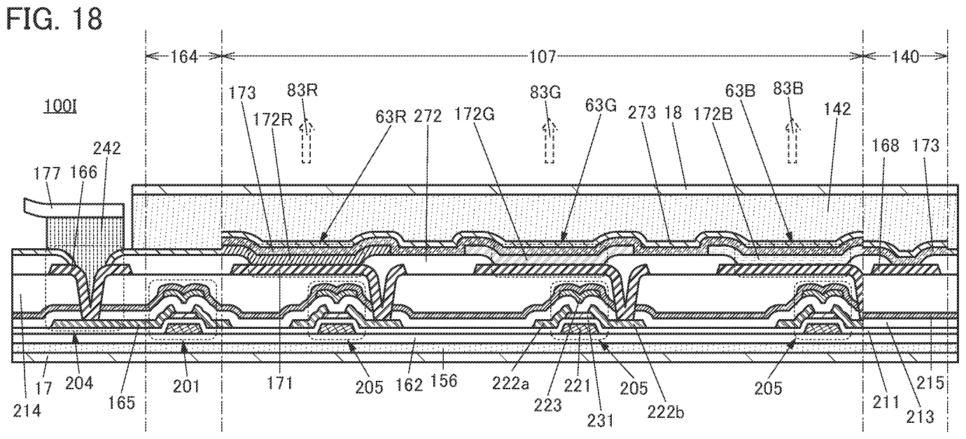

FIG. 18 is a cross-sectional view illustrating a structure of a display apparatus 100I. The display apparatus 100I is different from the display apparatus 100H in having flexibility. In other words, the display apparatus 100I is a flexible display. The display apparatus 100I includes a substrate 17 and a substrate 18 instead of the substrate 14b and the substrate 16b, respectively. The substrates 17 and 18 both have flexibility.

The display apparatus 100I includes a bonding layer 156 and an insulating layer 162. The insulating layer 162 and the substrate 17 are bonded to each other with the bonding layer 156. For example, the material that can be used for the bonding layer 122 can be used for the bonding layer 156. For example, the material that can be used for the insulating layer 211, the insulating layer 213, or the insulating layer 215 can be used for the insulating layer 162. Note that the transistors 201 and 205 are provided over the insulating layer 162.

For example, the insulating layer 162 is formed over a formation substrate, and the transistors, the light-emitting devices, and the like are formed over the insulating layer 162. Then, the bonding layer 142 is formed over the light-emitting devices, and the formation substrate and the substrate 18 are bonded to each other with the bonding layer 142. After that, the formation substrate is separated from the insulating layer 162 and the surface of the insulating layer 162 is exposed. Then, the bonding layer 156 is formed on the exposed surface of the insulating layer 162, and the insulating layer 162 and the substrate 17 are bonded to each other with the bonding layer 156. In this manner, the components formed over the formation substrate can be transferred onto the substrate 17, whereby the display apparatus 100I can be fabricated.

### <<Display Apparatus 100J>>

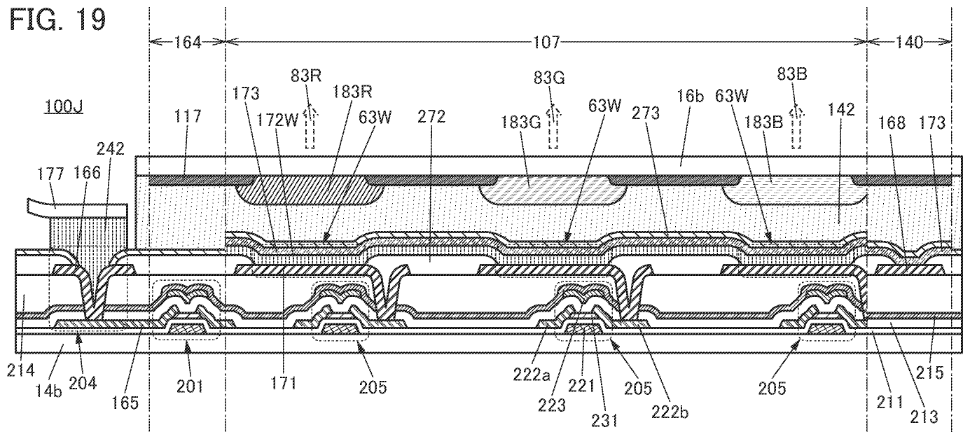

FIG. 19 is a cross-sectional view illustrating a structure of a display apparatus 100J. The display apparatus 100J is different from the display apparatus 100H in including light-emitting devices 63W, instead of the light-emitting devices 63R, 63G and 63B, and the coloring layers 183R, 183G, and 183B.

The display apparatus 100J includes the coloring layers 183R, 183G, and 183B between the substrate 16b and the substrate 14b. The coloring layer 183R overlaps with one light-emitting device 63W, the coloring layer 183G overlaps with another light-emitting device 63W, and the coloring layer 183B overlaps with another light-emitting device 63W.

The display apparatus 100J includes a light-blocking layer 117. For example, the light-blocking layer 117 is provided between the coloring layers 183R and 183G, between the coloring layers 183G and 183B, and between the coloring layers 183B and 183R. The light-blocking layer 117 includes a region overlapping with the connection portion 140 and a region overlapping with the circuit 164.

The light-emitting device 63W can emit white light, for example. The coloring layer 183R, the coloring layer 183G, and the coloring layer 183B can transmit red light, green light, and blue light, respectively, for example. In this manner, the display apparatus 100J can emit the red light 83R, the green light 83G, and the blue light 83B, for example, to perform full color display.

### <<Display Apparatus 100K>>

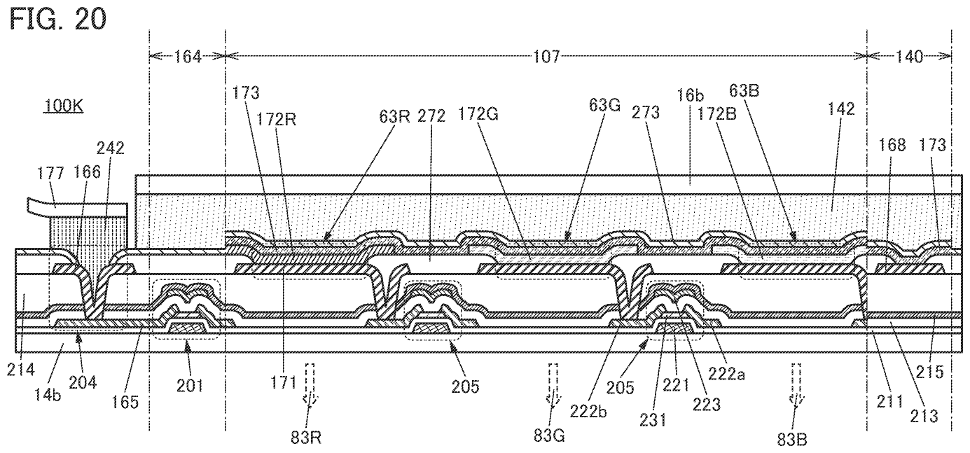

FIG. 20 is a cross-sectional view illustrating a structure of a display apparatus 100K. The display apparatus 100K is different from the display apparatus 100H in having a bottom-emission structure. The light-emitting devices emit the light 83R, the light 83G, and the light 83B to the substrate 14b side. A visible-light-transmitting material is used for the conductive layer 171. A visible-light-reflecting material is used for the conductive layer 173.

### <<Display Apparatus 100L>>

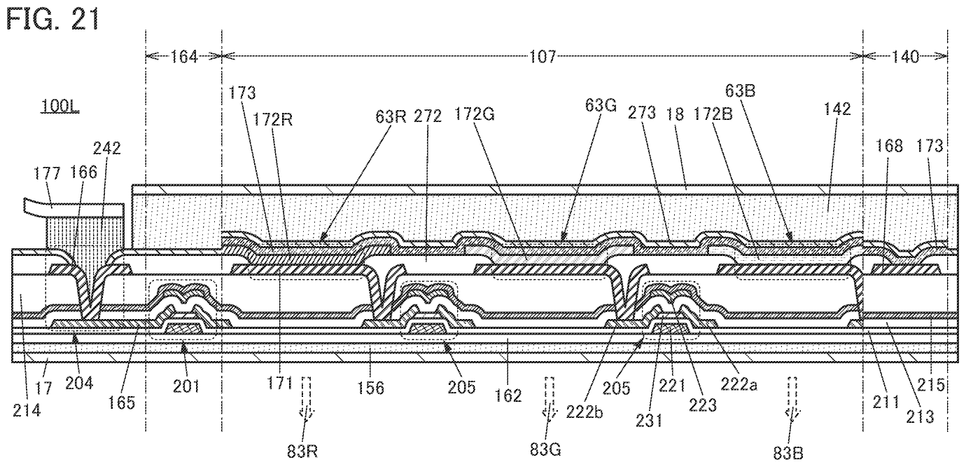

FIG. 21 is a cross-sectional view illustrating a structure of a display apparatus 100L. The display apparatus 100L is different from the display apparatus 100H in having flexibility and a bottom-emission structure. The display apparatus 100L includes the substrate 17 and the substrate 18 instead of the substrate 14b and the substrate 16b, respectively. The substrates 17 and 18 both have flexibility. The light-emitting devices emit the light 83R, the light 83G, and the light 83B to the substrate 17 side.

The conductive layers 221 and 223 may have a property of transmitting visible light and a property of reflecting visible light. When the conductive layers 221 and 223 have a property of transmitting visible light, the visible-light transmittance in the display portion 107 can be improved. Meanwhile, when the conductive layers 221 and 223 have a property of reflecting visible light, the amount of visible light entering the semiconductor layer 231 can be reduced. In addition, damage to the semiconductor layer 231 can be reduced. Accordingly, the reliability of the display apparatus 100K or the display apparatus 100L can be increased.

Even in a top-emission display apparatus such as the display apparatus 100H or the display apparatus 100I, at least one of the layers included in the transistor 205 may have a property of transmitting visible light. In that case, the conductive layer 171 also has a property of transmitting visible light. Accordingly, the visible-light transmittance in the display portion 107 can be improved.

### <<Display Apparatus 100M>>

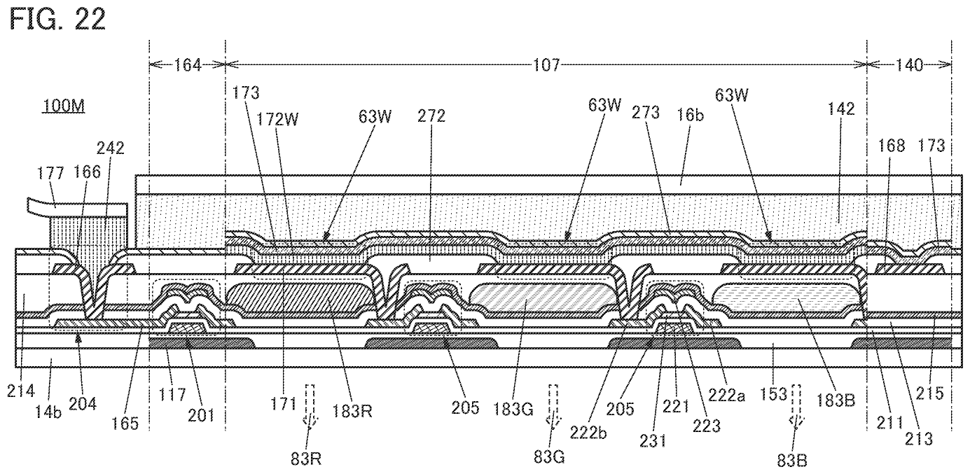

FIG. 22 is a cross-sectional view illustrating a structure of a display apparatus 100M. The display apparatus 100M is different from the display apparatus 100H in having a bottom-emission structure and including the light-emitting devices 63W, instead of the light-emitting devices 63R, 63G and 63B, and the coloring layers 183R, 183G, and 183B.

The display apparatus 100M includes the coloring layers 183R, 183G, and 183B. The display apparatus 100M includes the light-blocking layer 117.

### [Coloring Layer 183R, Coloring Layer 183G, and Coloring Layer 183B]

The coloring layers 183R, 183G, and 183B are positioned between the substrate 14b and the respective light-emitting devices 63W. For example, the coloring layers 183R, 183G, and 183B can be provided between the insulating layer 215 and the insulating layer 214.

### [Light-Blocking Layer 117]

The light-blocking layer 117 is provided over the substrate 14b and positioned between the substrate 14b and the transistor 205. An insulating layer 153 is positioned between the light-blocking layer 117 and the transistor 205. For example, the light-blocking layer 117 does not overlap with a light-emitting region of the light-emitting device 63W. For example, the light-blocking layer 117 overlaps with the connection portion 140 and the circuit 164.

The light-blocking layer 117 can also be provided in the display apparatus 100K or the display apparatus 100L. In that case, light emitted from the light-emitting devices 63R, 63G, and 63B can be inhibited from being reflected by the substrate 14b and being diffused inside the display apparatus 100K or the display apparatus 100L, for example. Thus, the display apparatus 100K and the display apparatus 100L can provide high display quality. Meanwhile, when the light-blocking layer 117 is not provided, the extraction efficiency of light emitted from the light-emitting devices 63R, 63G, and 63B can be increased.

At least part of this embodiment can be implemented in combination with any of the other embodiments described in this specification, as appropriate.

### Embodiment 9

In this embodiment, electronic devices of embodiments of the present invention will be described.

Electronic devices of this embodiment each include the display apparatus of one embodiment of the present invention in a display portion. The display apparatus of one embodiment of the present invention is highly reliable and can be easily increased in resolution and definition. Thus, the display apparatus of one embodiment of the present invention can be used for display portions of a variety of electronic devices.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display apparatus of one embodiment of the present invention can have high resolution, and thus can be suitably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With such a display apparatus having one or both of high definition and high resolution, the electronic device can have higher realistic sensation, sense of depth, and the like in personal use such as portable use or home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

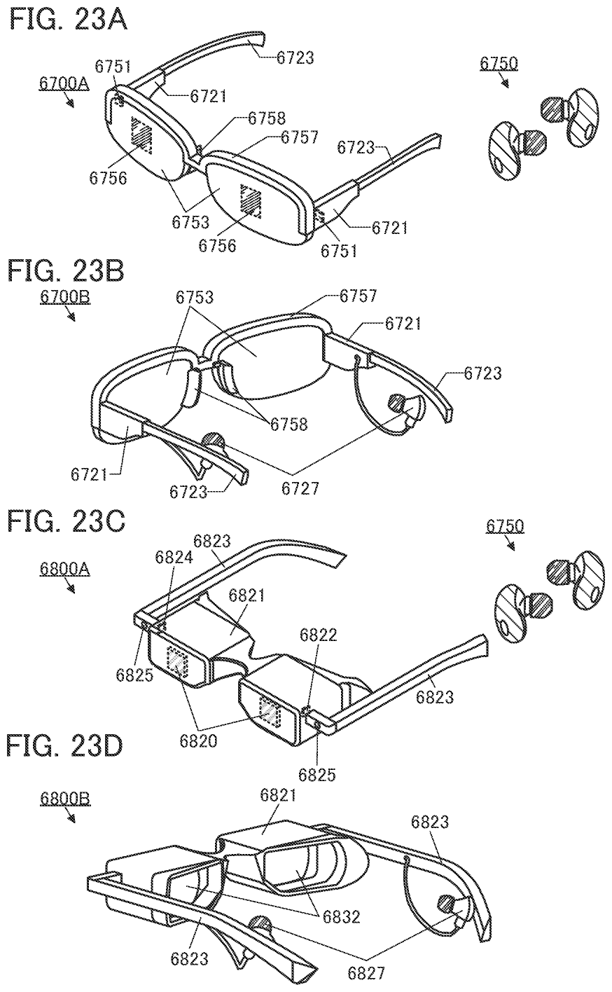

Examples of head-mounted wearable devices are described with reference to FIGS. 23A to 23D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 6700A illustrated in FIG. 23A and an electronic device 6700B illustrated in FIG. 23B each include a pair of display panels 6751, a pair of housings 6721, a communication portion (not illustrated), a pair of wearing portions 6723, a control portion (not illustrated), an image capturing portion (not illustrated), a pair of optical members 6753, a frame 6757, and a pair of nose pads 6758.

The display apparatus of one embodiment of the present invention can be used for the display panels 6751. Thus, a highly reliable electronic device can be obtained.

The electronic devices 6700A and 6700B can each project images displayed on the display panels 6751 onto display regions 6756 of the optical members 6753. Since the optical members 6753 have a light-transmitting property, the user can see images displayed on the display regions, which are superimposed on transmission images seen through the optical members 6753. Accordingly, the electronic devices 6700A and 6700B are capable of AR display.

In the electronic devices 6700A and 6700B, a camera capable of capturing images of the front side may be provided as the image capturing portion. Furthermore, when the electronic devices 6700A and 6700B are each provided with an acceleration sensor such as a gyroscope sensor, the orientation of the user's head can be sensed and an image corresponding to the orientation can be displayed on the display regions 6756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 6700A and 6700B are each provided with a battery so that they can be charged wirelessly and/or by wire.

A touch sensor module may be provided in the housing 6721. The touch sensor module has a function of detecting a touch on the outer surface of the housing 6721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 6721, the range of the operation can be increased.

Any of various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 6800A illustrated in FIG. 23C and an electronic device 6800B illustrated in FIG. 23D each include a pair of display portions 6820, a housing 6821, a communication portion 6822, a pair of wearing portions 6823, a control portion 6824, a pair of image capturing portions 6825, and a pair of lenses 6832.

The display apparatus of one embodiment of the present invention can be used in the display portions 6820. Thus, a highly reliable electronic device can be obtained.

The display portions 6820 are positioned inside the housing 6821 so as to be seen through the lenses 6832. When the pair of display portions 6820 display different images, three-dimensional display using parallax can be performed.

The electronic devices 6800A and 6800B can be regarded as electronic devices for VR. The user who wears the electronic device 6800A or the electronic device 6800B can see images displayed on the display portions 6820 through the lenses 6832.

The electronic devices 6800A and 6800B each preferably include a mechanism for adjusting the lateral positions of the lenses 6832 and the display portions 6820 so that the lenses 6832 and the display portions 6820 are positioned optimally in accordance with the positions of the user's eyes. Moreover, the electronic devices 6800A and 6800B each preferably include a mechanism for adjusting focus by changing the distance between the lenses 6832 and the display portions 6820.

The electronic device 6800A or the electronic device 6800B can be mounted on the user's head with the wearing portions 6823. FIG. 23C, for instance, illustrates an example in which the wearing portion 6823 has a shape like a temple (also referred to as a joint or the like) of glasses; however, one embodiment of the present invention is not limited thereto. The wearing portion 6823 may have any shape with which the user can wear the electronic device, such as a shape of a helmet or a band, for example.

The image capturing portion 6825 has a function of obtaining information on the external environment. Data obtained by the image capturing portion 6825 can be output to the display portion 6820. An image sensor can be used for the image capturing portion 6825. Moreover, a plurality of cameras may be provided so as to support a plurality of fields of view, such as a telescope field of view and a wide field of view.

Although an example in which the image capturing portions 6825 are provided is illustrated here, a range sensor (also referred to as a sensing portion) capable of measuring a distance between the user and an object just needs to be provided. In other words, the image capturing portion 6825 is one embodiment of the sensing portion. As the sensing portion, an image sensor or a range image sensor such as a light detection and ranging (LiDAR) sensor can be used, for example. By using images obtained by the camera and images obtained by the range image sensor, more pieces of information can be obtained and a gesture operation with higher accuracy is possible.

The electronic device 6800A may include a vibration mechanism that functions as bone-conduction earphones. For example, at least one of the display portion 6820, the housing 6821, and the wearing portion 6823 can include the vibration mechanism. Thus, without additionally requiring an audio device such as headphones, earphones, or a speaker, the user can enjoy a video and sound only by wearing the electronic device 6800A.

The electronic devices 6800A and 6800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 6750. The earphones 6750 include a communication portion (not illustrated) and have a wireless communication function. The earphones 6750 can receive information (e.g., audio data) from the electronic device with the wireless communication function. For example, the electronic device 6700A illustrated in FIG. 23A has a function of transmitting information to the earphones 6750 with the wireless communication function. For another example, the electronic device 6800A illustrated in FIG. 23C has a function of transmitting information to the earphones 6750 with the wireless communication function.

The electronic device may include an earphone portion. The electronic device 6700B illustrated in FIG. 23B includes earphone portions 6727. For example, the earphone portion 6727 can be connected to the control portion by wire. Part of a wiring that connects the earphone portion 6727 and the control portion may be positioned inside the housing 6721 or the wearing portion 6723.

Similarly, the electronic device 6800B illustrated in FIG. 23D includes earphone portions 6827. For example, the earphone portion 6827 can be connected to the control portion 6824 by wire. Part of a wiring that connects the earphone portion 6827 and the control portion 6824 may be positioned inside the housing 6821 or the wearing portion 6823. Alternatively, the earphone portions 6827 and the wearing portions 6823 may include magnets. This is preferred because the earphone portions 6827 can be fixed to the wearing portions 6823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 6700A and 6700B) and the goggles-type device (e.g., the electronic devices 6800A and 6800B) are preferable as the electronic device of one embodiment of the present invention.

The electronic device of one embodiment of the present invention can transmit information to earphones by wire or wirelessly.

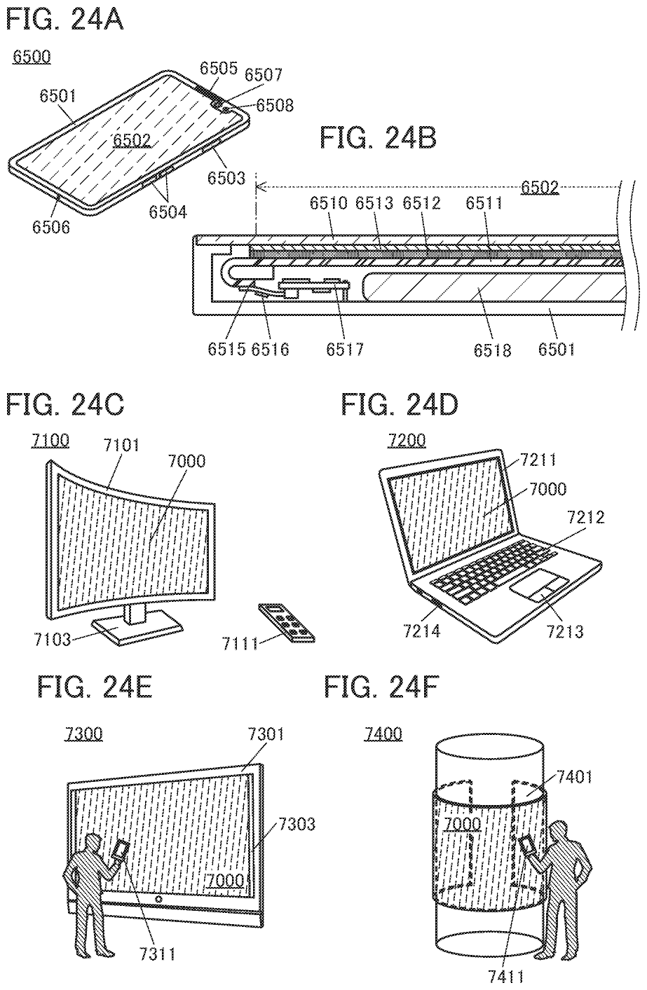

An electronic device 6500 illustrated in FIG. 24A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, a highly reliable electronic device can be obtained.

FIG. 24B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

The flexible display of one embodiment of the present invention can be used as the display panel 6511. Thus, the electronic device can be extremely lightweight. Since the display panel 6511 is extremely thin, the battery 6518 with high capacity can be mounted without an increase in the thickness of the electronic device. Moreover, part of the display panel 6511 is folded back such that a connection portion with the FPC 6515 is provided on the back side of a pixel portion, whereby an electronic device with a narrow bezel can be achieved.

FIG. 24C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000. Thus, a highly reliable electronic device can be obtained.

The television device 7100 illustrated in FIG. 24C can be operated with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel of the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 24D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, a highly reliable electronic device can be obtained.

FIGS. 24E and 24F illustrate examples of digital signage.

Digital signage 7300 illustrated in FIG. 24E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 24F illustrates digital signage 7400 attached to a cylindrical pillar 7401. The digital signage 7400 includes the display portion 7000 provided along a curved surface of the pillar 7401.

In FIGS. 24E and 24F, the display apparatus of one embodiment of the present invention can be used in the display portion 7000. Thus, a highly reliable electronic device can be obtained.

A larger area of the display portion 7000 can increase the amount of information that can be provided at a time. The larger display portion 7000 attracts more attention, so that the effectiveness of the advertisement can be increased, for example.

The touch panel is preferably used in the display portion 7000, in which case in addition to display of still or moving images on the display portion 7000, intuitive operation by a user is possible. Moreover, for an application for providing information such as route information or traffic information, usability can be enhanced by intuitive operation.

As illustrated in FIGS. 24E and 24F, it is preferable that the digital signage 7300 or the digital signage 7400 be capable of working with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

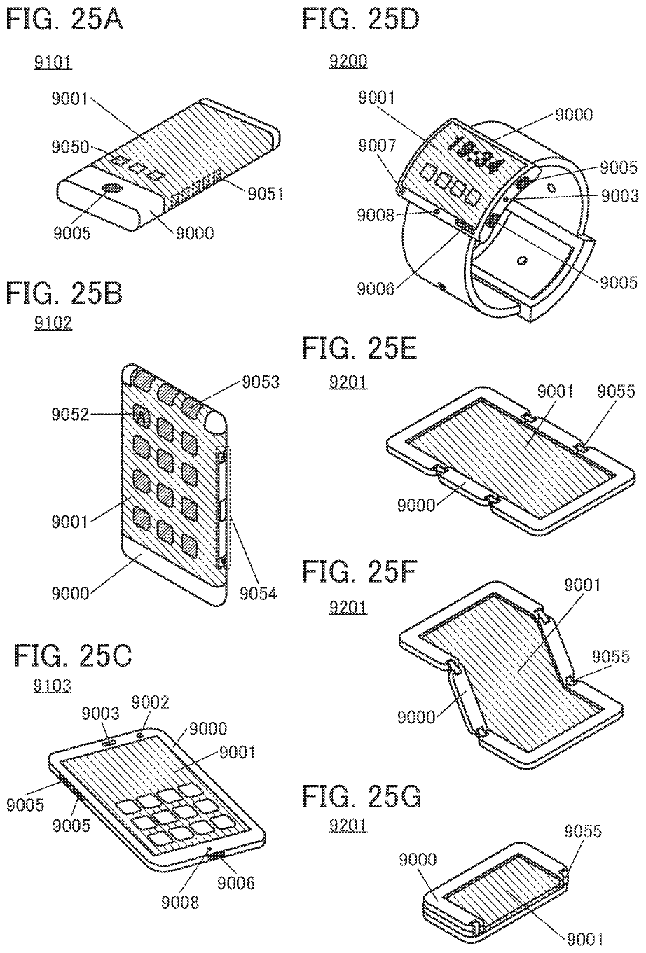

Electronic devices illustrated in FIGS. 25A to 25G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays), a microphone 9008, and the like.

The electronic devices illustrated in FIGS. 25A to 25G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of taking a still image or a moving image, a function of storing the taken image in a storage medium (an external storage medium or a storage medium incorporated in the camera), a function of displaying the taken image on the display portion, and the like.

The electronic devices in FIGS. 25A to 25G will be described in detail below.

FIG. 25A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 25A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050, for example, may be displayed at the position where the information 9051 is displayed.

FIG. 25B is a perspective view of a portable information terminal 9102. The portable information terminal 9102 has a function of displaying information on three or more surfaces of the display portion 9001. Here, an example is illustrated in which information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of user's clothes. Thus, the user can see the display without taking out the portable information terminal 9102 from the pocket and decide whether to answer the call, for example.

FIG. 25C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 25D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 25E to 25G are perspective views of a foldable portable information terminal 9201. FIG. 25E is a perspective view illustrating the portable information terminal 9201 that is opened. FIG. 25G is a perspective view illustrating the portable information terminal 9201 that is folded. FIG. 25F is a perspective view illustrating the portable information terminal 9201 that is shifted from one of the states in FIGS. 25E and 25G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate. In this specification, in the case where a plurality of structure examples are described in one embodiment, the structure examples can be combined as appropriate.

### Example 1

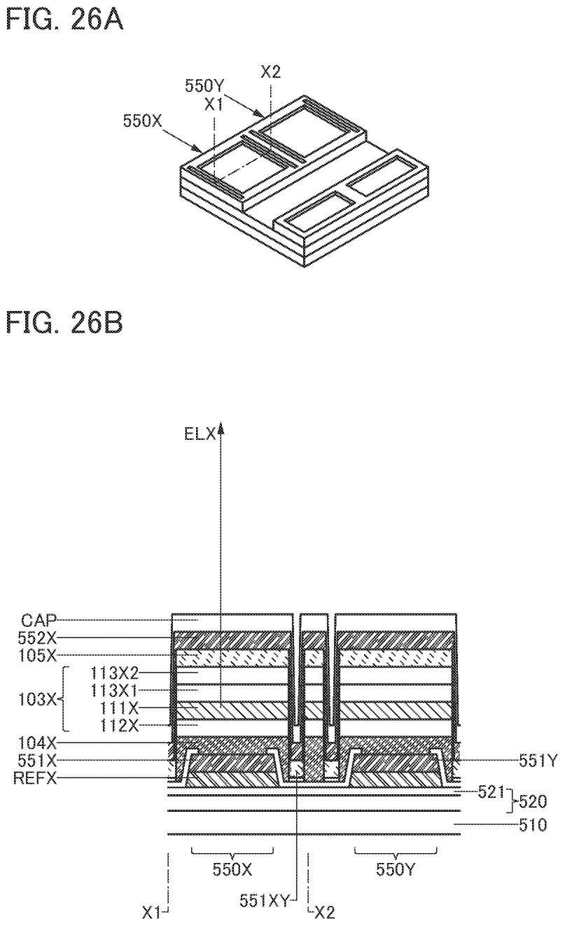

In this example, a light-emitting device 1 of one embodiment of the present invention will be described with reference to FIGS. 26A and 26B, FIG. 27, FIG. 28, FIG. 29, FIG. 30, and FIG. 31.

FIG. 26A is an external view of the light-emitting device 550X placed over a workpiece, and FIG. 26B is a cross-sectional view illustrating a cross-sectional structure of the light-emitting device 550X taken along the cutting line X1-X2 in FIG. 26A.

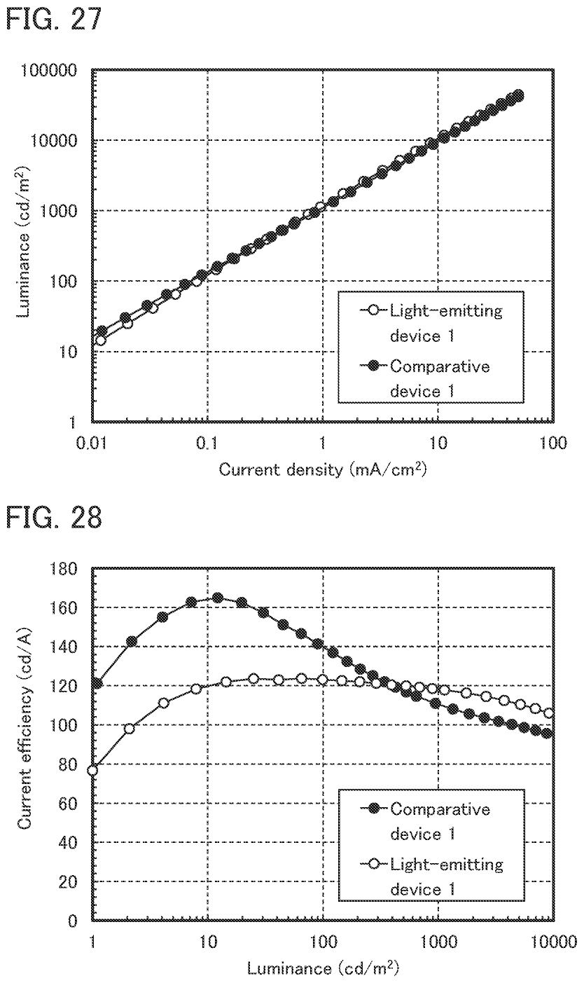

FIG. 27 shows the current density-luminance characteristics of the light-emitting device 1.

FIG. 28 shows the luminance-current efficiency characteristics of the light-emitting device 1.

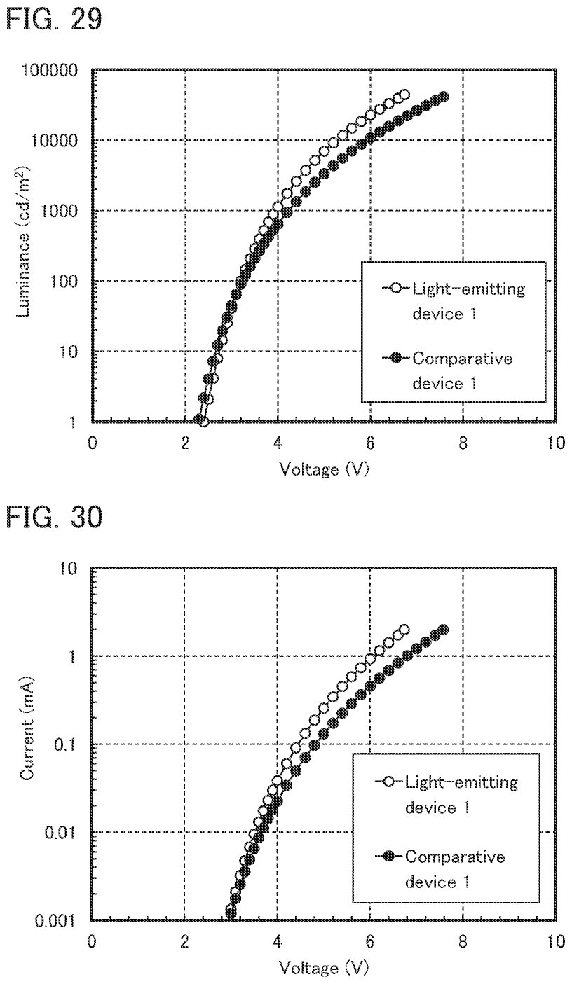

FIG. 29 shows the voltage-luminance characteristics of the light-emitting device 1.

FIG. 30 shows the voltage-current characteristics of the light-emitting device 1.

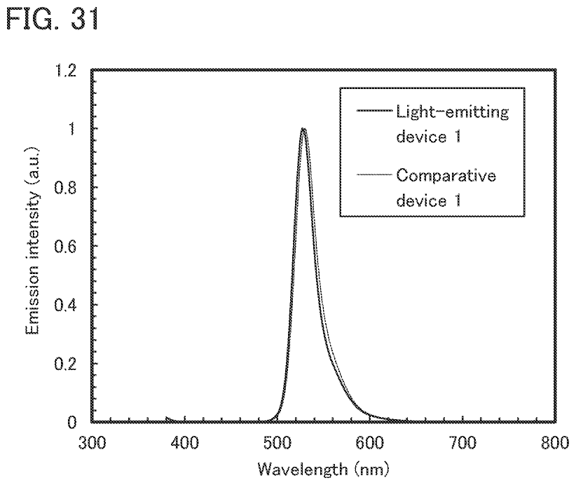

FIG. 31 shows an emission spectrum of the light-emitting device 1 emitting light at a luminance of 1000 cd/m².

### <Light-Emitting Device 1>

The fabricated light-emitting device 1, which is described in this example, has a structure similar to that of the light-emitting device 550X (see FIG. 26B).

### <<Structure of Light-Emitting Device 1>>

Table 3 shows the structure of the light-emitting device 1. Structural formulae of materials used in the light-emitting device described in this example are shown below. Note that in the tables in this example, subscript and superscript characters are written in ordinary size for convenience. For example, a subscript character in an abbreviation and a superscript character in a unit are written in ordinary size in the tables. The corresponding description in the specification gives an accurate reading of such notations in the tables.

TABLE 3

| | Reference | | Composition | Thickness/ |
|---|---|---|---|---|
| Component | numeral | Material | ratio | nm |
| Layer | CAP | DBT3P-II | | 70 |
| Electrode | 552X | Ag:Mg | 1:0.1 | 15 |
| Layer | 105X | 11mDBtBPPnfpr:2′,7′tBu-2hppSF | 0.5:0.5 | 5 |
| Layer | 113X2 | 11mDBtBPPnfpr | | 5 |
| Layer | 113X1 | 2mPCCzPDBq | | 15 |
| Layer | 111X | 8mpTP- | 0.5:0.5:0.1 | 40 |
| | | 4mDBtPBfpm:βNCCP:Ir(5mppy- | | |
| | | d3)2(mbfpypy-d3) | | |
| Layer | 112X | PCBBiF | | 105 |
| Layer | 104X | PCBBiF:OCHD-003 | 1:0.03 | 10 |
| Electrode | 551X | ITSO | | 50 |
| Reflective film | REFX | APC | | 100 |

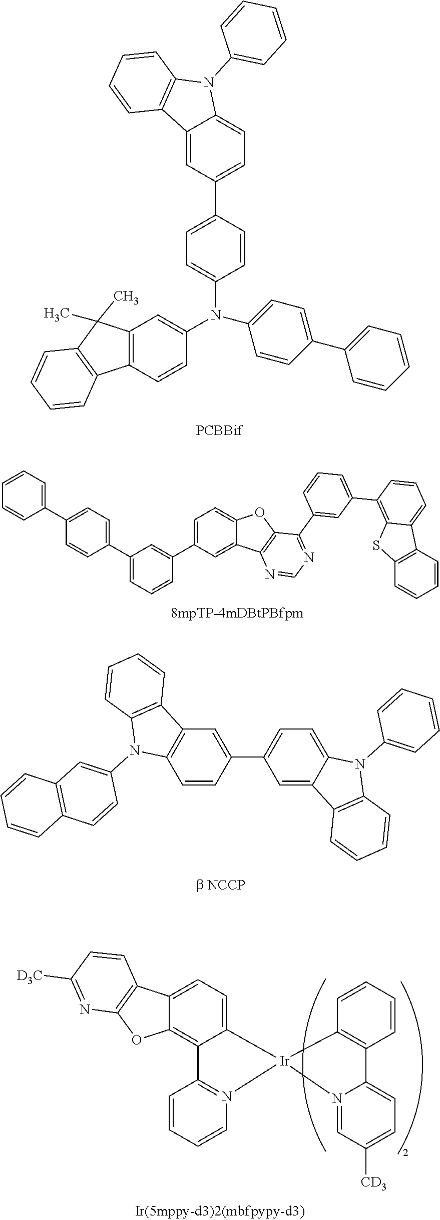

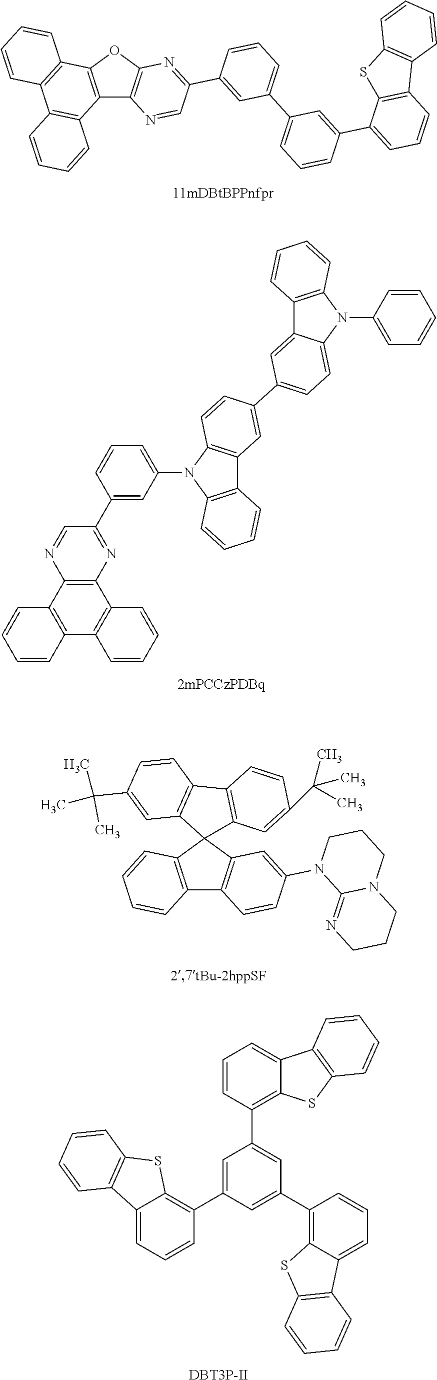 [SMILES: c1cc(-c2cccc(-c3cccc4c3sc3ccccc34)c2)cc(-c2cnc3c(n2)oc2c4ccccc4c4ccccc4c32)c1 ; c1ccc(-n2c3ccccc3c3cc(-c4ccc5c(c4)c4ccccc4n5-c4cccc(-c5cnc6c7ccccc7c7ccccc7c6n5)c4)ccc32)cc1 ; CC(C)(C)c1ccc2c(c1)C1(c3ccccc3-c3ccc(N4CCCN5CCCN=C54)cc31)c1cc(C(C)(C)C)ccc1-2 ; c1ccc2c(c1)sc1c(-c3cc(-c4cccc5c4sc4ccccc45)cc(-c4cccc5c4sc4ccccc45)c3)cccc12 ; "DBT3P-II"]

In this example, the light-emitting device was fabricated using an alloy containing silver (Ag), palladium (Pd), and copper (Cu) (abbreviation: APC), indium oxide-tin oxide containing silicon or silicon oxide (abbreviation: ITSO), N-(biphenyl-4-yl)-N-[4-(9-phenyl-9H-carbazol-3-yl)phenyl]-9,9-dimethyl-9H-fluoren-2-amine (abbreviation: PCBBiF), an electron-accepting material (abbreviation: OCHD-003), 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-9H,9′H-3,3′-bicarbazole (abbreviation: PNCCP), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)), 2-{3-[3-(N-phenyl-9H-carbazol-3-yl)-9H-carbazol-9-yl]phenyl}dibenzo[f,h]quinoxaline (abbreviation: 2mPCCzPDBq), 11-[(3′-dibenzothiophen-4-yl)biphenyl-3-yl]phenanthro[9′,10′:4,5]furo[2,3-b]pyrazine (abbreviation: 11mDBtBPPnfpr), 1-(2′,7′-di-tert-butyl-9,9′-spirobi[9H-fluoren]-2-yl)-1,3,4,6,7,8-hexahydro-2H-pyrimido[1,2-a]pyrimidine (abbreviation: 2′,7′tBu-2hppSF), silver (Ag), magnesium (Mg), and 4,4′,4″-(benzene-1,3,5-triyl)tri(dibenzothiophene) (abbreviation: DBT3P-II).

### <<Method for Fabricating Light-Emitting Device 1>>

The light-emitting device 1 described in this example was fabricated using a method including the following steps.

### [Step 1]

In Step 1, a reflective film REFX was formed. Specifically, the reflective film REFX was formed by a sputtering method using APC as a target. The reflective film REFX contains APC and has a thickness of 100 nm.

### [Step 2]

In Step 2, the electrode 551X was formed over the reflective film REFX. Specifically, the electrode 551X was formed by a sputtering method using ITSO as a target. The electrode 551X contains ITSO and has a thickness of 50 nm.

Next, a workpiece provided with the electrode was washed with water and then transferred into a vacuum evaporation apparatus. After that, the pressure in the vacuum evaporation apparatus was reduced to approximately 10′ Pa, and vacuum baking was performed at 170° C. for 60 minutes in a heating chamber of the vacuum evaporation apparatus. Then, the workpiece was cooled down for approximately 30 minutes.

### [Step 3]

In Step 3, the layer 104X was formed over the electrode 551X. Specifically, materials of the layer 104X were co-deposited by a resistance-heating method. The layer 104X contains PCBBiF and OCHD-003 at a weight ratio of 1:0.03, has a thickness of 10 nm, and has an area of 4 mm² (2 mm×2 mm). Note that OCHD-003 contains fluorine, and has a molecular weight of 672.

### [Step 4]

In Step 4, the layer 112X was formed over the layer 104X. Specifically, a material of the layer 112X was deposited by a resistance-heating method. The layer 112X contains PCBBiF and has a thickness of 105 nm.

### [Step 5]

In Step 5, the layer 111X was formed over the layer 112X. Specifically, materials of the layer 111X were co-deposited by a resistance-heating method. The layer 111X contains 8mpTP-4mDBtPBfpm, PNCCP, and Ir(5mppy-d₃)₂(mbfpypy-d₃) at a weight ratio of 0.5:0.5:0.1 and has a thickness of 40 nm.

### [Step 6]

In Step 6, a layer 113X1 was formed over the layer 111X. Specifically, a material of the layer 113X1 was deposited by a resistance-heating method. The layer 113X1 contains 2mPCCzPDBq and has a thickness of 15 nm.

### [Step 7]

In Step 7, the layer 113X2 was formed over the layer 113X1. Specifically, a material of the layer 113X2 was deposited by a resistance-heating method. The layer 113X2 contains 11mDBtBPPnfpr and has a thickness of 5 nm.

### [Step 8-1]

After the workpiece was taken out from the vacuum evaporation apparatus and exposed to the atmosphere, a sacrificial layer SCR1 was formed over the layer 113X2 in Step 8-1. Specifically, the sacrificial layer SCR1 was formed by an ALD method using trimethylaluminum (abbreviation: TMA) as a precursor and water vapor as an oxidizer.

The sacrificial layer SCR1 contains aluminum oxide and has a thickness of 30 nm.

### [Step 8-2]

In Step 8-2, a sacrificial layer SCR2 was formed over the sacrificial layer SCR1. Specifically, the sacrificial layer SCR2 was formed by a sputtering method using molybdenum (Mo) as a target.

The sacrificial layer SCR2 contains Mo and has a thickness of 50 nm.

### [Step 8-3]

In Step 8-3, a resist was formed over the sacrificial layer SCR2 using a photoresist, and the sacrificial layer SCR2, the sacrificial layer SCR1, the layer 113X2, the layer 113X1, the layer 111X, the layer 112X, and the layer 104X were processed into predetermined shapes by a lithography method.

Specifically, the sacrificial layer SCR2 was etched using an etching gas containing carbon tetrafluoride (CF₄), oxygen (O₂), and helium (He) at a flow rate ratio of 100:67:333 and then using an etching gas containing oxygen, followed by removal of the resist using a chemical solution. Next, the sacrificial layer SCR1 was processed using the sacrificial layer SCR2 as a mask and an etching gas containing trifluoroform (CHF₃) and helium (He) at a flow rate ratio of 1:49. After that, the etching conditions were changed, and a stacked-layer film including the layers from the layer 104X to the layer 113X2 was processed into a predetermined shape. Specifically, the processing was performed using an etching gas containing oxygen (02).

The predetermined shape was made by forming a slit in a region of the stacked-layer film that did not overlap with the electrode 551X. Specifically, a slit having a width of 3 m was formed in a position that is 3.5 m apart from the end portion of the electrode 551X and in a region overlapping with a gap 551XY between the electrode 551X and an electrode 551Y (see FIG. 26B).

### [Step 8-4]

In Step 8-4, the sacrificial layer SCR2 was removed using an etching gas containing CF₄, O₂, and He at a flow rate ratio of 100:67:333 and then the sacrificial layer SCR1 was removed using a chemical solution, so that the layer 113X2 was exposed in the workpiece.

Next, the workpiece was transferred into a vacuum evaporation apparatus in which the pressure was reduced to approximately 1×10⁻⁴ Pa, and vacuum baking was performed at 110° C. for one hour in a heating chamber of the vacuum evaporation apparatus. Then, the workpiece was cooled down for approximately 30 minutes.

### [Step 9]

In Step 9, the layer 105X was formed over the layer 113X2. Specifically, materials of the layer 105X were co-deposited by a resistance-heating method. The layer 105X contains 11mDBtBPPnfpr and 2′,7′tBu-2hppSF at a weight ratio of 0.5:0.5 and has a thickness of 5 nm. Note that 2′,7′tBu-2hppSF has an acid dissociation constant pKₐ of 14.18 and has a 1,3,4,6,7,8-hexahydro-2H-pyrimido[1,2-a]pyrimidine group. Furthermore, 11mDBtBPPnfpr is an organic compound having an acid dissociation constant pKₐ of −1.85 and having neither a pyridine ring nor a phenanthroline ring.

### [Step 10]

In Step 10, the electrode 552X was formed over the layer 105X. Specifically, materials of the electrode 552X were co-deposited by a resistance-heating method. The electrode 552X contains Ag and Mg at a volume ratio of 1:0.1 and has a thickness of 15 nm.

### [Step 11]

In Step 11, the layer CAP was formed over the electrode 552X. Specifically, a material of the layer CAP was deposited by a resistance-heating method. The layer CAP contains DBT3P-II and has a thickness of 70 nm.

### <<Operation Characteristics of Light-Emitting Device 1>>

When supplied with electric power, the light-emitting device 1 emitted the light ELX (see FIG. 26B). The operation characteristics of the light-emitting device 1 were measured at room temperature (see FIG. 27 to FIG. 31). Note that the luminance, CIE chromaticity, and emission spectrum were measured with a spectroradiometer (SR-UL1R produced by TOPCON TECHNOHOUSE CORPORATION).

Table 4 shows the main initial characteristics of the fabricated light-emitting device emitting light at a luminance of approximately 1000 cd/m². Table 4 also shows the characteristics of a comparative device having a structure described later.

TABLE 4

| | | | Current | | | Current |
|---|---|---|---|---|---|---|
| | Voltage | Current | density | Chromaticity | Chromaticity | efficiency |
| | (V) | (mA) | (mA/cm2) | x | y | (cd/A) |
| Light-emitting device 1 | 3.9 | 0.03 | 0.7 | 0.23 | 0.73 | 118.5 |
| Comparative device 1 | 4.2 | 0.03 | 0.9 | 0.25 | 0.72 | 111.0 |

The light-emitting device 1 was found to exhibit excellent characteristics. For example, the light-emitting device 1 exhibited stably high current efficiency in a wide luminance region from 10 cd/m² to 10000 cd/m² or higher. By contrast, the comparative device 1 exhibited unstable characteristics in which the current efficiency largely changed depending on the luminance. The light-emitting device 1 exhibited high current efficiency comparable to that of a light-emitting device fabricated consistently in a vacuum and not subjected to Steps 8-1 to 8-4. The light-emitting device 1 operated at a lower voltage than the comparative device 1. Thus, it was found that the layer 105X included in the light-emitting device of one embodiment of the present invention exhibited an excellent electron-injection property.

### <ESR Measurement>

The spin density of a film containing the materials used for the layer 105X of the light-emitting device 1 was measured by ESR spectroscopy.

Specifically, the spin density of the materials, which were used for the layer 105X, in a film state was measured. A measurement sample was formed by co-depositing 11mDBtBPPnfpr and 2′,7′tBu-2hppSF at a weight ratio of 1:1 to a thickness of 50 nm over a quartz substrate.

Note that the measurement of an ESR spectrum of the measurement sample using ESR spectroscopy was performed at room temperature with an ESR spectrometer E500 (produced by Bruker Corporation). The measurement was performed at room temperature under the conditions where the resonance frequency was 9.56 GHz, the output power was 1 mW, the modulated magnetic field was 50 mT, the modulation width was 0.5 mT, the time constant was 0.04 s, and the sweep time was 1 min. As a result, it was found that no signal was observed at a g-factor of around 2.00 and the spin density was lower than 8×10¹⁶ spins/cm³, which is the lower detection limit. In the case where the spin density is lower than or equal to 1×10¹⁷ spins/cm³, it can be said that electrons are not transferred between the materials contained in the film. Therefore, it can be said that 2′,7′tBu-2hppSF does not have an electron-donating property with respect to 11mDBtBPPnfpr.

The spin density of the materials, which were used for the layer 104X, in a film state was measured. A measurement sample was formed by co-depositing PCBBiF and OCHD-003 at a weight ratio of 1:0.1 to a thickness of 100 nm over a quartz substrate.

Note that the measurement of an ESR spectrum of the measurement sample using ESR spectroscopy was performed at room temperature with an ESR spectrometer JES FA300 (produced by JEOL Ltd.). The measurement was performed at room temperature under the conditions where the resonance frequency was 9.18 GHz, the output power was 1 mW, the modulated magnetic field was 50 mT, the modulation width was 0.5 mT, the time constant was 0.03 s, and the sweep time was 1 min. As a result, it was found that a signal was observed at a g-factor of around 2.00 and the spin density was 5×10¹⁹ spins/cm³. This suggests that OCHD-003 has an electron-accepting property with respect to PCBBiF.

### <Comparative Device 1>

The fabricated comparative device 1 has a structure similar to that of the light-emitting device 550X (see FIG. 26B).

### <<Structure of Comparative Device 1>>

The comparative device 1 is different from the light-emitting device 1 in the structure of the layer 105X. Specifically, the comparative device 1 is different from the light-emitting device 1 in that the layer 105X contains lithium fluoride (LiF) and ytterbium (Yb) instead of 11mDBtBPPnfpr and 2′,7′tBu-2hppSF.

### <<Method for Fabricating Comparative Device 1>>

The comparative device 1 was fabricated by a method including the following step. The method for fabricating the comparative device 1 is different from that for fabricating the light-emitting device 1 in that LiF and Yb are used instead of 11mDBtBPPnfpr and 2′,7′tBu-2hppSF in Step 9. Different portions are described in detail here, and the above description is referred to for portions where a method similar to the above was employed.

### [Step 9]

In Step 9, the layer 105X was formed over the layer 113X2. Specifically, materials of the layer 105X were co-deposited by a resistance-heating method. The layer 105X contains lithium fluoride (abbreviation: LiF) and ytterbium (abbreviation: Yb) at a volume ratio of 2:1 and has a thickness of 1.5 nm.

### <<Operation Characteristics of Comparative Device 1>>

When supplied with electric power, the comparative device 1 emitted the light ELX (see FIG. 26B). The operation characteristics of the comparative device 1 were measured at room temperature (see FIG. 27 to FIG. 31). Note that the luminance, CIE chromaticity, and emission spectrum were measured with a spectroradiometer (SR-UL1R produced by TOPCON TECHNOHOUSE CORPORATION).

### Example 2

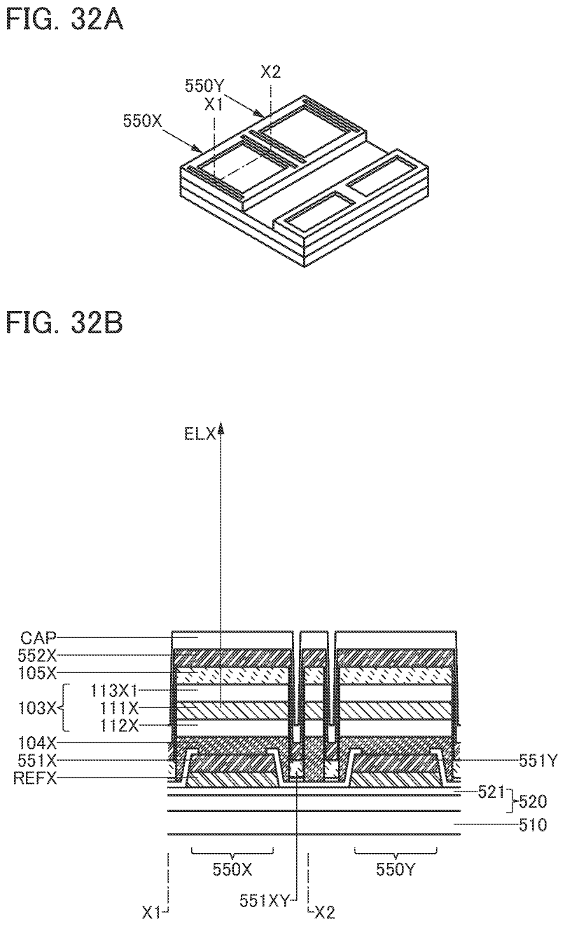

In this example, a light-emitting device 2 of one embodiment of the present invention will be described with reference to FIGS. 32A and 32B, FIG. 33, FIG. 34, FIG. 35, FIG. 36, and FIG. 37.

FIG. 32A is an external view of the light-emitting device 550X placed over a workpiece, and FIG. 32B is a cross-sectional view illustrating a cross-sectional structure of the light-emitting device 550X taken along the cutting line X1-X2 in FIG. 32A.

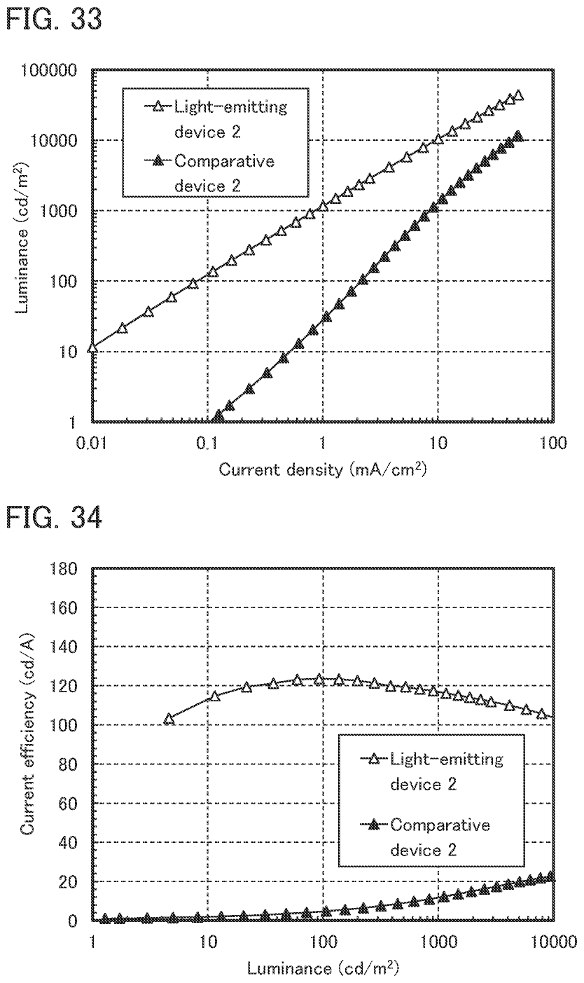

FIG. 33 shows the current density-luminance characteristics of the light-emitting device 2.

FIG. 34 shows the luminance-current efficiency characteristics of the light-emitting device 2.

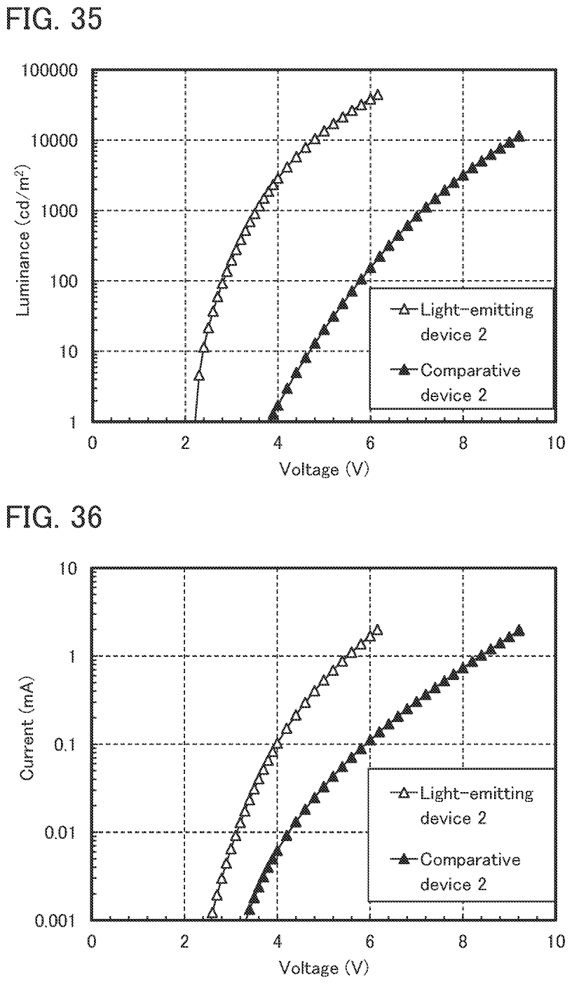

FIG. 35 shows the voltage-luminance characteristics of the light-emitting device 2.

FIG. 36 shows the voltage-current characteristics of the light-emitting device 2.

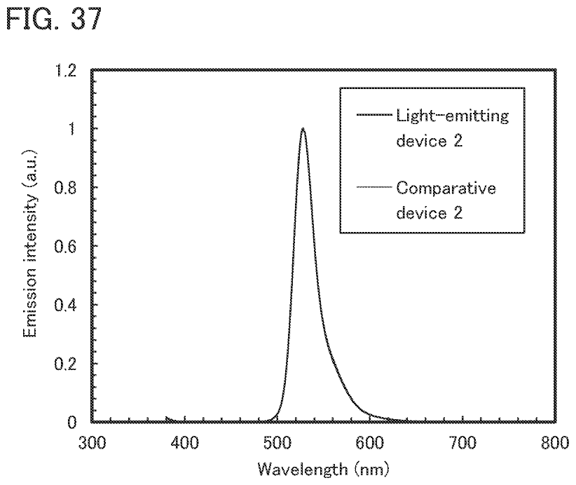

FIG. 37 shows an emission spectrum of the light-emitting device 2 emitting light at a luminance of 1000 cd/m².

### <Light-Emitting Device 2>

The fabricated light-emitting device 2, which is described in this example, has a structure similar to that of the light-emitting device 550X (see FIG. 32B).

### <<Structure of Light-Emitting Device 2>>

Table 5 shows the structure of the light-emitting device 2. Note that in the tables in this example, subscript and superscript characters are written in ordinary size for convenience. For example, a subscript character in an abbreviation and a superscript character in a unit are written in ordinary size in the tables. The corresponding description in the specification gives an accurate reading of such notations in the tables. Note that the light-emitting device 2 is different from the light-emitting device 1 in not including the layer 113X2.

TABLE 5

| | Reference | | Composition | Thickness/ |
|---|---|---|---|---|
| Component | numeral | Material | ratio | nm |
| Layer | CAP | DBT3P-II | | 70 |
| Electrode | 552X | Ag:Mg | 1:0.1 | 15 |
| Layer | 105X | 11mDBtBPPnfpr:2′,7′tBu-2hppSF | 0.5:0.5 | 5 |
| Layer | 113X1 | 2mPCCzPDBq | | 20 |
| Layer | 111X | 8mpTP- | 0.5:0.5:0.1 | 40 |
| | | 4mDBtPBfpm:βNCCP:Ir(5mppy- | | |
| | | d3)2(mbfpypy-d3) | | |
| Layer | 112X | PCBBIF | | 105 |
| Layer | 104X | PCBBIF:OCHD-003 | 1:0.03 | 10 |
| Electrode | 551X | ITSO | | 50 |
| Reflective film | REFX | APC | | 100 |

### <<Method for Fabricating Light-Emitting Device 2>>

The light-emitting device 2 described in this example was fabricated by a method including the following steps. Note that the method for fabricating the light-emitting device 2 is different from that for fabricating the light-emitting device 1 in that the layer 113X1 having a thickness of 20 nm is formed instead of the layer 113X1 having a thickness of 15 nm in Step 6; the layer 105X is formed instead of the layer 113X2 over the layer 113X1 in Step 7; the layer 105X is processed into a predetermined shape in addition to the stacked-layer film including the layers from the layer 104X to the layer 113X1 in Steps 8-1 to 8-4; and Step 9 is omitted and the process goes to Step 10 successively after Step 8-4. Different portions are described in detail here, and the above description is referred to for portions where a method similar to the above was employed.

### [Step 6]

In Step 6, the layer 113X1 was formed over the layer 111X. Specifically, a material of the layer 113X1 was deposited by a resistance-heating method. The layer 113X1 contains 2mPCCzPDBq and has a thickness of 20 nm.

### [Step 7]

In Step 7, the layer 105X was formed over the layer 113X1. Specifically, materials of the layer 105X were co-deposited by a resistance-heating method. The layer 105X contains 11mDBtBPPnfpr and 2′,7′tBu-2hppSF at a weight ratio of 0.5:0.5 and has a thickness of 5 nm. Note that 2′,7′tBu-2hppSF has an acid dissociation constant pKₐ of 14.18 and has a 1,3,4,6,7,8-hexahydro-2H-pyrimido[1,2-a]pyrimidine group. Furthermore, 11mDBtBPPnfpr is an organic compound having an acid dissociation constant pKₐ of −1.85 and having neither a pyridine ring nor a phenanthroline ring.

### [Step 8-1]

After the workpiece was taken out from the vacuum evaporation apparatus and exposed to the atmosphere, the sacrificial layer SCR1 was formed over the layer 105X in Step 8-1. Specifically, the sacrificial layer SCR1 was formed by an ALD method using trimethylaluminum (abbreviation: TMA) as a precursor and water vapor as an oxidizer.

The sacrificial layer SCR1 contains aluminum oxide and has a thickness of 30 nm.

### [Step 8-2]

In Step 8-2, the sacrificial layer SCR2 was formed over the sacrificial layer SCR1. Specifically, the sacrificial layer SCR2 was formed by a sputtering method using molybdenum (Mo) as a target.

The sacrificial layer SCR2 contains Mo and has a thickness of 50 nm.

### [Step 8-3]

In Step 8-3, a resist was formed over the sacrificial layer SCR2 using a photoresist, and the sacrificial layer SCR2, the sacrificial layer SCR1, the layer 105X, the layer 113X1, the layer 111X, the layer 112X, and the layer 104X were processed into predetermined shapes by a lithography method.

Specifically, the sacrificial layer SCR2 was etched using an etching gas containing CF₄, O₂, and He at a flow rate ratio of 100:67:333 and then using an etching gas containing oxygen, followed by removal of the resist using a chemical solution. Next, the sacrificial layer SCR1 was processed using the sacrificial layer SCR2 as a mask and an etching gas containing CHF₃ and He at a flow rate ratio of 1:49. After that, the etching conditions were changed, and a stacked-layer film including the layers from the layer 104X to the layer 105X was processed into a predetermined shape. Specifically, the processing was performed using an etching gas containing oxygen.

The predetermined shape was made by forming a slit in a region of the stacked-layer film that did not overlap with the electrode 551X. Specifically, a slit having a width of 3 m was formed in a position that is 3.5 m apart from the end portion of the electrode 551X and in a region overlapping with the gap 551XY between the electrode 551X and the electrode 551Y (see FIG. 32B).

### [Step 8-4]

In Step 8-4, the sacrificial layer SCR2 was removed using an etching gas containing CF₄, O₂, and He at a flow rate ratio of 100:67:333 and then the sacrificial layer SCR1 was removed using a chemical solution, so that the layer 105X was exposed.

Next, the workpiece was transferred into a vacuum evaporation apparatus in which the pressure was reduced to approximately 1×10⁻⁴ Pa, and vacuum baking was performed at 110° C. for one hour in a heating chamber of the vacuum evaporation apparatus. Then, the workpiece was cooled down for approximately 30 minutes.

### [Step 10]

After Step 8-4, Step 9 was omitted and the electrode 552X was formed over the layer 105X in Step 10. Specifically, materials of the electrode 552X were co-deposited by a resistance-heating method. The electrode 552X contains Ag and Mg at a volume ratio of 1:0.1 and has a thickness of 15 nm.

### <<Operation Characteristics of Light-Emitting Device 2>>

When supplied with electric power, the light-emitting device 2 emitted the light ELX (see FIG. 32B). The operation characteristics of the light-emitting device 2 were measured at room temperature (see FIG. 33 to FIG. 37). Note that the luminance, CIE chromaticity, and emission spectrum were measured with a spectroradiometer (SR-UL1R produced by TOPCON TECHNOHOUSE CORPORATION).

Table 6 shows the main initial characteristics of the fabricated light-emitting device emitting light at a luminance of approximately 1000 cd/m². Table 6 also shows the characteristics of a comparative device having a structure described later.

TABLE 6

| | | | Current | | | Current |
|---|---|---|---|---|---|---|
| | Voltage | Current | density | Chromaticity | Chromaticity | efficiency |
| | (V) | (mA) | (mA/cm2) | x | y | (cd/A) |
| Light-emitting device 2 | 3.5 | 0.03 | 0.8 | 0.24 | 0.72 | 117.4 |
| Comparative device 2 | 7.2 | 0.37 | 9.1 | 0.24 | 0.72 | 12.3 |

The light-emitting device 2 was found to exhibit excellent characteristics. For example, the light-emitting device 2 exhibited higher current efficiency than the comparative device 2. In addition, the light-emitting device 2 operated at a lower voltage than the comparative device 2. Thus, it was found that the layer 105X included in the light-emitting device of one embodiment of the present invention exhibited an excellent electron-injection property. It was also found that the layer 105X exhibited an excellent electron-injection property even when being exposed to the atmosphere and the chemical solution during the fabrication process. Furthermore, the light-emitting device of one embodiment of the present invention was found to have excellent resistance to the atmosphere, the chemical solution, and the etching step.

### <ESR Measurement>

The spin density of a film containing the materials used for the layer 105X of the light-emitting device 2 was measured by ESR spectroscopy.

Specifically, the spin density of the materials, which were used for the layer 105X, in a film state was measured. A measurement sample was formed by co-depositing 11mDBtBPPnfpr and 2′,7′tBu-2hppSF at a weight ratio of 1:1 to a thickness of 50 nm over a quartz substrate.

Note that the measurement of an ESR spectrum of the measurement sample using ESR spectroscopy was performed at room temperature with an ESR spectrometer E500 (produced by Bruker Corporation). The measurement was performed at room temperature under the conditions where the resonance frequency was 9.56 GHz, the output power was 1 mW, the modulated magnetic field was 50 mT, the modulation width was 0.5 mT, the time constant was 0.04 s, and the sweep time was 1 min. As a result, it was found that no signal was observed at a g-factor of around 2.00 and the spin density was lower than 8×10¹⁶ spins/cm³, which is the lower detection limit. In the case where the spin density is lower than or equal to 1×10¹⁷ spins/cm³, it can be said that electrons are not transferred between the materials contained in the film. Therefore, it can be said that 2′,7′tBu-2hppSF does not have an electron-donating property with respect to 11mDBtBPPnfpr.

The spin density of the materials, which were used for the layer 104X, in a film state was measured. A measurement sample was formed by co-depositing PCBBiF and OCHD-003 at a weight ratio of 1:0.1 to a thickness of 100 nm over a quartz substrate.

Note that the measurement of an ESR spectrum of the measurement sample using ESR spectroscopy was performed at room temperature with an ESR spectrometer JES FA300 (produced by JEOL Ltd.). The measurement was performed at room temperature under the conditions where the resonance frequency was 9.18 GHz, the output power was 1 mW, the modulated magnetic field was 50 mT, the modulation width was 0.5 mT, the time constant was 0.03 s, and the sweep time was 1 min. As a result, it was found that a signal was observed at a g-factor of around 2.00 and the spin density was 5×10¹⁹ spins/cm³. This suggests that OCHD-003 has an electron-accepting property with respect to PCBBiF.

### <Comparative Device 2>

The fabricated comparative device 2 has a structure similar to that of the light-emitting device 550X (see FIG. 32B).

### <<Structure of Comparative Device 2>>

The comparative device 2 is different from the light-emitting device 2 in including the layer 113X2 instead of the layer 105X. Specifically, the comparative device 2 is different from the light-emitting device 2 in including the layer 113X2 containing 11mDBtBPPnfpr instead of the layer 105X containing 11 mDBtBPPnfpr and 2′,7′tBu-2hppSF.

### <<Method for Fabricating Comparative Device 2>>

The comparative device 2 was fabricated by a method including the following step. Note that the method for fabricating the comparative device 2 is different from that for fabricating the light-emitting device 2 in that the layer 113X2 is formed instead of the layer 105X in Step 7. Different portions are described in detail here, and the above description is referred to for portions where a method similar to the above was employed.

### [Step 9]

In Step 9, the layer 113X2 was formed over the layer 113X1. Specifically, a material of the layer 113X2 was deposited by a resistance-heating method. The layer 113X2 contains 11mDBtBPPnfpr and has a thickness of 5 nm.

### <<Operation Characteristics of Comparative Device 2>>

When supplied with electric power, the comparative device 2 emitted the light ELX (see FIG. 32B). The operation characteristics of the comparative device 2 were measured at room temperature (see FIG. 33 to FIG. 37). Note that the luminance, CIE chromaticity, and emission spectrum were measured with a spectroradiometer (SR-UL1R produced by TOPCON TECHNOHOUSE CORPORATION).

This application is based on Japanese Patent Application Serial No. 2022-206180 filed with Japan Patent Office on Dec. 23, 2022, the entire contents of which are hereby incorporated by reference.

What is claimed is:

1. A light-emitting device comprising:
a first electrode;
a second electrode;
a first unit; and
a first layer,
wherein the first unit is between the first electrode and the second electrode,
wherein the first unit comprises a first light-emitting material,
wherein the first layer is between the second electrode and the first unit,
wherein the first layer is in contact with the second electrode,
wherein the first layer comprises a first organic compound and a second organic compound,
wherein the first organic compound has an acid dissociation constant pKₐ larger than or equal to 8, and
wherein the second organic compound comprises no pyridine ring, no phenanthroline ring, or one phenanthroline ring.

2. The light-emitting device according to claim 1,
wherein the second organic compound has an acid dissociation constant pKₐsmaller than 4.

3. A light-emitting device comprising:
a first electrode;
a second electrode;
a first unit; and
a first layer,
wherein the first unit is between the first electrode and the second electrode,
wherein the first unit comprises a first light-emitting material,
wherein the first layer is between the second electrode and the first unit,
wherein the first layer is in contact with the second electrode,
wherein the first layer comprises a first organic compound and a second organic compound,
wherein the first organic compound has an acid dissociation constant pKₐ larger than or equal to 8, and
wherein the second organic compound has a polarization term δₚ of a solubility parameter δ of less than or equal to 4.0 MPa^{0.5}.

4. The light-emitting device according to claim 1, wherein the first organic compound comprises a guanidine skeleton.

5. The light-emitting device according to claim 1, wherein the first organic compound comprises a 1,3,4,6,7,8-hexahydro-2H-pyrimido[1,2-a]pyrimidine group.

6. The light-emitting device according to claim 1, wherein the first organic compound does not have an electron-donating property with respect to the second organic compound.

7. The light-emitting device according to claim 1, wherein the first layer comprises a material having a spin density lower than or equal to 1×10¹⁷ spins/cm³ in a film state observed by electron spin resonance spectroscopy.

8. The light-emitting device according to claim 1, wherein the first layer is an electron-injection layer.

9. The light-emitting device according to claim 3, wherein the first organic compound comprises a guanidine skeleton.

10. The light-emitting device according to claim 3, wherein the first organic compound comprises a 1,3,4,6,7,8-hexahydro-2H-pyrimido[1,2-a]pyrimidine group.

11. The light-emitting device according to claim 3, wherein the first layer is an electron-injection layer.

12. A display apparatus comprising:
a first light-emitting device; and
a second light-emitting device,
wherein the first light-emitting device comprises:
a first electrode;
a second electrode;
a first unit between the first electrode and the second electrode; and
a first layer between the second electrode and the first unit,
wherein the first unit comprises a first light-emitting material,
wherein the first layer is in contact with the second electrode,
wherein the first layer comprises a first organic compound and a second organic compound,
wherein the second light-emitting device comprises:
a third electrode;
a fourth electrode;
a second unit between the third electrode and the fourth electrode; and
a second layer between the fourth electrode and the second unit,
wherein the third electrode is adjacent to the first electrode,
wherein a first gap is positioned between the third electrode and the first electrode,
wherein the second unit comprises a second light-emitting material,
wherein the second layer is in contact with the fourth electrode,
wherein the second layer comprises a third organic compound and a fourth organic compound,
wherein the first organic compound has an acid dissociation constant pKₐ larger than or equal to 8,
wherein the third organic compound has an acid dissociation constant pKₐ larger than or equal to 8,
wherein the second organic compound comprises no pyridine ring, no phenanthroline ring, or one phenanthroline ring, and
wherein the fourth organic compound comprises no pyridine ring, no phenanthroline ring, or one phenanthroline ring.

13. The display apparatus according to claim 12,
wherein the second organic compound has an acid dissociation constant pKₐ smaller than 4, and
wherein the fourth organic compound has an acid dissociation constant pKₐ smaller than 4.

14. The display apparatus according to claim 12,
wherein the second organic compound has a polarization term δₚ of a solubility parameter δ of less than or equal to 4.0 MPa^{0.5}, and
wherein the fourth organic compound has a polarization term δₚ of a solubility parameter δ of less than or equal to 4.0 MPa^{0.5}.

15. The display apparatus according to claim 12, wherein at least one of the first organic compound and the third organic compound comprises a guanidine skeleton.

16. The display apparatus according to claim 12, wherein at least one of the first organic compound and the third organic compound comprises a 1,3,4,6,7,8-hexahydro-2H-pyrimido[1,2-a]pyrimidine group.

17. The display apparatus according to claim 12,
wherein the first layer is a first electron-injection layer, and
wherein the second layer is a second electron-injection layer.

18. The display apparatus according to claim 12,
wherein the first light-emitting device comprises a third layer,
wherein the third layer is between the first unit and the first electrode,
wherein the second light-emitting device comprises a fourth layer,
wherein the fourth layer is between the second unit and the third electrode,
wherein a second gap is positioned between the fourth layer and the third layer,
wherein the second gap overlaps with the first gap,
wherein the third layer comprises a material having a spin density higher than or equal to 1×10¹⁸ spins/cm³ in a film state observed by electron spin resonance spectroscopy, and
wherein the fourth layer comprises a material having a spin density higher than or equal to 1×10¹⁸ spins/cm³ in a film state observed by electron spin resonance spectroscopy.

19. The display apparatus according to claim 18, further comprising a fifth layer,
wherein the fifth layer comprises the first layer and the second layer, and
wherein the fifth layer overlaps with the first gap between the first layer and the second layer.

20. A display module comprising:
the display apparatus according to claim 12; and
at least one of a connector and an integrated circuit.

21. An electronic device comprising:
the display apparatus according to claim 12; and
at least one of a battery, a camera, a speaker, and a microphone.
